(19) United States
(12) Patent Application Publication
(10) Pub. No.: US 2024/0008301 A1
(43) Pub. Date: Jan. 4, 2024

(54) Light-Emitting Device

(71) Applicant: Semiconductor Energy Laboratory Co., Ltd., Kanagawa-ken (JP)

(72) Inventors: Toshiki Sasaki, Kawasaki (JP); Hiromitsu KIDO, Atsugi (JP); Tsunenori SUZUKI, Yokohama (JP); Nobuharu OHSAWA, Kanagawa (JP); Hideko YOSHIZUMI, Atsugi (JP); Satoshi SEO, Sagamihara (JP); Satoko NUMATA, Atsugi (JP); Eriko AOYAMA, Atsugi (JP); Yui YOSHIYASU, Atsugi (JP)

(73) Assignee: Semiconductor Energy Laboratory Co., Ltd., Kanagawa-ken (JP)

(21) Appl. No.: 18/214,844

(22) Filed: Jun. 27, 2023

(30) Foreign Application Priority Data
Jun. 29, 2022 (JP) 2022-105076
Jun. 12, 2023 (JP) 2023-096193

(51) Int. Cl. H10K 50/13; H10K 50/16; H10K 50/15; H10K 85/60; C09K 11/06

(52) U.S. Cl. CPC H10K 50/13; H10K 50/16; H10K 50/15; H10K 85/649; C09K 11/06; H10K 2101/27

(57) ABSTRACT

A green phosphorescent light-emitting device with a long lifetime is provided. The light-emitting device includes a first electrode, a second electrode, and a light-emitting layer. The light-emitting layer is between the first electrode and the second electrode. The light-emitting layer includes a first organic compound, a second organic compound, and a phosphorescent light-emitting substance. The first organic compound includes a heteroaromatic ring skeleton and an aromatic hydrocarbon group. The second organic compound includes a bicarbazole skeleton. The lowest triplet excited level of the first organic compound is derived from only the aromatic hydrocarbon group. The energy of the lowest triplet excited level of the second organic compound is higher than or equal to 2.20 eV and lower than or equal to 2.65 eV.

### BACKGROUND OF THE INVENTION

### 1. Field of the Invention

One embodiment of the present invention relates to a light-emitting device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

### 2. Description of the Related Art

Recent display devices have been expected to be applied to a variety of uses. Usage examples of large-sized display devices include a television device for home use (also referred to as TV or television receiver), digital signage, and a public information display (PID). In addition, a smartphone, a tablet terminal, and the like each including a touch panel are being developed as portable information terminals.

Higher resolution of display devices is also in demand. For example, high resolution is required in display devices for virtual reality (VR), augmented reality (AR), substitutional reality (SR), and mixed reality (MR). Such display devices with high resolution have been actively developed.

Light-emitting devices using organic compounds suitable for the above high-resolution display devices have been actively researched. Light-emitting devices utilizing electroluminescence of organic compounds (hereinafter referred to as EL; such devices are also referred to as organic EL devices or organic EL elements) have features such as ease of reduction in thickness and weight, high-speed response to input signals, and driving with a constant DC voltage power source, and have been used in display devices.

Displays or lighting devices including light-emitting devices can be used suitably for a variety of electronic appliances as described above, and research and development of light-emitting devices has progressed for more favorable characteristics.

In particular, the lifetime of light-emitting devices is a key characteristic affecting the usage period, display quality, and power consumption of the above electronic devices. Patent Document 1 discloses a structure in which an exciplex serves as an energy donor to increase the emission efficiency, lifetime, and driving voltage of a phosphorescent light-emitting device.

### REFERENCES

[Patent Document 1] Japanese Published Patent Application No. 2012-186461
[Non-Patent Document 1] Nicholas J. Turro, V. Ramamurthy, J. C. Scaiano, “MODERN MOLECULAR PHOTOCHEMISTRY OF ORGANIC MOLECULES”, UNIVERSITY SCIENCE BOOKS, 2010. 02.10, pp. 204-208
[Non-Patent Document 2] Daisaku TANAKA et.al., “Ultra High Efficiency Green Organic Light-Emitting Devices”, Japanese Journal of Applied Physics, Vol. 46, No. 1, 2007, pp. L10-L12

### SUMMARY OF THE INVENTION

An object of one embodiment of the present invention is to provide a highly reliable light-emitting device. Another object is to provide a highly reliable light-emitting device capable of efficient light emission. Another object is to provide a highly reliable green phosphorescent light-emitting device. Another object is to provide a highly reliable green phosphorescent light-emitting device capable of efficient light emission.

An object of another embodiment of the present invention is to provide a highly reliable display device. Another object is to provide a highly reliable display device having low power consumption.

Other objects are to provide a novel organic compound, a novel light-emitting device, a novel display device, a novel display module, and a novel electronic device.

Note that the description of these objects does not preclude the existence of other objects. One embodiment of the present invention does not need to achieve all of these objects. Other objects can be derived from the description of the specification, the drawings, and the claims.

One embodiment of the present invention is a light-emitting device including a first electrode, a second electrode, and a light-emitting layer. The light-emitting layer is between the first electrode and the second electrode. The light-emitting layer includes a first organic compound, a second organic compound, and a phosphorescent light-emitting substance. The first organic compound includes a heteroaromatic ring skeleton and an aromatic hydrocarbon group. The second organic compound includes a bicarbazole skeleton. The lowest triplet excited state of the first organic compound is locally distributed at the aromatic hydrocarbon group. The energy of the lowest triplet excited level of the second organic compound is higher than or equal to 2.20 eV and lower than or equal to 2.65 eV.

Another embodiment of the present invention is a light-emitting device including a first electrode, a second electrode, and a light-emitting layer. The light-emitting layer is between the first electrode and the second electrode. The light-emitting layer includes a first organic compound, a second organic compound, and a phosphorescent light-emitting substance. The first organic compound includes a heteroaromatic ring skeleton and a substituent. The substituent includes a 1,1′:4′,1″-terphenyl skeleton. The second organic compound includes a bicarbazole skeleton. The energy of a lowest triplet excited level of the second organic compound is higher than or equal to 2.20 eV and lower than or equal to 2.65 eV.

Another embodiment of the present invention is the light-emitting device with the above structure, in which the substituent includes one or both of a dibenzofuran skeleton and a dibenzothiophene skeleton.

Another embodiment of the present invention is the light-emitting device with the above structure, in which a meta-position of the substituent is bonded to the heteroaromatic ring skeleton.

Another embodiment of the present invention is the light-emitting device with the above structure, in which the substituent is bonded to the heteroaromatic ring skeleton through a 1,3-phenylene group.

Another embodiment of the present invention is a light-emitting device including a first electrode, a second electrode, and a light-emitting layer. The light-emitting layer is between the first electrode and the second electrode. The light-emitting layer includes a first organic compound, a second organic compound, and a phosphorescent light-emitting substance. The first organic compound includes a heteroaromatic ring skeleton and a 1,1′:4′,1″-terphenyl group. The second organic compound includes a bicarbazole skeleton. The energy of a lowest triplet excited level of the second organic compound is higher than or equal to 2.20 eV and lower than or equal to 2.65 eV.

Another embodiment of the present invention is the light-emitting device with the above structure, in which a meta-position of the 1,1′:4′,1″-terphenyl group is bonded to the heteroaromatic ring skeleton.

Another embodiment of the present invention is the light-emitting device with the above structure, in which the 1,1′:4′,1″-terphenyl group is bonded to the heteroaromatic ring skeleton through a 1,3-phenylene group.

Another embodiment of the present invention is the light-emitting device with the above structure, in which the heteroaromatic ring skeleton includes a fused ring.

Another embodiment of the present invention is the light-emitting device with the above structure, in which the heteroaromatic ring skeleton includes a diazine skeleton.

Another embodiment of the present invention is the light-emitting device with the above structure, in which the heteroaromatic ring skeleton includes a fused ring and a diazine skeleton.

Another embodiment of the present invention is the light-emitting device with the above structure, in which the heteroaromatic ring skeleton includes a benzofuropyrimidine skeleton or a triazine skeleton.

Another embodiment of the present invention is the light-emitting device with the above structure, in which the second organic compound includes a naphthyl group.

Another embodiment of the present invention is the light-emitting device with the above structure, in which a lowest triplet excited level of the first organic compound is derived from only the substituent.

Another embodiment of the present invention is a display module including the above light-emitting device and at least one of a connector and an integrated circuit.

Another embodiment of the present invention is an electronic device including the above light-emitting device and at least one of a housing, a battery, a camera, a speaker, and a microphone.

One embodiment of the present invention can provide a highly reliable light-emitting device. Another embodiment can provide a highly reliable light-emitting device capable of efficient light emission. Another embodiment can provide a highly reliable green phosphorescent light-emitting device. Another embodiment can provide a highly reliable green phosphorescent light-emitting device capable of efficient light emission.

One embodiment of the present invention can provide a highly reliable display device. Another embodiment can provide a highly reliable display device having low power consumption.

Another embodiment can provide a novel organic compound, a novel light-emitting device, a novel display device, a novel display module, and a novel electronic device.

Note that the description of these effects does not preclude the existence of other effects. One embodiment of the present invention does not necessarily have all of these effects. Other effects can be derived from the description of the specification, the drawings, the claims, and the like.

### BRIEF DESCRIPTION OF THE DRAWINGS

FIGS. 1A to 1C are schematics of light-emitting devices of one embodiment of the present invention.

FIGS. 2A and 2B illustrate a display device of one embodiment of the present invention.

FIGS. 3A and 3B illustrate a display device of one embodiment of the present invention.

FIGS. 4A to 4E are cross-sectional views illustrating an example of a manufacturing method of a display device.

FIGS. 5A to 5D are cross-sectional views illustrating an example of a manufacturing method of a display device.

FIGS. 6A to 6D are cross-sectional views illustrating an example of a manufacturing method of a display device.

FIGS. 7A to 7C are cross-sectional views illustrating an example of a manufacturing method of a display device.

FIGS. 8A to 8C are cross-sectional views illustrating an example of a manufacturing method of a display device.

FIGS. 9A to 9C are cross-sectional views illustrating an example of a manufacturing method of a display device.

FIGS. 10A and 10B are perspective views illustrating a structure example of a display module.

FIGS. 11A and 11B are cross-sectional views illustrating structure examples of a display device.

FIG. 12 is a perspective view illustrating a structure example of a display device.

FIG. 13 is a cross-sectional view illustrating a structure example of a display device.

FIG. 14 is a cross-sectional view illustrating a structure example of a display device.

FIG. 15 is a cross-sectional view illustrating a structure example of a display device.

FIGS. 16A to 16D illustrate examples of an electronic device.

FIGS. 17A to 17F illustrate examples of electronic devices.

FIGS. 18A to 18G illustrate examples of electronic devices.

FIG. 19 is a graph showing the luminance-current density characteristics of Light-emitting device 1 and Comparative light-emitting device 1.

FIG. 20 is a graph showing the current efficiency-luminance characteristics of Light-emitting device 1 and Comparative light-emitting device 1.

FIG. 21 is a graph showing the luminance-voltage characteristics of Light-emitting device 1 and Comparative light-emitting device 1.

FIG. 22 is a graph showing the current density-voltage characteristics of Light-emitting device 1 and Comparative light-emitting device 1.

FIG. 23 is a graph showing the emission spectra of Light-emitting device 1 and Comparative light-emitting device 1.

FIG. 24 is a graph showing the time dependence of normalized luminance of Light-emitting device 1 and Comparative light-emitting device 1.

FIGS. 25A to 25C show analysis results of 8mpTP-4mDBtPBfpm by calculation.

FIGS. 26A to 26C show analysis results of an organic compound represented by Structural Formula (216) by calculation.

FIGS. 27A to 27C show analysis results of 8BP-4mDBtPBfpm by calculation.

FIG. 28 is a graph showing the luminance-current density characteristics of Light-emitting device 2 and Comparative light-emitting device 2.

FIG. 29 is a graph showing the current efficiency-luminance characteristics of Light-emitting device 2 and Comparative light-emitting device 2.

FIG. 30 is a graph showing the luminance-voltage characteristics of Light-emitting device 2 and Comparative light-emitting device 2.

FIG. 31 is a graph showing the current density-voltage characteristics of Light-emitting device 2 and Comparative light-emitting device 2.

FIG. 32 is a graph showing the emission spectra of Light-emitting device 2 and Comparative light-emitting device 2.

FIG. 33 is a graph showing the time dependence of normalized luminance of Light-emitting device 2 and Comparative light-emitting device 2.

FIG. 34 is a graph showing the luminance-current density characteristics of Light-emitting device 3 and Light-emitting device 4.

FIG. 35 is a graph showing the current efficiency-luminance characteristics of Light-emitting device 3 and Light-emitting device 4.

FIG. 36 is a graph showing the luminance-voltage characteristics of Light-emitting device 3 and Light-emitting device 4.

FIG. 37 is a graph showing the current density-voltage characteristics of Light-emitting device 3 and Light-emitting device 4.

FIG. 38 is a graph showing the emission spectra of Light-emitting device 3 and Light-emitting device 4.

FIG. 39 is a graph showing the time dependence of normalized luminance of Light-emitting device 3 and Light-emitting device 4.

FIG. 40 shows results of the emission spectra of 8mpTP-4mDBtPBfpm and 8mpTP-4mDBtPBfpm-d₂₃ measured at a low temperature.

FIG. 41 shows results of the emission lifetimes of 8mpTP-4mDBtPBfpm and 8mpTP-4mDBtPBfpm-d₂₃ measured at a low temperature.

FIG. 42 is a graph showing the current efficiency-luminance characteristics of Light-emitting device 5 to Light-emitting device 7.

FIG. 43 is a graph showing the luminance-voltage characteristics of Light-emitting device 5 to Light-emitting device 7.

FIG. 44 is a graph showing the current efficiency-current density characteristics of Light-emitting device 5 to Light-emitting device 7.

FIG. 45 is a graph showing the current density-voltage characteristics of Light-emitting device 5 to Light-emitting device 7.

FIG. 46 is a graph showing the luminance-current density characteristics of Light-emitting device 5 to Light-emitting device 7.

FIG. 47 is a graph showing the electroluminescence spectra of Light-emitting device 5 to Light-emitting device 7.

FIG. 48 is a graph showing the time dependence of normalized luminance of Light-emitting device 5 to Light-emitting device 7.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

### Embodiment 1

In a phosphorescent light-emitting device, light emission basically occurs from the lowest triplet excited level (T₁ level), which is at an energy level lower than the lowest singlet excited level (S₁ level). Hence, the energy gap (HOMO-LUMO energy gap) between the highest occupied molecular orbital (HOMO) level and the lowest unoccupied molecular orbital (LUMO) level of a material used in a phosphorescent light-emitting device needs to be wider than that in the fluorescent light-emitting device that exhibits the same emission color.

When a light-emitting device has a structure where an exciplex serves as an energy donor to excite a phosphorescent light-emitting substance, i.e., an exciplex-triplet energy transfer (ExTET) structure, the S₁ level of the exciplex is preferably higher than or equal to the T₁ level of the phosphorescent light-emitting substance with the S₁ and T₁ levels of the exciplex being close to each other. In addition, the T₁ level of each of the compounds forming the exciplex is preferably higher than or equal to the T₁ level of the phosphorescent light-emitting substance.

In a light-emitting device having the ExTET structure, the exciplex that is to supply energy to the phosphorescent light-emitting substance is preferably formed of an organic compound having an electron-transport property and an organic compound having a hole-transport property. In that case, the HOMO-LUMO energy gap of the exciplex corresponds to the energy gap between the LUMO level of the organic compound having an electron-transport property and the HOMO level of the organic compound having a hole-transport property.

In the organic compound having an electron-transport property and the organic compound having a hole-transport property that form the exciplex, the HOMO level of the organic compound having an electron-transport property is lower than that of the organic compound having a hole-transport property and the LUMO level of the organic compound having a hole-transport property is higher than that of the organic compound having an electron-transport property. Therefore, the HOMO-LUMO energy gap in each of the organic compound having an electron-transport property and the organic compound having a hole-transport property that form the exciplex is inevitably greater than the HOMO-LUMO energy gap of the exciplex.

The process in which adjacency of an anion of the organic compound having an electron-transport property to a cation of the organic compound having a hole-transport property directly form an exciplex (electroplex process) has probably been the predominant formation of an exciplex in a light-emitting device. Even when one of the organic compound having an electron-transport property and the organic compound having a hole-transport property comes into an excited state, the one quickly interacts with the other to form an exciplex; thus, most excitons in the light-emitting layer exist as exciplexes. This is why the S₁ and T₁ levels of the organic compounds themselves forming the exciplexes have been unspotlighted.

However, the present inventors have found that, when a light-emitting layer is formed using an organic compound having an electron-transport property and an organic compound having a hole-transport property that have certain structures, triplet excitation energy of each organic compound affects the reliability of the phosphorescent light-emitting device. This is probably because the process in which the T₁ level of each organic compound is generated from the T₁ level of the exciplex occurs in the device.

When the ν=0→ν=0 transition (0→0 band) between vibrational levels of the ground state and the excited state is clearly observed from a fluorescence spectrum or a phosphorescence spectrum, the S₁ level or the T₁ level of an organic compound is preferably calculated using the 0→0 band (see Non-Patent Document 1, for example). When the 0→0 band is unclear, the S₁ level can be energy of the wavelength at the intersection of the horizontal axis (wavelength) or the base line and a tangent to the fluorescence spectrum at a point where the slope of the spectrum at a peak on the shorter wavelength side has a maximum value and the T₁ level can be energy of the wavelength at the intersection of the horizontal axis (wavelength) or the base line and a tangent to the phosphorescence spectrum at a point where the slope of the spectrum at a peak on the shorter wavelength side has a maximum value (see Non-Patent Document 2, for example). In this specification, the latter method is employed to measure the levels. In the case where the levels are compared with each other, those calculated by the same method are used.

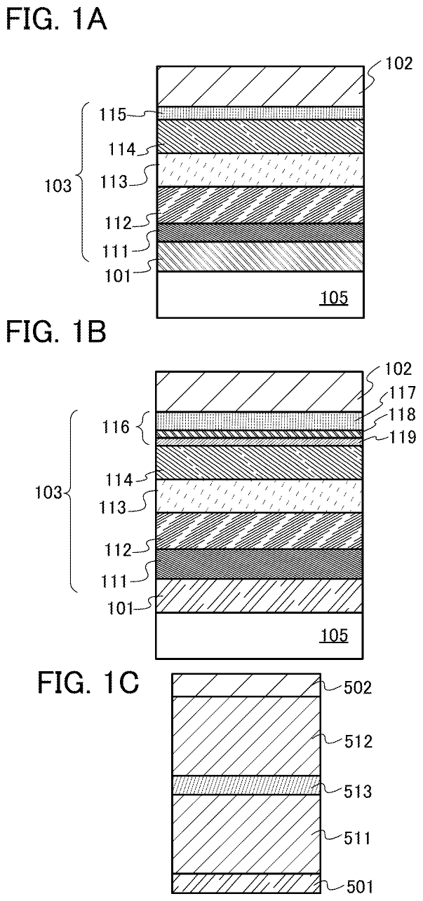

A light-emitting device of one embodiment of the present invention includes at least a light-emitting layer 113 between a first electrode 101 and a second electrode 102, as illustrated in FIG. 1A. The light-emitting layer 113 includes a phosphorescent light-emitting substance, a first organic compound, and a second organic compound.

The first organic compound is an organic compound having an electron-transport property. The first organic compound includes a heteroaromatic ring skeleton and a first substituent bonded to the heteroaromatic ring skeleton. In one embodiment of the present invention, the first organic compound is an organic compound in which the lowest triplet excited state is locally distributed at the first substituent and the lowest triplet excited level (T₁ level) is derived from the first substituent. This means that the skeleton or group that is included in the first organic compound and has the lowest T₁ level is the above first substituent. In other words, the lowest triplet excited state T₁ (i.e., triplet exciton) of the first organic compound is distributed (or localized) at the first substituent.

The heteroaromatic ring skeleton in the first organic compound is preferably a π-electron deficient heteroaromatic ring skeleton including two or more nitrogen atoms. The heteroaromatic ring skeleton preferably includes a diazine skeleton or a triazine skeleton, further preferably a diazine skeleton, in particular.

The heteroaromatic ring skeleton preferably includes a fused ring, and the fused ring is regarded as part of the heteroaromatic ring in the case where a hydrocarbon such as a benzene ring is fused to the heteroaromatic ring. In other words, a monocyclic heteroaromatic ring (e.g., a triazine ring) and a fused heteroaromatic ring (e.g., a quinoxaline ring or a benzofuropyrimidine ring), in which a benzene ring or the like is fused, are each regarded as one heteroaromatic ring. In particular, a benzofuropyrimidine skeleton or a benzothienopyrimidine skeleton is preferably included as the heteroaromatic ring skeleton.

Specifically, the heteroaromatic ring skeleton in the first organic compound is preferably represented by any of Structural Formulae (B-1) to (B-32) below.

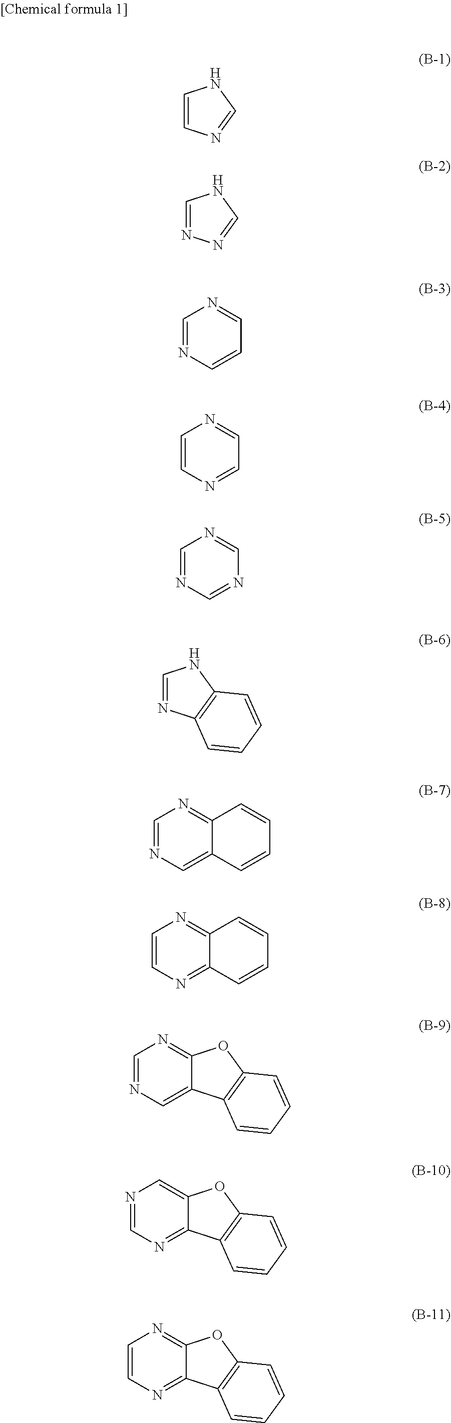

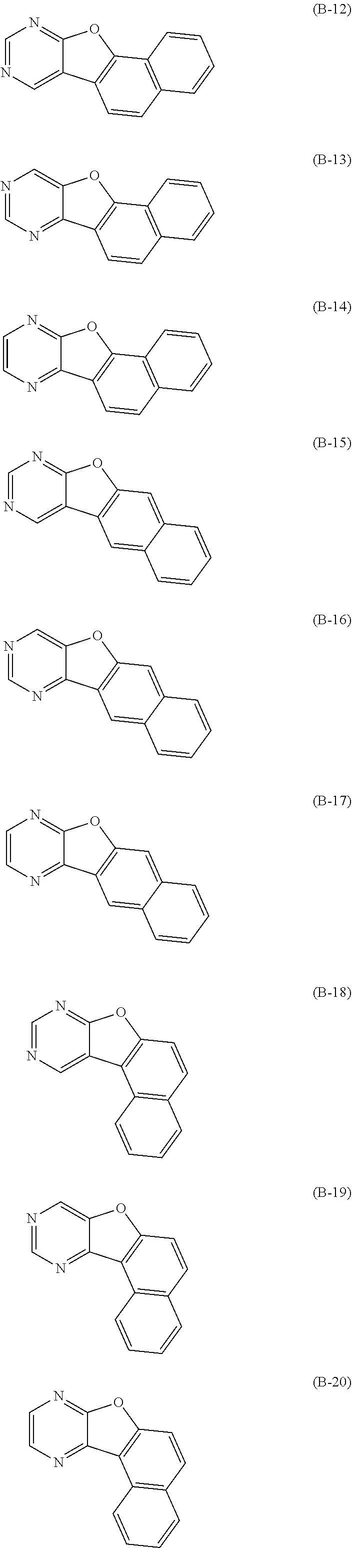

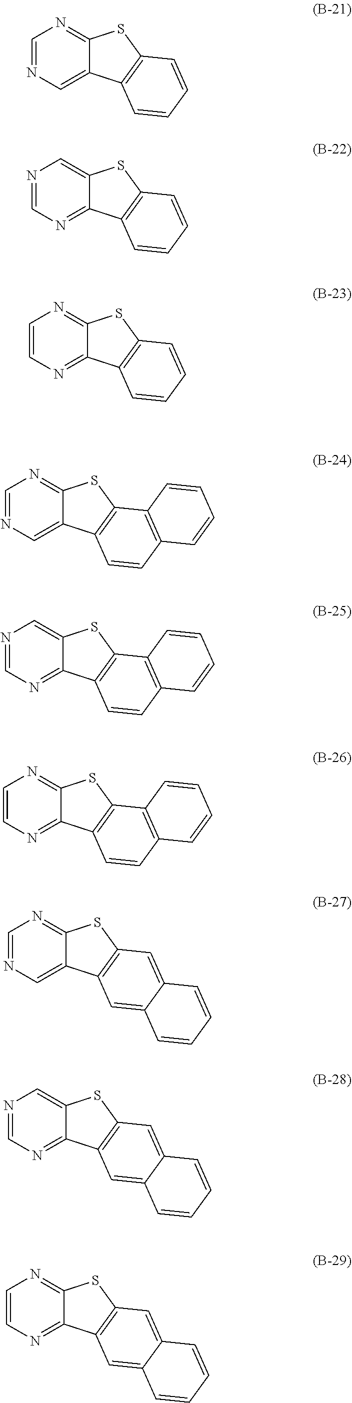

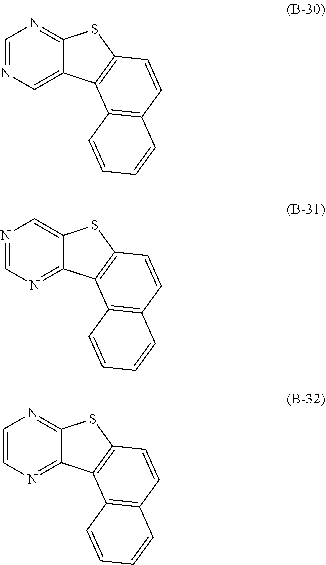 [SMILES: c1ccc2c(c1)ccc1sc3ncncc3c12 ; c1ccc2c(c1)ccc1sc3cncnc3c12 ; c1ccc2c(c1)ccc1sc3nccnc3c12]

The first substituent in the first organic compound is preferably an aromatic hydrocarbon group or a heteroaromatic group. Note that the first substituent is a group which includes at least a 1,1′:4′,1″-terphenyl skeleton. The meta- or ortho-position, i.e., the 3- or 2-position, of a terminal benzene ring of the 1,1′:4′,1″-terphenyl skeleton is bonded to the heteroaromatic ring skeleton; alternatively, the 1,1′:4′,1″-terphenyl skeleton is bonded to the heteroaromatic ring skeleton through a 1,3-phenylene group or a 1,2-phenylene group.

In the above 1,1′:4′,1″-terphenyl skeleton, carbon atoms adjacent to their respective carbon atoms, by which two adjacent benzene rings of the three benzene rings bonded to one another at the para-positions, are bonded, may be bridged by any of oxygen, sulfur, and carbon. In other words, the first substituent may include a dibenzothiophene skeleton, a dibenzofuran skeleton, or a fluorene skeleton, and the above 1,1′:4′,1″-terphenyl skeleton preferably includes a dibenzothiophene skeleton, a dibenzofuran skeleton, or a fluorene skeleton.

The 1,1′:4′,1″-terphenyl skeleton in the first substituent may include a substituent. Examples of the substituent are an alkyl group having 1 to 6 carbon atoms and a phenyl group.

Specifically, the first substituent in the first organic compound is preferably a skeleton represented by any of Structural Formulae (S1-1) to (S1-24) below.

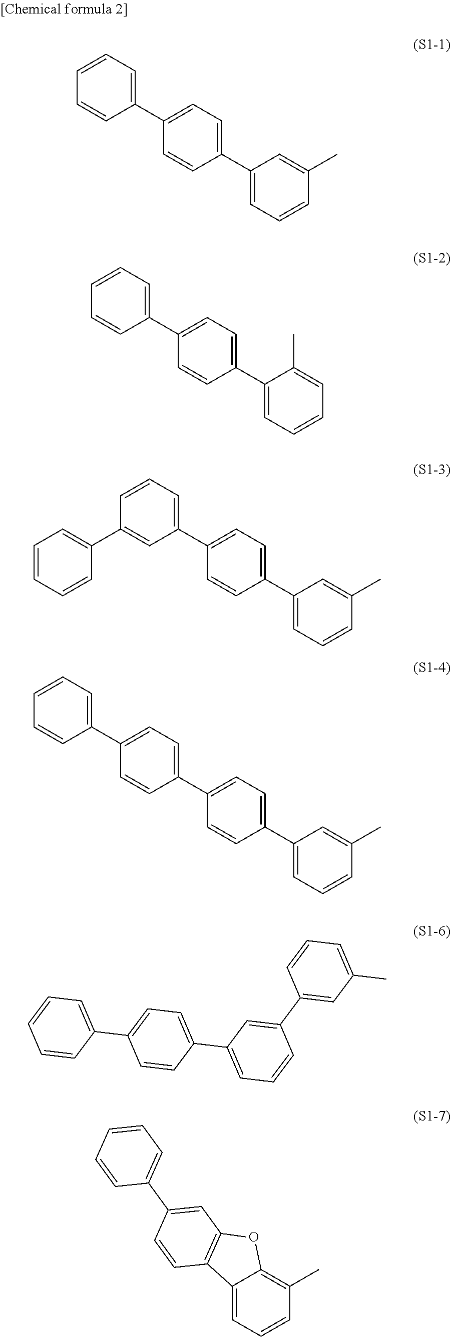

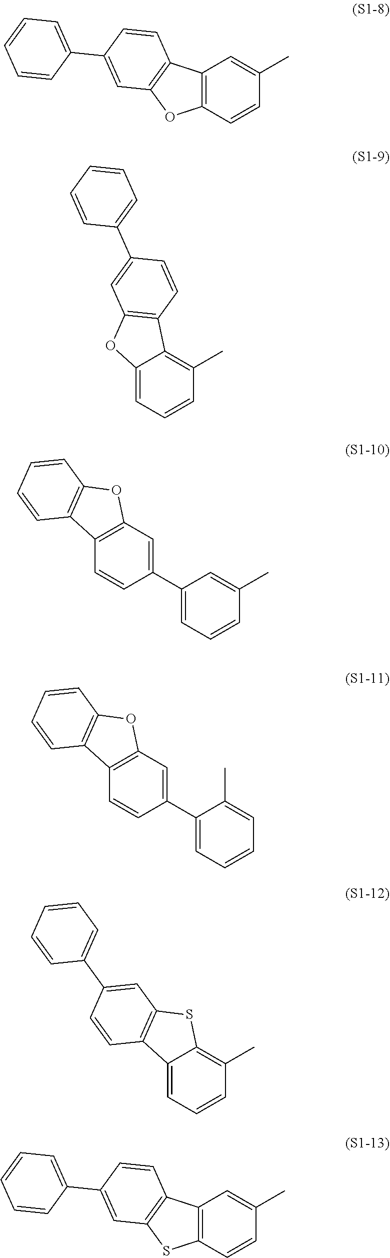 [SMILES: Cc1ccc2oc3cc(-c4ccccc4)ccc3c2c1 ; Cc1cccc2oc3cc(-c4ccccc4)ccc3c12 ; Cc1cccc(-c2ccc3c(c2)oc2ccccc23)c1 ; Cc1ccccc1-c1ccc2c(c1)oc1ccccc12 ; Cc1cccc2c1sc1cc(-c3ccccc3)ccc12 ; Cc1ccc2sc3cc(-c4ccccc4)ccc3c2c1]

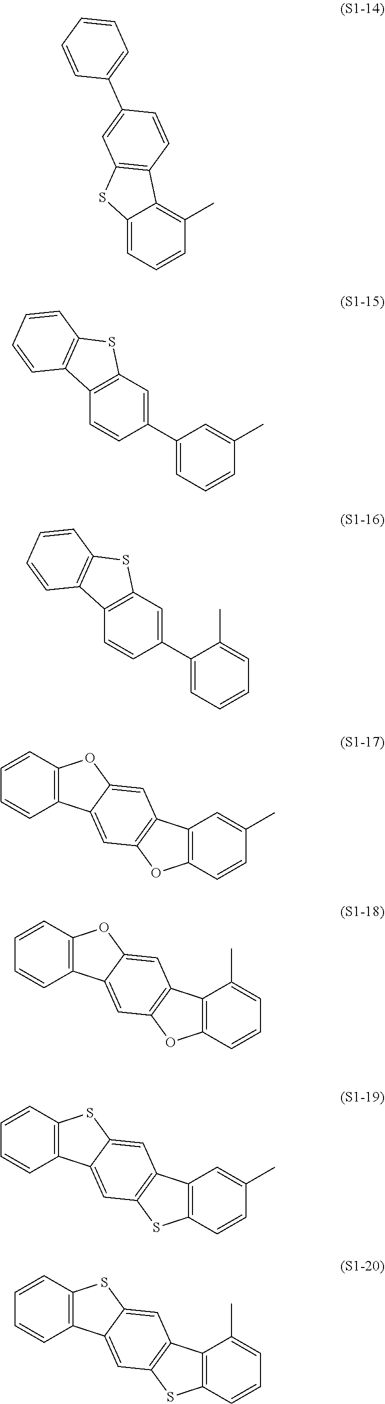

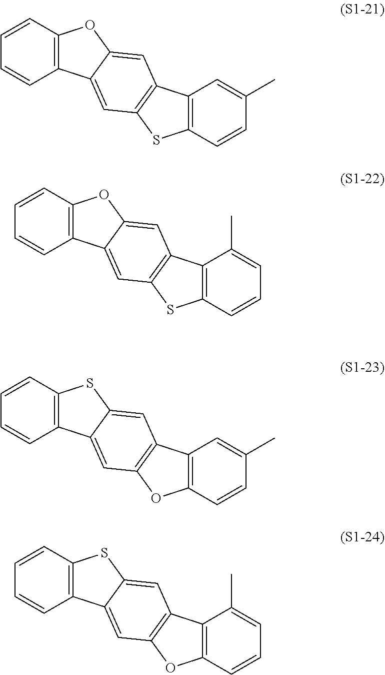 [SMILES: Cc1ccc2sc3cc4c(cc3c2c1)oc1ccccc14 ; Cc1cccc2sc3cc4c(cc3c12)oc1ccccc14 ; Cc1ccc2oc3cc4c(cc3c2c1)sc1ccccc14 ; Cc1cccc2oc3cc4c(cc3c12)sc1ccccc14]

In the case where the above heteroaromatic ring skeleton has a fused ring and the fused ring has a ring composed of only carbon atoms, the first substituent is preferably bonded to the ring composed of only carbon atoms.

The first organic compound preferably includes one or two second substituents having a hole-transport property in addition to the above heteroaromatic ring skeleton and the first substituent.

The second substituent is preferably a group represented by any of General Formulae (Ht-1) to (Ht-15) below.

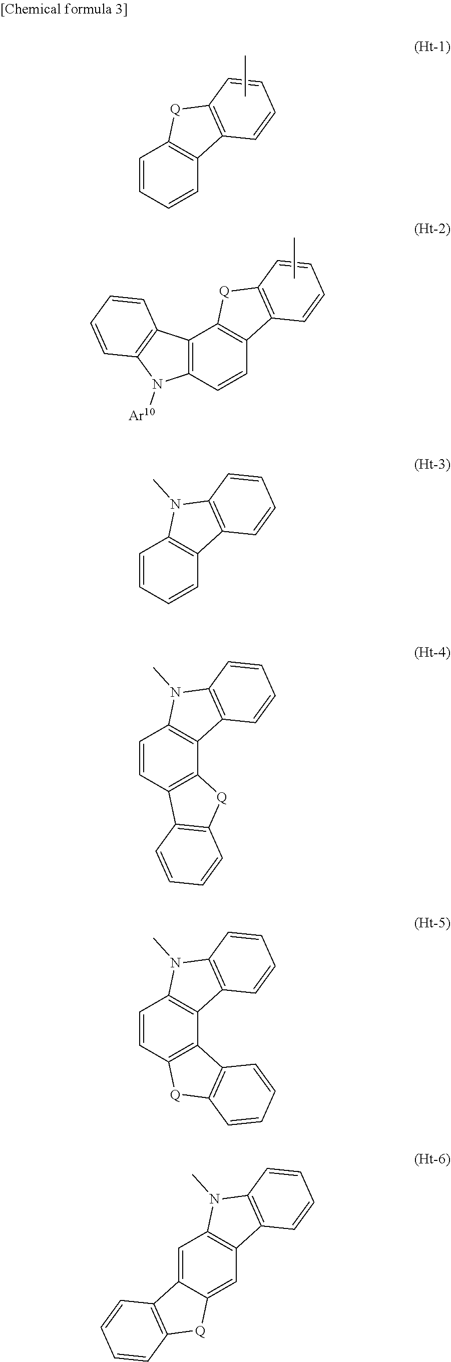

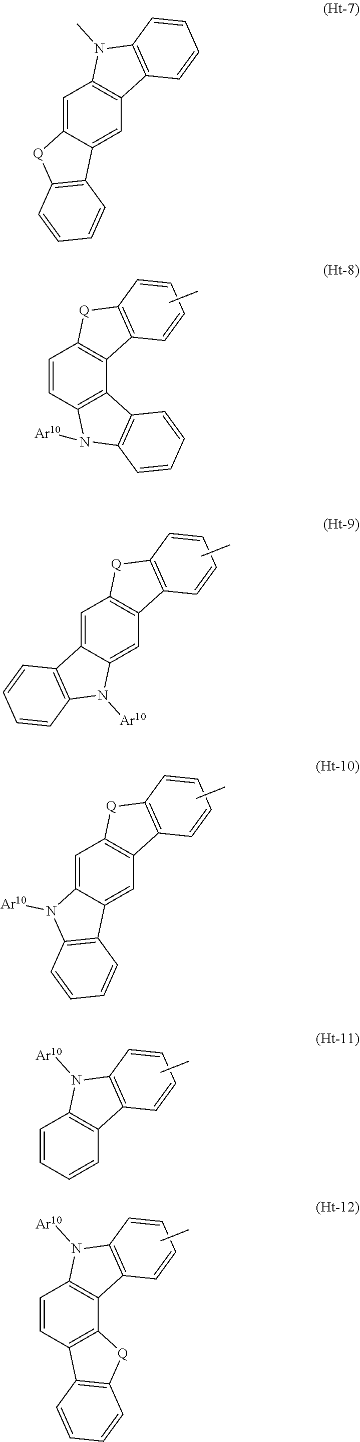

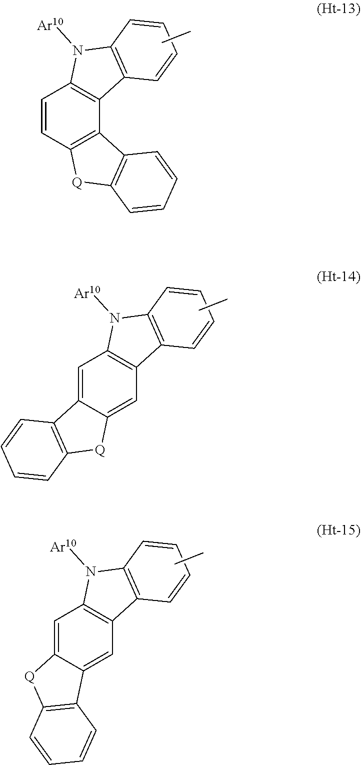

In General Formulae (Ht-1) to (Ht-15) above, Q represents oxygen or sulfur, and Ar¹⁰ represents a substituted or unsubstituted aryl group having 6 to 13 carbon atoms.

The second substituent is preferably bonded to the above heteroaromatic ring skeleton through a phenylene group. In that case, the phenylene group is preferably a 1,3-phenylene group or a 1,2-phenylene group, further preferably a 1,3-phenylene group.

In the case where the above heteroaromatic ring skeleton has a fused ring and the fused ring has a ring composed of only carbon atoms, the second substituent or the phenylene group to which the second substituent is bonded is preferably bonded to a ring including a heteroatom (in particular, a ring including nitrogen, such as a diazine ring).

Some or all of the hydrogen in the first organic compound may be deuterium.

Specifically, the first organic compound is preferably an organic compound represented by any of Structural Formulae (200) to (225) below.

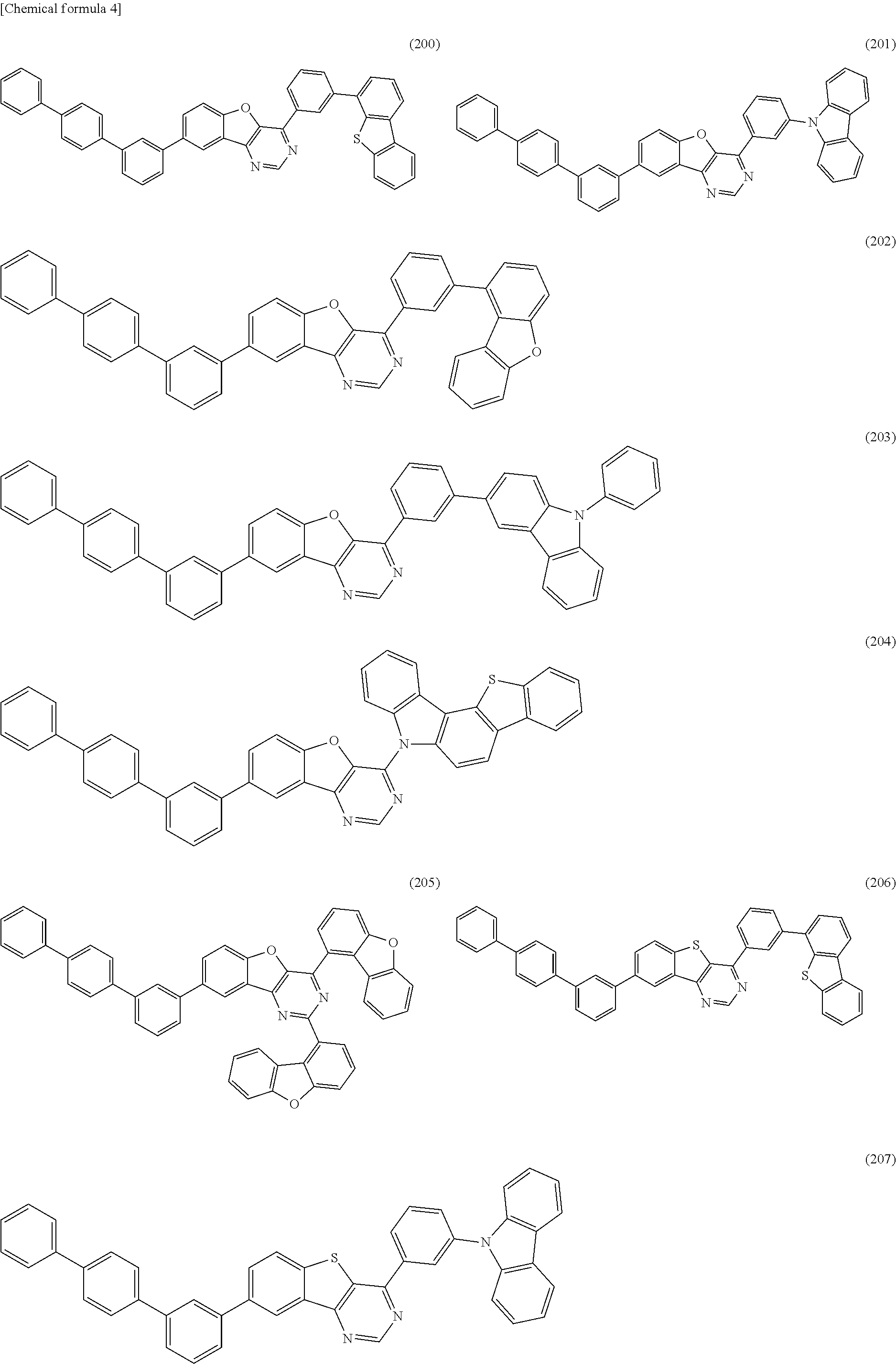

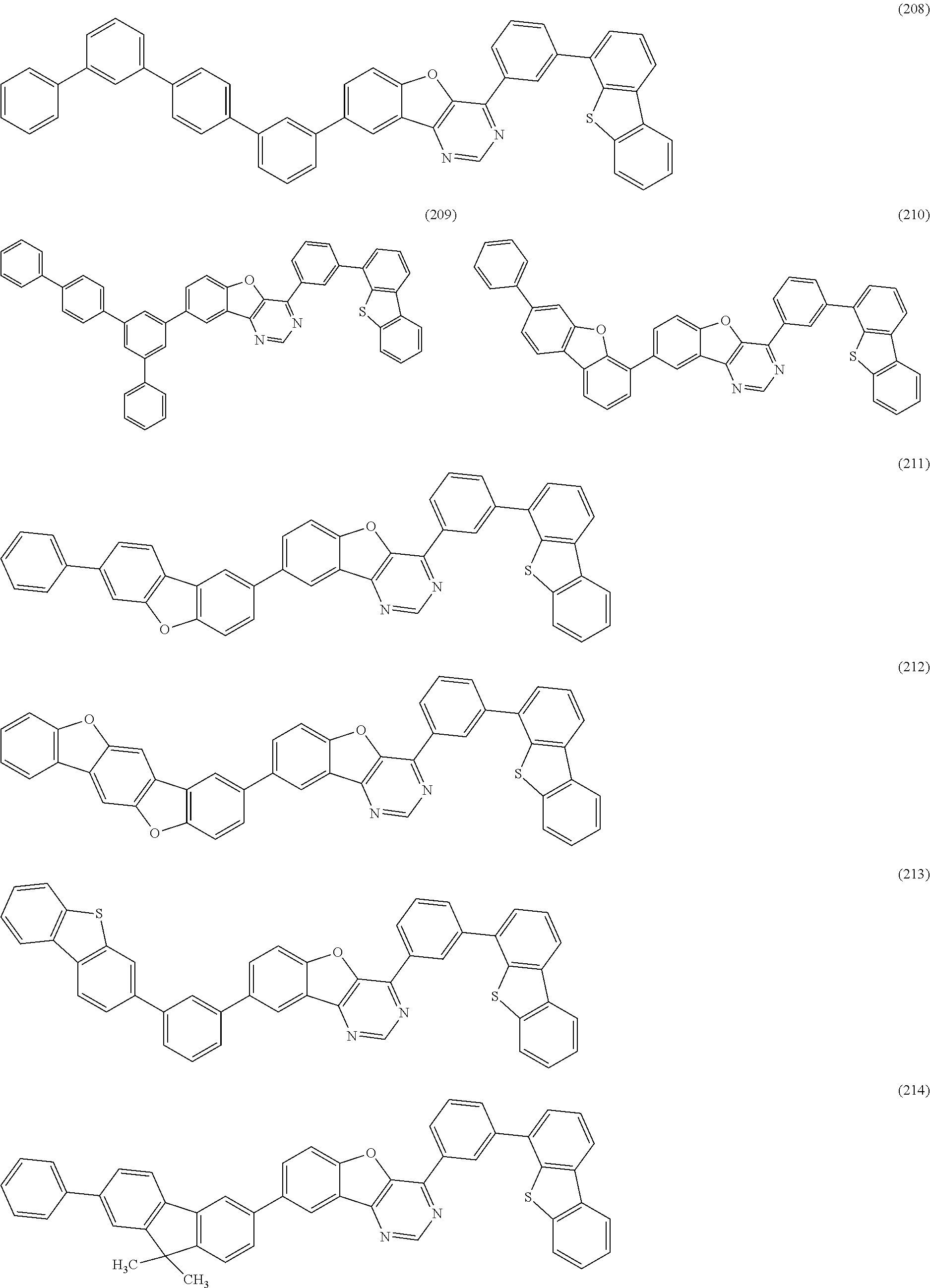

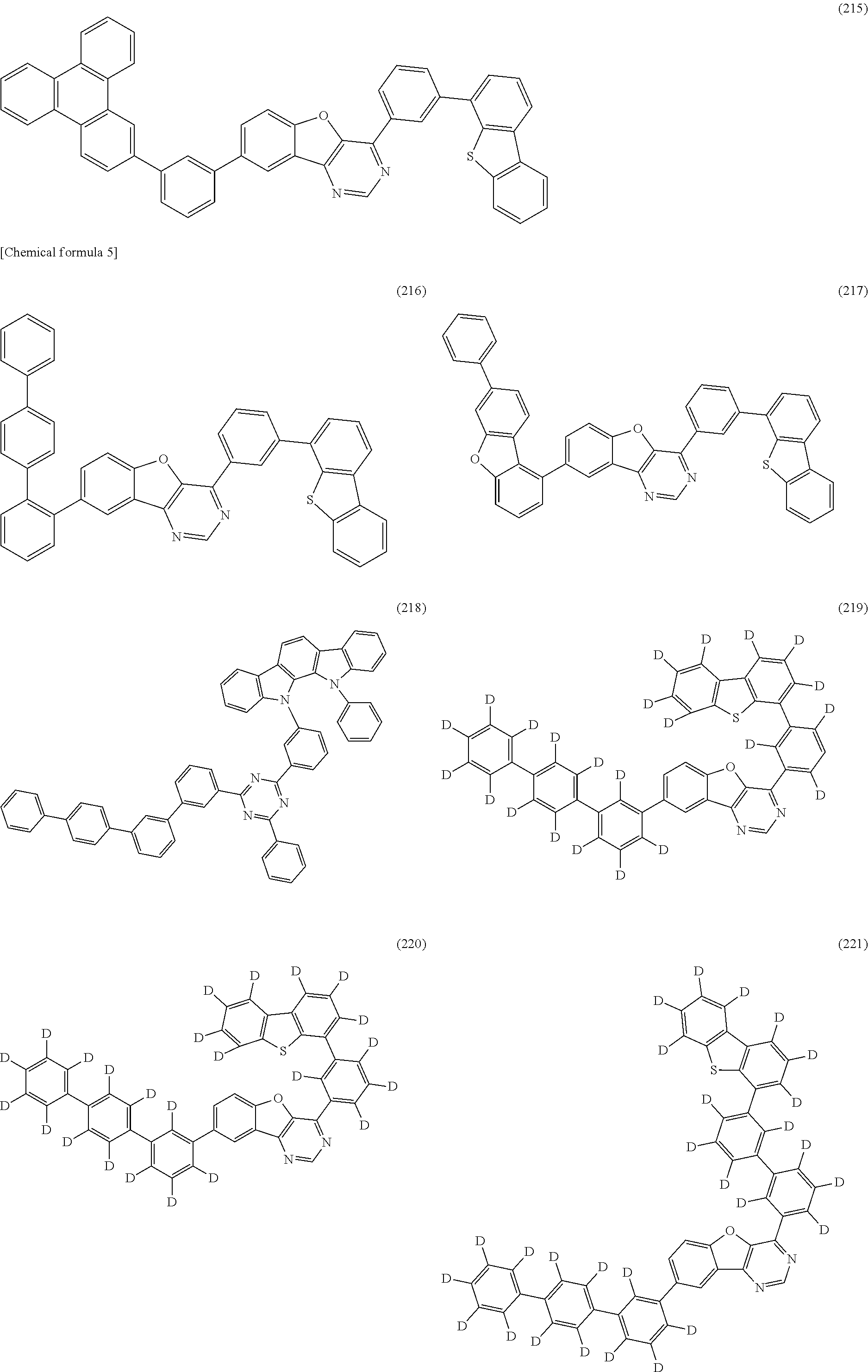

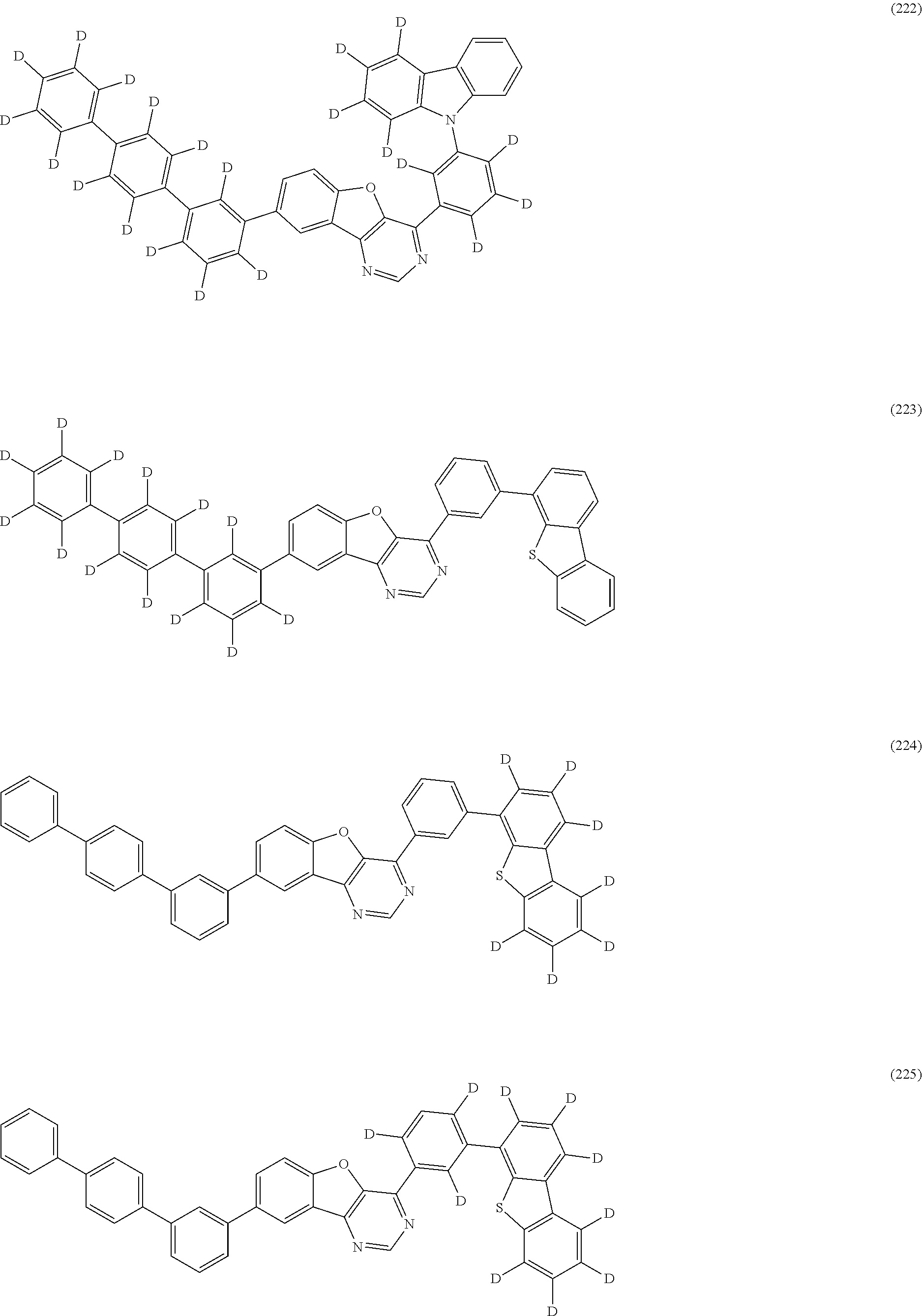

The above first organic compound may further include a substituent instead of hydrogen or deuterium. The substituent is preferably an alkyl group having 1 to 6 carbon atoms or a phenyl group.

The second organic compound is an organic compound having a hole-transport property. The second organic compound includes a bicarbazole skeleton and has a T₁ level higher than or equal to 2.20 eV and lower than or equal to 2.65 eV, preferably higher than or equal to 2.50 eV and lower than or equal to 2.60 eV.

The second organic compound, which includes a bicarbazole skeleton as described above, preferably includes a 3,3′-bicarbazole skeleton, further preferably a 9,9′-diaryl-9H,9′H-3,3′-bicarbazole skeleton. Note that the second organic compound has a T₁ level higher than or equal to 2.20 eV and lower than or equal to 2.65 eV, preferably higher than or equal to 2.50 eV and lower than or equal to 2.60 eV. Although the T₁ level of 9,9′-diphenyl-9H,9′H-3,3′-bicarbazole (PCCP) is 2.73 eV, the T₁ level is made less than that of PCCP while the 9,9′-diaryl-9H,9′H-3,3′-bicarbazole skeleton, which has the same structure as PCCP, is maintained, whereby the light-emitting device of one embodiment of the present invention can have a long lifetime. Note that the T₁ level is preferably higher than or equal to 2.20 eV for excitation of a green to yellow phosphorescent light-emitting material.

The second organic compound preferably includes an aromatic hydrocarbon group, further preferably a naphthyl group in particular. The naphthyl group is preferably bonded to nitrogen at the 9-position of at least one of the two carbazole skeletons. The lowest triplet excited level of the second organic compound is preferably derived from the aromatic hydrocarbon group.

The second organic compound preferably has a 1,1′:4′,1″-terphenyl skeleton. Examples of the second organic compound having such a structure include an organic compound having a phenyl group at the 7-position of a carbazole skeleton, like an organic compound represented by Structural Formula (304) below, and an organic compound having a parabiphenyl group at the 6-position of a carbazole skeleton, like an organic compound represented by Structural Formula (303) below. The lowest triplet excited level of the second organic compound is preferably derived from the 1,1′:4′,1″-terphenyl skeleton.

For example, an organic compound represented by any of Structural Formulae (300) to (305) below can be used as the second organic compound.

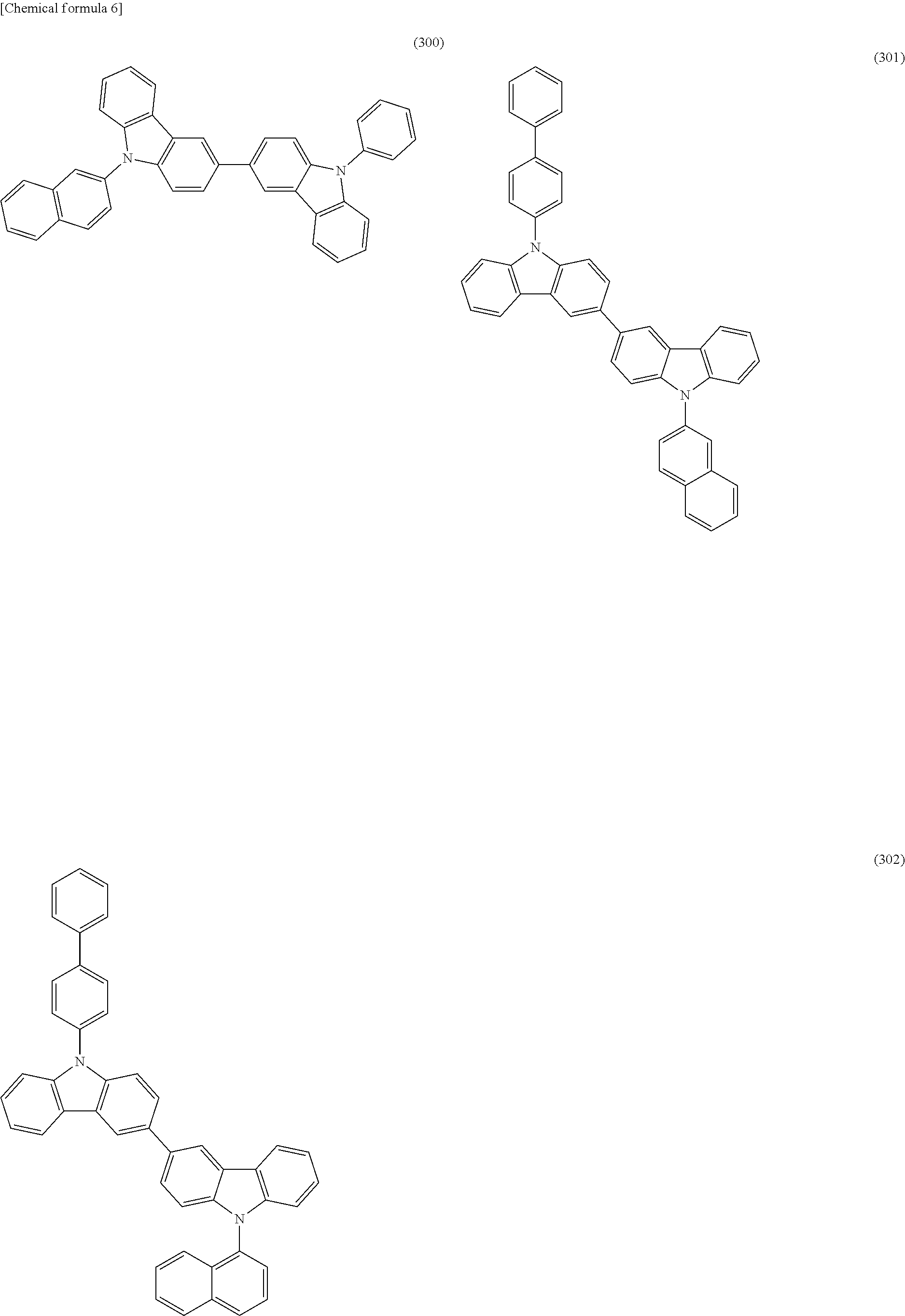 [SMILES: c1ccc(-n2c3ccccc3c3cc(-c4ccc5c(c4)c4ccccc4n5-c4ccc5ccccc5c4)ccc32)cc1 ; c1ccc(-c2ccc(-n3c4ccccc4c4cc(-c5ccc6c(c5)c5ccccc5n6-c5ccc6ccccc6c5)ccc43)cc2)cc1 ; c1ccc(-c2ccc(-n3c4ccccc4c4cc(-c5ccc6c(c5)c5ccccc5n6-c5cccc6ccccc56)ccc43)cc2)cc1]

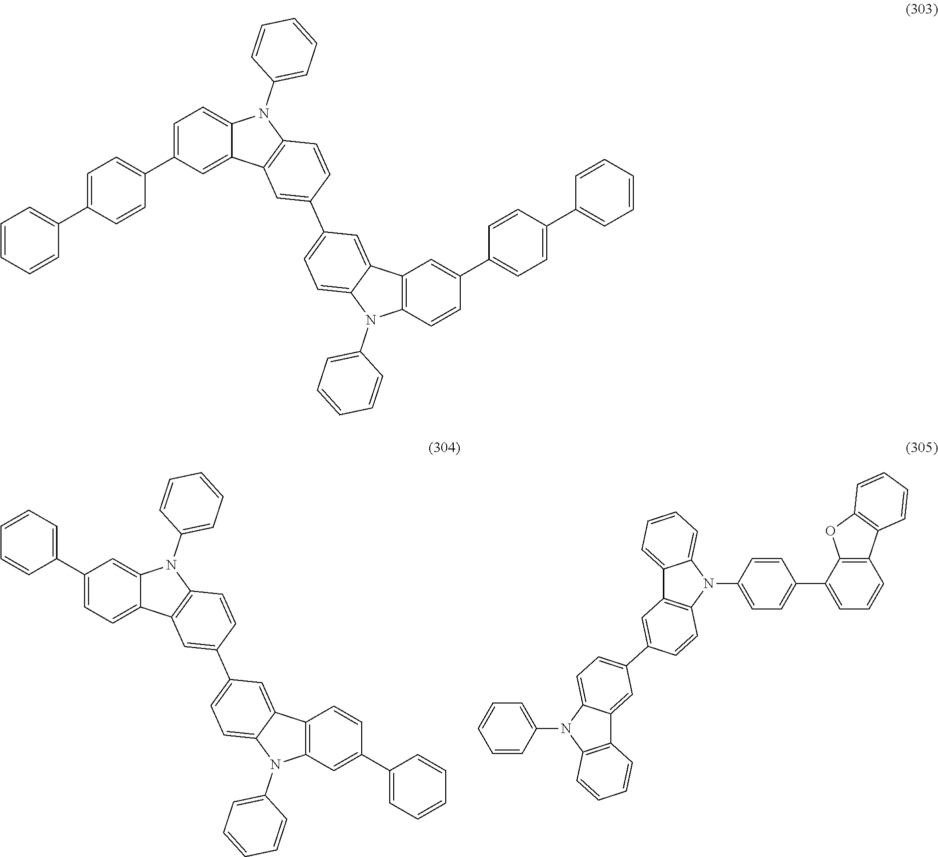 [SMILES: c1ccc(-c2ccc(-c3ccc4c(c3)c3cc(-c5ccc6c(c5)c5cc(-c7ccc(-c8ccccc8)cc7)ccc5n6-c5ccccc5)ccc3n4-c3ccccc3)cc2)cc1 ; c1ccc(-c2ccc3c4cc(-c5ccc6c(c5)c5ccc(-c7ccccc7)cc5n6-c5ccccc5)ccc4n(-c4ccccc4)c3c2)cc1 ; c1ccc(-n2c3ccccc3c3cc(-c4ccc5c(c4)c4ccccc4n5-c4ccc(-c5cccc6c5oc5ccccc56)cc4)ccc32)cc1]

Preferably, the first organic compound and the second organic compound in combination form an exciplex capable of exciting the aforementioned phosphorescent light-emitting substance. When the exciplex of the first organic compound and the second organic compound serves as an energy donor for the phosphorescent light-emitting substance, an increase in energy transfer efficiency or a reduction in driving voltage can be achieved, for example.

In that case, the S₁ level of the exciplex is higher than or equal the T₁ level of the aforementioned phosphorescent light-emitting substance; note that the S₁ level and the T₁ level of the exciplex are close to each other. Note that the difference between the S₁ level of the exciplex and the T₁ level of the aforementioned phosphorescent light-emitting substance is preferably less than or equal to 0.20 eV for a reduction in driving voltage.

As the phosphorescent light-emitting material, a yellow to green phosphorescent light-emitting material that emits light with a peak at 470 nm to 560 nm can be used. Any known material may be used as long as the material emits such phosphorescent light, and any of the following organometallic complexes can be preferably used, for example.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]); [2-d₃-methyl-8-(2-pyridinyl-κN)benzofuro[2,3-b]pyridine-κC]bis[2-(5-d₃-methyl-2-pyridinyl-κN2)phenyl-κC]iridium(III) (abbreviation: [Ir(5mppy-d₃)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)₂(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]); and a rare earth metal complex such as tris(acetylacetonato) (monophenanthroline)terbium(III) (abbreviation: [Tb(acac)₃(Phen)]). These compounds mainly emit yellow to green phosphorescent light and have an emission peak in the wavelength range of 470 nm to 570 nm. Note that organometallic iridium complexes including a pyrimidine skeleton have distinctively high reliability or emission efficiency and thus are particularly preferable. An organometallic iridium complex that includes a ligand in which hydrogen is substituted by deuterium is preferably used with the above first organic compound and the second organic compound for particularly high reliability.

The light-emitting device of one embodiment of the present invention having the above structure can be a green phosphorescent light-emitting device with a long lifetime.

Structures of the light-emitting device are described in detail.

FIGS. 1A to 1C are schematics of the light-emitting devices of embodiments of the present invention. Each of the light-emitting devices includes a first electrode 101 over an insulator 105, and an EL layer 103 between the first electrode 101 and a second electrode 102. The EL layer includes at least the light-emitting layer 113. The first electrodes of light-emitting devices are independent from each other, and the second electrode is formed as a layer shared by the light-emitting devices.

Furthermore, the EL layer 103 preferably include functional layers such as a hole-injection layer 111, a hole-transport layer 112, an electron-transport layer 114, and an electron-injection layer 115, as shown in FIG. 1A. The EL layer 103 may include functional layers other than the above functional layers, such as a hole-blocking layer, an electron-blocking layer, an exciton-blocking layer, and a charge-generation layer. Alternatively, any of the above layers may be omitted.

The light-emitting layer 113 included in the EL layer 103 of the light-emitting device includes the phosphorescent light-emitting substance, the first organic compound, and the second organic compound, as described in Embodiment 1. The phosphorescent light-emitting substance, the first organic compound, and the second organic compound are described in detail in Embodiment 1; therefore, repeated description will be omitted. The description in Embodiment 1 is to be referred to.

Although the first electrode 101 includes an anode and the second electrode 102 includes a cathode in this embodiment, the first electrode 101 may include a cathode and the second electrode 102 may include an anode. The first electrode 101 and the second electrode 102 each have a single-layer structure or a stacked-layer structure. In the case of the stacked-layer structure, a layer in contact with the EL layer 103 serves as an anode or a cathode. In the case where the electrodes each have the stacked-layer structure, there is no limitation on work functions of materials for layers other than the layer in contact with the EL layer 103, and the materials can be selected in accordance with required properties such as a resistance value, processing easiness, reflectivity, light-transmitting property, and stability.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium, (Ti), aluminum (Al), nitride of a metal material (e.g., titanium nitride), or the like can be used for the anode. The anode may be a stack of layers formed of any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111, which is described later, is used for a layer (typically, the hole-injection layer) in contact with the anode, an electrode material can be selected regardless of its work function.

The hole-injection layer 111 is provided in contact with the anode and has a function of facilitating injection of holes into the EL layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance having an electron-accepting property. Examples of the substance having an acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a high electron-accepting property and thus is preferable. Specific examples include α,α′,α″-1,2,3-cyclopropanetriylidenetris[4-cyano-2,3,5,6-tetrafluorobenzeneacetonitrile], a,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an acceptor property and an organic compound having a hole-transport property.

As the organic compound having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property used in the composite material preferably has a hole mobility higher than or equal to 1×10⁻⁶ cm²/Vs. The organic compound having a hole-transport property used in the composite material preferably has a fused aromatic hydrocarbon ring or a π-electron rich heteroaromatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to the nitrogen of the amine through an arylene group may be used. Note that the organic compound having a hole-transport property preferably has an N,N-bis(4-biphenyl)amino group to enable fabricating a light-emitting device with a long lifetime.

Specific examples of the hole-transport material include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

As the material having a hole-transport property, the following aromatic amine compounds can also be used, for example: N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances having an acceptor property, the organic compound having an acceptor property is easy to use because it is easily deposited by vapor deposition.

Note that the first compound may be used for the hole-injection layer 111.

The hole-transport layer 112 is formed using an organic compound having a hole-transport property. The organic compound having a hole-transport property preferably has a hole mobility higher than or equal to 1×10⁻⁶ cm²/Vs.

Examples of the material having a hole-transport property include compounds having an aromatic amine skeleton such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: pNCCBP), 9,9′-di-2-naphthyl-3,3′-9H,9′H-bicarbazole (abbreviation: BisPNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole; compounds having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property used for the composite material for the hole-injection layer 111 can also be suitably used as the material contained in the hole-transport layer 112.

As described above, the light-emitting layer 113 in the light-emitting device of one embodiment of the present invention includes the phosphorescent light-emitting substance, the first organic compound, and the second organic compound. When a display device is obtained using the light-emitting device of one embodiment of the present invention, the display device may include a light-emitting device including a light-emitting layer with another structure. When the light-emitting device of one embodiment of the present invention has a structure with two or more light-emitting layers in the EL layer 103, like a tandem light-emitting device, for example, one of the two light-emitting layers does not have the structure described in Embodiment 1 in some cases. In such cases, the light-emitting layer is a layer including a light-emitting substance and preferably includes a light-emitting substance and a host material. The light-emitting layer 113 may additionally include other materials. Alternatively, the light-emitting layer may be a stack of two layers with different compositions.

As the light-emitting substance, fluorescent substances, phosphorescent substances, substances exhibiting thermally activated delayed fluorescence (TADF), or other light-emitting substances may be used.

Examples of the material that can be used as a fluorescent substance in the light-emitting layer 113 are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(NN,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N′-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A fused heteroaromatic compound containing nitrogen and boron, especially a compound having a diaza-boranaphtho-anthracene skeleton, exhibits a narrow emission spectrum, emits blue light with favorable color purity, and can thus be used suitably. Examples of the compound include 5,9-diphenyl-5,9-diaza-13b-boranaphtho[3,2,1-de]anthracene (abbreviation: DABNA1), 9-([1,1′-diphenyl]-3-yl)-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N-diphenyl-5H,9H-[1,4]benzazaborino[2,3,4-kl]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′:4,5][1,4]benzazaborino[3,2-b]phenazaborin-7,13-diamine (abbreviation: ν-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′:8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer 113 are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), and tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-[1-{2,6-bis(1-methylethyl)phenyl}-1H-imidazol-2-yl-κN3]-4-cyanophenyl-κC) (abbreviation: CNImIr); an organometallic complex having a benzimizazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and an organometallic iridium complex in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)). These compounds emit blue phosphorescent light and have an emission peak in the wavelength range of 450 nm to 520 nm.

As the phosphorescent light-emitting substance, any of the phosphorescent light-emitting substances described in Embodiment 1 can be used. Note that organometallic iridium complexes including a pyrimidine skeleton have distinctively high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato] (dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range of 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

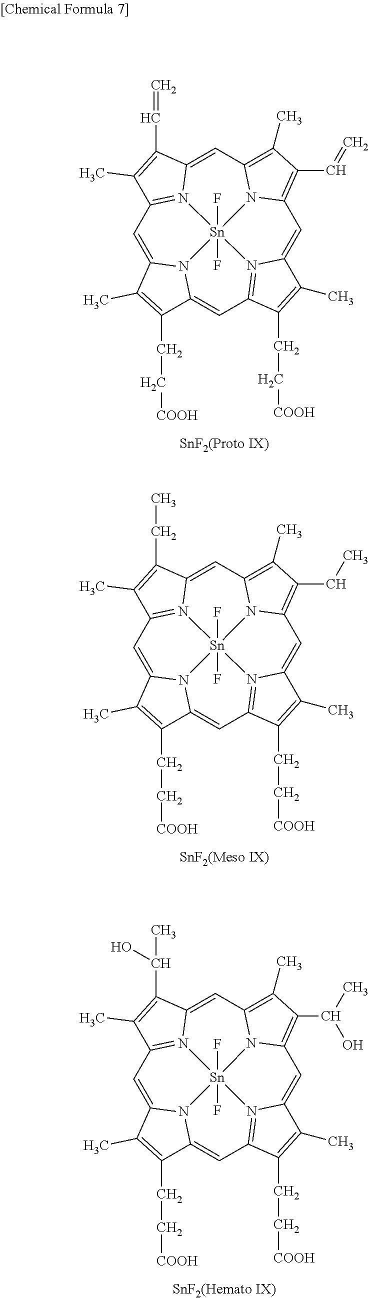

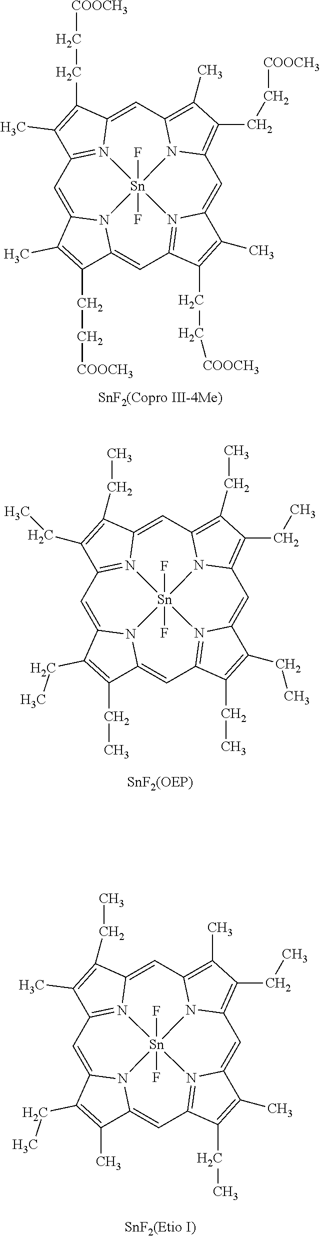

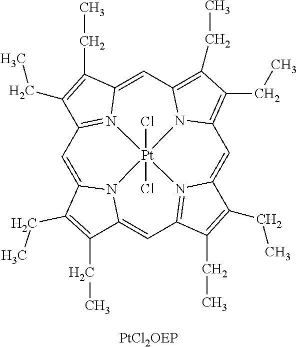

Alternatively, it is possible to use a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 9-[4-(4,6-diphenyl-1,3,5-triazin-2-yl)phenyl]-9′-phenyl-3,3′-bi-9H-carbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

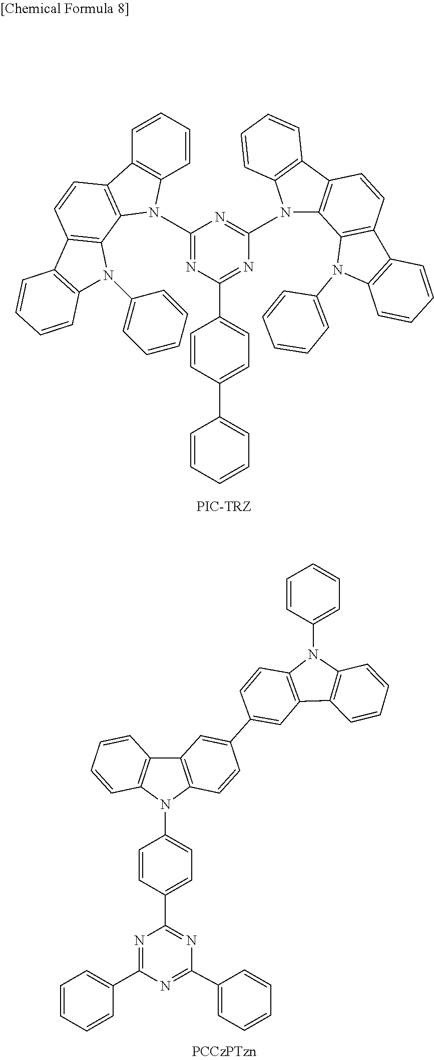 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

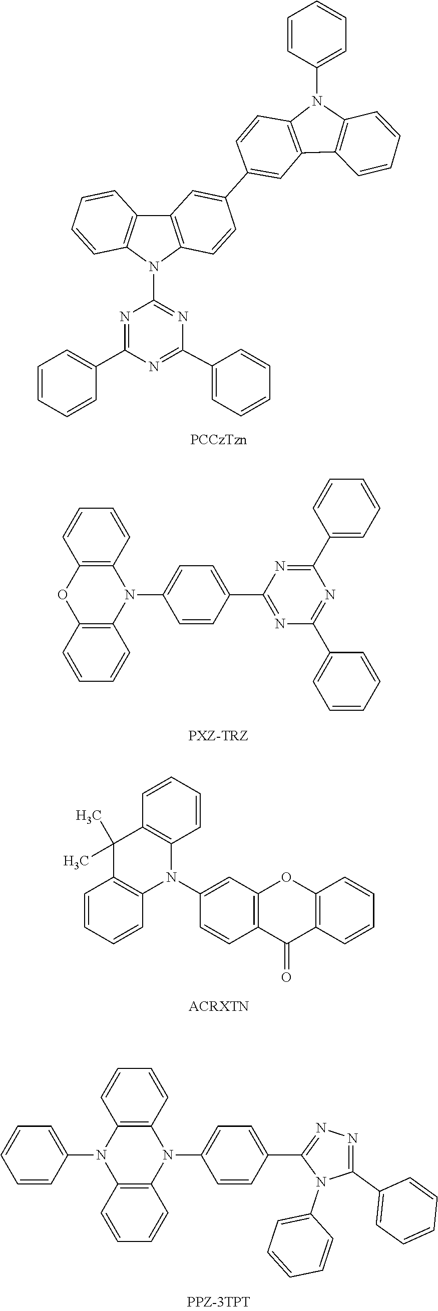 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21 ; c1ccc(-c2nnc(-c3ccc(N4c5ccccc5N(c5ccccc5)c5ccccc54)cc3)n2-c2ccccc2)cc1]

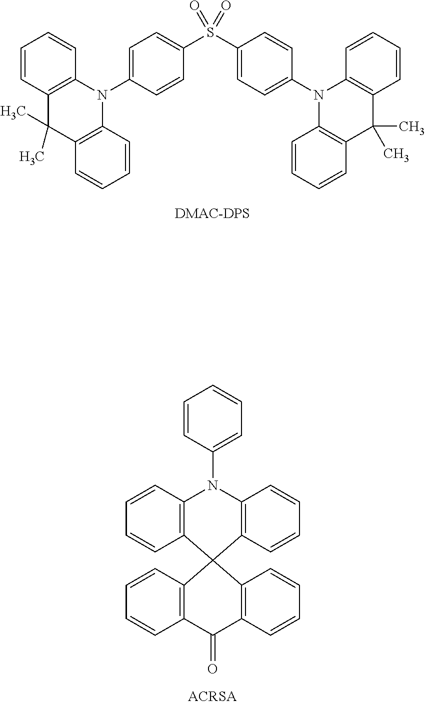

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

As the host material in the light-emitting layer, various carrier-transport materials such as materials having an electron-transport property and/or materials having a hole-transport property, and the TADF materials can be used.

The material with a hole-transport property is preferably an organic compound having an amine skeleton or a π-electron rich heteroaromatic ring skeleton, for example. As the π-electron rich heteroaromatic ring, a fused aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to the nitrogen of the amine through an arylene group may be used. Note that the organic compound having a hole-transport property preferably has an N,N-bis(4-biphenyl)amino group to enable fabricating a light-emitting device with a long lifetime.

Examples of such an organic compound include compounds having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), and 3,3′-bis(9-phenyl-9H-carbazole) (abbreviation: PCCP); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

The material having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring skeleton is preferably used. Examples of the organic compound having a π-electron deficient heteroaromatic ring skeleton include an organic compound that includes a heteroaromatic ring having a polyazole skeleton, an organic compound that includes a heteroaromatic ring having a pyridine skeleton, an organic compound that includes a heteroaromatic ring having a diazine skeleton, and an organic compound that includes a heteroaromatic ring having a triazine skeleton.

Among the above materials, the organic compound that includes a heteroaromatic ring having a diazine skeleton (a pyrimidine skeleton, a pyrazine skeleton, or a pyridazine skeleton), the organic compound that includes a heteroaromatic ring having a pyridine skeleton, and the organic compound that includes a heteroaromatic ring having a triazine skeleton have high reliability and thus are preferable. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of the organic compound having a π-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: COil), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalene-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), 2-[4-(2-triphenylenyl)phenyl]-1,10-phenanthroline (abbreviation: pTpPPhen), or 2,2′-(biphenyl-4,4′-diyl)bis(9-phenyl-1,10-phenanthroline) (abbreviation: PPhen2BP); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(DN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine} (abbreviation: 2,6(NP-PPm)2Py), 8-(1,1′:4′,1″-terphenyl-3-yl)-4-[3-(dibenzothiophen-4-yl)phenyl]-benzofuro[3,2-d]pyrimidine (abbreviation: 8mpTP-4mDBtPBfpm), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)-(biphenyl-3-yl)-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl]-3-yl)-4-phenyl-6-(8-[1,1′:4′,1″-terphenyl]-4-yl-1-dibenzofuranyl)-1,3,5-triazine (abbreviation: mBP-TPDBfTzn). The organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a good electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on a lowest-energy-side absorption band of the fluorescent substance, in which case excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring. Examples of the fused aromatic ring or the fused heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further fused to carbazole because the HOMO level thereof is shallower than that of carbazole by approximately 0.1 eV and thus holes enter the host material easily. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: α,N-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(2-naphthyl)-10-[3-(2-naphthyl)phenyl]anthracene (abbreviation: βN-mpNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength on a lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a substance having an electron-transport property. The material having an electron-transport property preferably has an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton.

As the organic compound having an electron-transport property that can be used for the electron-transport layer 114, any of the above-mentioned organic compounds that can be used as the organic compound having an electron-transport property in the light-emitting layer 113 can be used. Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of high stability.

Note that the electron-transport layer 114 may have a stacked-layer structure. A layer in the stacked-layer structure of the electron-transport layer 114, which is in contact with the light-emitting layer 113, may function as a hole-blocking layer. In the case where the electron-transport layer in contact with the light-emitting layer functions as a hole-blocking layer, the electron-transport layer is preferably formed using a material having a deeper HOMO level than a material contained in the light-emitting layer 113 by greater than or equal to 0.5 eV.

A layer that contains an alkali metal, an alkaline earth metal, or a compound thereof such as lithium fluoride (LiF), cesium fluoride (CsF), calcium fluoride (CaF₂), or 8-hydroxyquinolinato-lithium (abbreviation: Liq), a layer that contains 1,1′-pyridine-2,6-diyl-bis(1,3,4,6,7,8-hexahydro-2H-pyrimido[1,2-a]pyrimidine) (abbreviation: hpp2Py), or the like may be provided as the electron-injection layer 115. An electride or a layer that is formed using a substance having an electron-transport property and that includes an alkali metal, an alkaline earth metal, or a compound thereof can be used as the electron-injection layer 115. Examples of the electride include a substance in which electrons are added at high concentration to calcium oxide-aluminum oxide.

Note that as the electron-injection layer 115, it is possible to use a layer containing a substance that has an electron-transport property (preferably an organic compound having a bipyridine skeleton) and contains a fluoride of the alkali metal or the alkaline earth metal at a concentration higher than that at which the electron-injection layer 115 becomes in a microcrystalline state (50 wt % or higher). Since the layer has a low refractive index, a light-emitting device including the layer can have high external quantum efficiency.

The electron-injection layer 115 may be formed using any of the above substances alone, or any of the above substances contained in a layer including a substance having an electron-transport property.

Instead of the electron-injection layer 115, a charge-generation layer 116 may be provided (FIG. 1). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates.

Note that the charge-generation layer 116 preferably includes one or both of an electron-relay layer 118 and an n-type layer 119 in addition to the p-type layer 117.

The electron-relay layer 118 includes at least the substance having an electron-transport property and has a function of preventing an interaction between the n-type layer 119 and the p-type layer 117 and smoothly transferring electrons. The LUMO level of the substance having an electron-transport property included in the electron-relay layer 118 is preferably between the LUMO level of the acceptor substance in the p-type layer 117 and the LUMO level of a substance included in a layer of the electron-transport layer 114 that is in contact with the charge-generation layer 116. As a specific value of the energy level, the LUMO level of the substance having an electron-transport property in the electron-relay layer 118 is preferably higher than or equal to −5.0 eV, further preferably higher than or equal to −5.0 eV and lower than or equal to −3.0 eV. Note that as the substance having an electron-transport property in the electron-relay layer 118, a phthalocyanine-based material or a metal complex having a metal-oxygen bond and an aromatic ligand is preferably used.

The n-type layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the n-type layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

The second electrode 102 is an electrode including a cathode. The second electrode 102 may have a stacked-layer structure, in which case a layer in contact with the EL layer 103 functions as a cathode. For the cathode, a metal, an alloy, an electrically conductive compound, or a mixture thereof each having a low work function (specifically, lower than or equal to 3.8 eV) or the like can be used. Specific examples of such a cathode material include elements belonging to Group 1 or 2 of the periodic table, such as alkali metals (e.g., lithium (Li) or cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be deposited by a dry process such as a vacuum evaporation method or a sputtering method, an ink-jet method, a spin coating method, or the like. Alternatively, a wet process using a sol-gel method or a wet process using a paste of a metal material may be employed.

The EL layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different deposition methods may be used to form the electrodes or the layers described above.

Next, an embodiment of a light-emitting device with a structure in which a plurality of light-emitting units are stacked (this type of light-emitting device is also referred to as a stacked or tandem device) is described with reference to FIG. 1C. This organic EL element includes a plurality of light-emitting units between an anode and a cathode. One light-emitting unit has substantially the same structure as the EL layer 103 illustrated in FIG. 1A. In other words, the organic EL element illustrated in FIG. 1C includes a plurality of light-emitting units, and the organic EL elements illustrated in FIGS. 1A and 1B each include a single light-emitting unit.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 1A, and the materials given in the description for FIG. 1A can be used. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 1C, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 1B. A composite material of an organic compound and a metal oxide used in the p-type layer enables low-voltage driving and low-current driving because of having an excellent carrier-injection property and an excellent carrier-transport property. In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

The charge-generation layer 513 preferably includes the n-type layer 119. In the case where the n-type layer 119 is formed in the intermediate layer, the n-type layer 119 functions as the electron-injection layer in the light-emitting unit on the anode side; thus, an electron-injection layer is not necessarily formed in the light-emitting unit on the anode side (here, the first light-emitting unit 511).

The light-emitting device having two light-emitting units is described with reference to FIG. 1C; however, one embodiment of the present invention can also be applied to a light-emitting device in which three or more light-emitting units are stacked. When a plurality of light-emitting units partitioned by the charge-generation layer 513 are provided between a pair of electrodes as in the light-emitting device of this embodiment, it is possible to provide a long-life device which can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The EL layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

### Embodiment 2

In this embodiment, a display device including the light-emitting device described in Embodiment 1 is described.

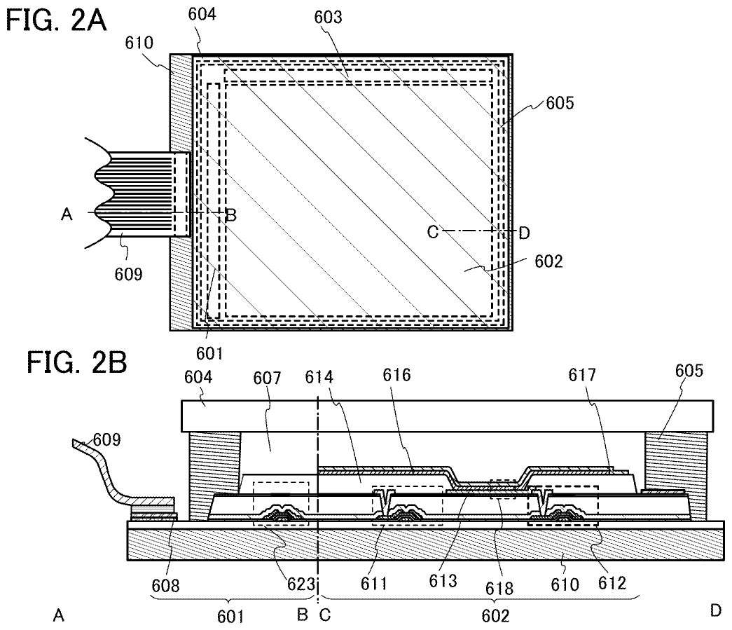

In this embodiment, the display device manufactured using the light-emitting device described in Embodiment 1 is described with reference to FIGS. 2A and 2B. Note that FIG. 2A is a top view of the display device and FIG. 2B is a cross-sectional view taken along the lines A-B and C-D in FIG. 2A. This display device includes a driver circuit portion (source line driver circuit) 601, a pixel portion 602, and a driver circuit portion (gate line driver circuit) 603, which are to control light emission of a light-emitting device and illustrated with dotted lines. Reference numeral 604 denotes a sealing substrate; 605, a sealing material; and 607, a space surrounded by the sealing material 605.

Reference numeral 608 denotes a lead wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display device in the present specification includes, in its category, not only the display device itself but also the display device provided with the FPC or the PWB.

Next, a cross-sectional structure is described with reference to FIG. 2B. The driver circuit portions and the pixel portion are formed over an element substrate 610; FIG. 2B shows the source line driver circuit 601, which is a driver circuit portion, and one pixel in the pixel portion 602.

The element substrate 610 may be a substrate containing glass, quartz, an organic resin, a metal, an alloy, or a semiconductor or a plastic substrate formed of fiber reinforced plastic (FRP), poly(vinyl fluoride) (PVF), polyester, or acrylic resin.

The structure of transistors used in pixels and driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable that a semiconductor having crystallinity be used, in which case deterioration of the transistor characteristics can be suppressed.

Here, an oxide semiconductor is preferably used for semiconductor devices such as the transistors provided in the pixels and driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed in each display region is maintained. As a result, an electronic apparatus with extremely low power consumption can be obtained.

For stable characteristics of the transistor, for example, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the driver circuit 601. In addition, the driver circuit may be formed with any of a variety of circuits such as a CMOS circuit, a PMOS circuit, or an NMOS circuit. Although a driver integrated type in which the driver circuit is formed over the substrate is illustrated in this embodiment, the driver circuit is not necessarily formed over the substrate, and the driver circuit can be formed outside, not over the substrate.

The pixel portion 602 includes a plurality of pixels including a switching FET 611, a current controlling FET 612, and a first electrode 613 electrically connected to a drain of the current controlling FET 612. One embodiment of the present invention is not limited to the structure. The pixel portion 602 may include three or more FETs and a capacitor in combination.

Note that to cover an end portion of the first electrode 613, an insulator 614 is formed, for which a positive photosensitive acrylic resin film is used here.

In order to improve coverage with an EL layer or the like which is formed later, the insulator 614 is formed to have a curved surface with curvature at its upper or lower end portion. For example, in the case where positive photosensitive acrylic resin is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a second electrode 617 are formed over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask, an inkjet method, and a spin coating method. The EL layer 616 has the structure described in Embodiment 1. As another material included in the EL layer 616, a low molecular compound or a high molecular compound (including an oligomer or a dendrimer) may be used.

As a material used for the second electrode 617, which is formed over the EL layer 616 and functions as a cathode, a material having a low work function (e.g., Al, Mg, Li, and Ca, or an alloy or a compound thereof, such as MgAg, MgIn, and AlLi) is preferably used. In the case where light generated in the EL layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting device is formed with the first electrode 613, the EL layer 616, and the second electrode 617. The light-emitting device is the light-emitting device described in Embodiment 1. In the display device of this embodiment, the pixel portion, which includes a plurality of light-emitting devices, may include both the light-emitting device described in Embodiment 1 and a light-emitting device having a different structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 may be filled with a filler, or may be filled with an inert gas (such as nitrogen or argon), or the sealing material. It is preferable that the sealing substrate be provided with a recessed portion and a drying agent be provided in the recessed portion, in which case deterioration due to influence of moisture can be suppressed.

An epoxy-based resin or glass frit is preferably used for the sealing material 605. It is preferable that such a material not be permeable to moisture or oxygen as much as possible. As the sealing substrate 604, a glass substrate, a quartz substrate, or a plastic substrate formed of fiber reinforced plastic (FRP), poly(vinyl fluoride) (PVF), polyester, and acrylic resin can be used.

Although not illustrated in FIGS. 2A and 2B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material through which an impurity such as water does not permeate easily. Thus, diffusion of an impurity such as water from the outside into the inside can be effectively suppressed.

As a material of the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a deposition method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display device manufactured using the light-emitting device described in Embodiment 1 can be obtained.

The display device in this embodiment is manufactured using the light-emitting device described in Embodiment 1 and thus can have favorable characteristics. Specifically, since the light-emitting device described in Embodiment 1 has high emission efficiency, the display device can achieve low power consumption. Since the light-emitting device described in Embodiment 1 has high reliability, the display device can be highly reliable.

This embodiment can be freely combined with any of the other embodiments.

### Embodiment 3

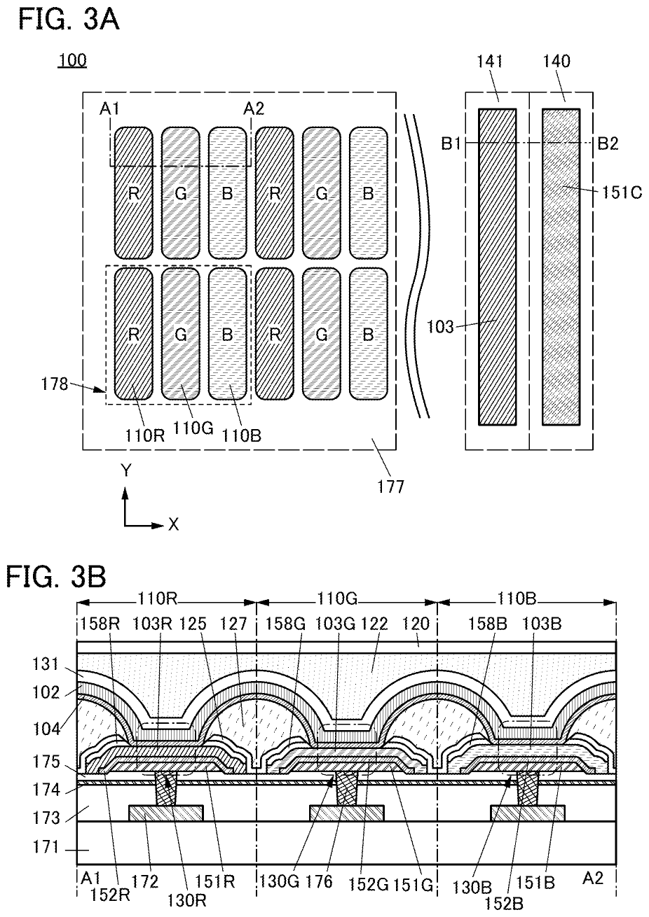

As illustrated in FIGS. 3A and 3B, a plurality of the light-emitting devices 130 are formed over the insulating layer 175 to constitute a display device. In this embodiment, the display device of another embodiment of the present invention will be described in detail.

A display device 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and Y, and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 3A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a region 141 is provided and a connection portion 140 may also be provided. The region 141 is provided between the pixel portion 177 and the connection portion 140. The EL layer 103 is provided in the region 141. A conductive layer 151C is provided in the connection portion 140.

Although FIG. 3A illustrates an example where the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 3B is an example of a cross-sectional view along the dashed-dotted line A1-A2 in FIG. 3A. As illustrated in FIG. 3A, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 3B shows cross sections of a plurality of the inorganic insulating layers 125 and a plurality of the insulating layers 127, the inorganic insulating layers 125 are preferably connected to each other and the insulating layers 127 are connected to each other when the display device 100 is seen from above. In other words, the inorganic insulating layer 125 and the insulating layer 127 preferably have an opening over a first electrode.

In FIG. 3B, a light-emitting device 130R, a light-emitting device 130G, and a light-emitting device 130B are shown as the light-emitting devices 130. The light-emitting devices 130R, 130G, and 130B emit light of the respective colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom emission type.

The light-emitting device 130R includes the first electrode (pixel electrode) including a conductive layer 151R and a conductive layer 152R, an EL layer 103R over the first electrode, the common layer 104 over the EL layer 103R, and the second electrode (common electrode) 102 over the common layer 104. Although the common layer 104 is not necessarily provided, it is preferable to provide the common layer 104 to reduce damage to the EL layer 103R during processing. In the case where the common layer 104 is provided, the common layer 104 is preferably an electron-injection layer.

The light-emitting layer in the light-emitting device 130G has the structure described in Embodiment 1, and the light-emitting device 130G includes the first electrode (pixel electrode) including a conductive layer 151G and a conductive layer 152G, an EL layer 103G over the first electrode, the common layer 104 over the EL layer 103G, and the second electrode (common electrode) 102 over the common layer 104. Although the common layer 104 is not necessarily provided, it is preferable to provide the common layer 104 to reduce damage to the EL layer 103G during processing. In the case where the common layer 104 is provided, the common layer 104 is preferably an electron-injection layer. Furthermore, in the case where the common layer 104 is provided, a stack of the EL layer 103G and the common layer 104 corresponds to the EL layer 103 described in Embodiment 1.

The light-emitting device 130B includes the first electrode (pixel electrode) including a conductive layer 151B and a conductive layer 152B, an EL layer 103B over the first electrode, the common layer 104 over the EL layer 103B, and the second electrode (common electrode) 102 over the common layer 104. Although the common layer 104 is not necessarily provided, it is preferable to provide the common layer 104 to reduce damage to the EL layer 103B during processing. In the case where the common layer 104 is provided, the common layer 104 is preferably an electron-injection layer.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The EL layers 103R, 103G, and 103B are island-shaped layers that are independent of each other for the respective colors. Providing the island-shaped EL layer 103 in each of the light-emitting devices 130 can suppress leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped EL layer 103 is formed by forming an EL film and processing the EL film by a photolithography technique.

The EL layer 103 is preferably provided to cover the top surface and the side surface of the first electrode (pixel electrode) of the light-emitting device 130. In this case, the aperture ratio of the display device 100 can be easily increased as compared to the structure where an end portion of the EL layer 103 is positioned inward from an end portion of the pixel electrode. Covering the side surface of the pixel electrode of the light-emitting device 130 with the EL layer 103 can inhibit the pixel electrode from being in contact with the second electrode 102; hence, a short circuit of the light-emitting device 130 can be inhibited.

In the display device of one embodiment of the present invention, the first electrode (pixel electrode) of the light-emitting device preferably has a stacked-layer structure. For example, in the example illustrated in FIG. 3B, the first electrode of the light-emitting device 130 is a stack of the conductive layer 151 and the conductive layer 152.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers containing different materials. In that case, the conductive layer 151 may include a layer formed using a material that can be used for the conductive layer 152, such as a conductive oxide, and the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The conductive layer 151 preferably has a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the EL layer 103 provided along the side surface of the conductive layer 152 can be improved.

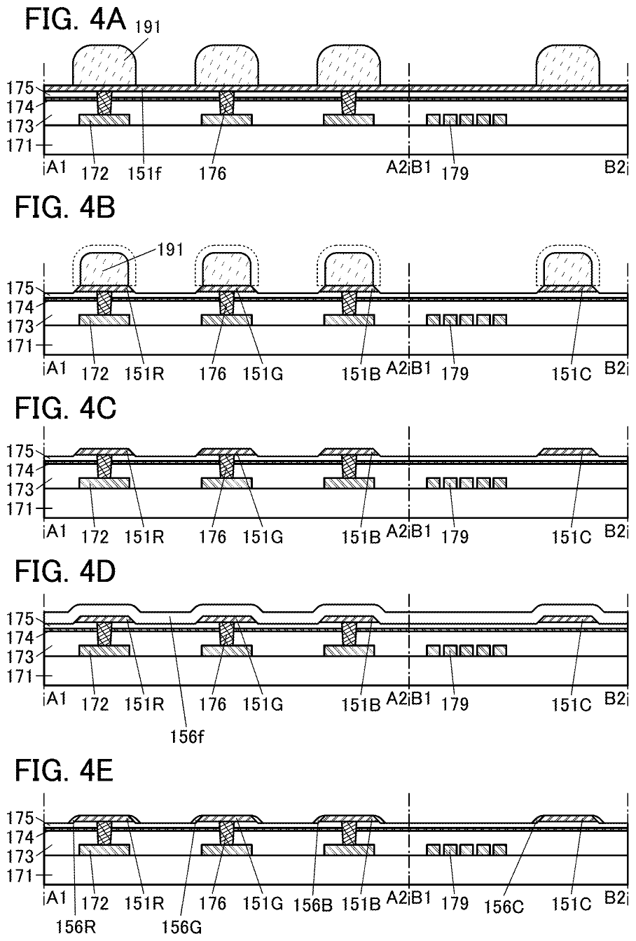

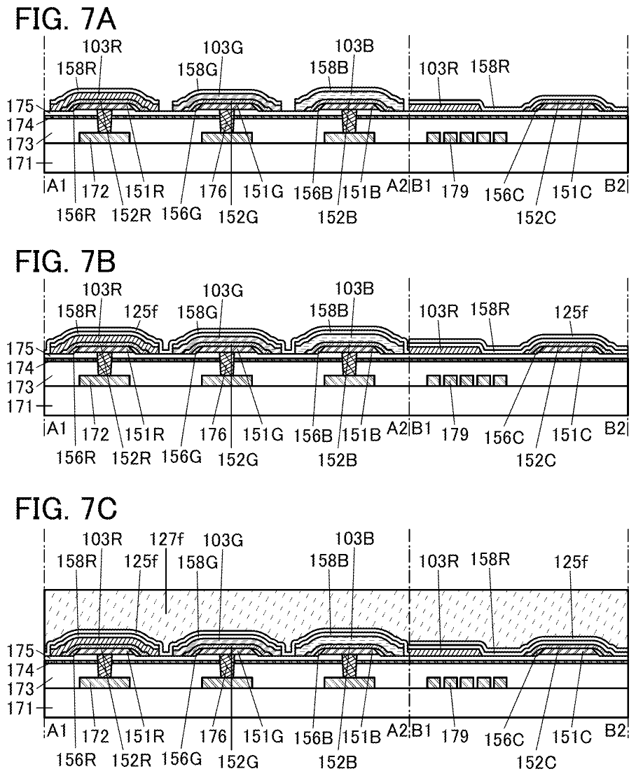

Next, an exemplary manufacturing method of the display device 100 having the structure illustrated in FIG. 4A is described with reference to FIGS. 7A to 7C, FIGS. 8A to 8C, FIGS. 9A to 9C, FIGS. 10A and 10B, FIGS. 11A and 11B, FIG. 12, FIG. 13, FIG. 14, FIG. 15, and FIGS. 16A to 16D.

### Fabrication Method Example 1

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography technique, for example.

As light used for exposure in the photolithography technique, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used.

For etching of thin films, a dry etching method, a wet etching method, a sandblast method, or the like can be used.

First, as illustrated in FIG. 4A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, openings reaching the conductive layer 172 are formed in the insulating layers 175, 174, and 173. Then, the plugs 176 are formed to fill the openings.

Next, a conductive film 151f to be the conductive layers 151R, 151G, 151B, and 151C is formed over the plugs 176 and the insulating layer 175. A metal material can be used for the conductive film 151f, for example.

Then, a resist mask 191 is formed over a conductive film 151cf. The resist mask 191 can be formed by application of a photosensitive material (photoresist), light exposure, and development.

Subsequently, as illustrated in FIG. 4B, the conductive film 151f in a region not overlapping with the resist mask 191 is removed, for example. In this manner, the conductive layer 151 is formed.

Next, the resist mask 191 is removed as illustrated in FIG. 4C. The resist mask 191 can be removed by ashing using oxygen plasma, for example.

Then, as illustrated in FIG. 4D, an insulating film 156f to be an insulating layer 156R, an insulating layer 156G, an insulating layer 156B, and an insulating layer 156C is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 4E, the insulating film 156f is processed to form the insulating layers 156R, 156G, 156B, and 156C.

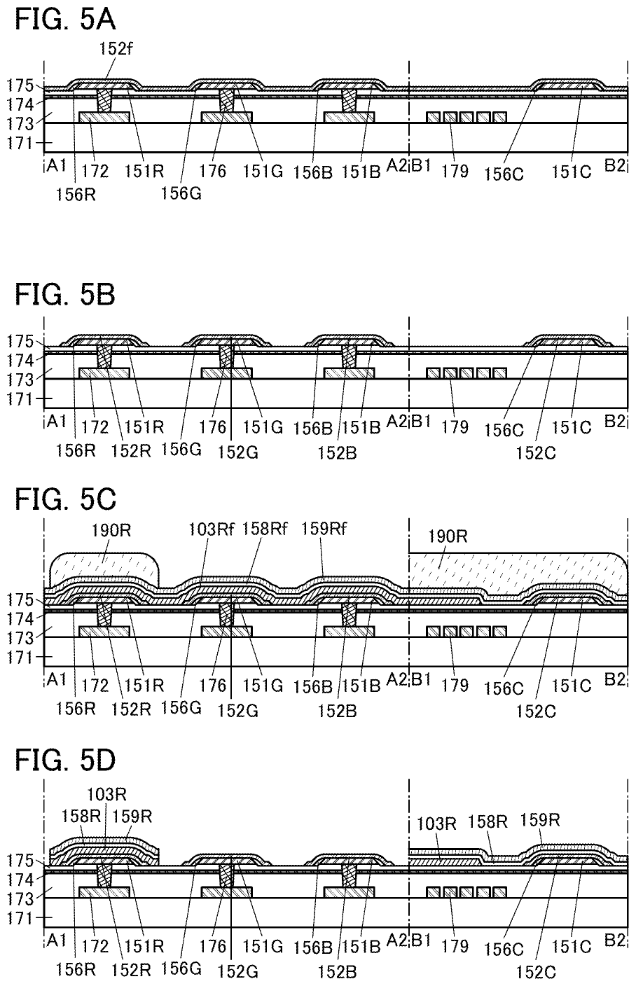

Next, as illustrated in FIG. 5A, a conductive film 152f is formed over the conductive layers 151R, 151G, 151B, and 151C and the insulating layers 156R, 156G, 156B, 156C, and 175. A conductive oxide can be used for the conductive film 152f, for example. The conductive film 152f may have a stacked-layer structure.

Then, as illustrated in FIG. 5B, the conductive film 152f is processed, so that the conductive layers 152R, 152G, 152B, and 152C are formed.

Next, as illustrated in FIG. 5C, an EL film 103Rf is formed over the conductive layers 152R, 152G, and 152B and the insulating layer 175. As illustrated in FIG. 5C, the EL film 103Rf is not formed over the conductive layer 152C.

Then, as illustrated in FIG. 5C, a sacrificial film 158f and a mask film 159Rf are formed.

Providing the sacrificial film 158Rf over the EL film 103Rf can reduce damage to the EL film 103Rf in the manufacturing process of the display device, resulting in an increase in the reliability of the light-emitting device.

As the sacrificial film 158Rf, a film that is highly resistant to the process conditions for the EL film 103Rf, specifically, a film having high etching selectivity with respect to the EL film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the EL film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., yet still further preferably lower than or equal to 80° C.

The sacrificial film 158Rf and the mask film 159Rf are preferably films that can be removed by a wet etching method.

Note that the sacrificial film 158Rf that is formed over and in contact with the EL film 103Rf is preferably formed by a formation method that is less likely to damage the EL film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a low-melting-point material such as aluminum or silver. It is preferable to use a metal material that can block ultraviolet rays for one or both of the sacrificial film 158Rf and the mask film 159Rf, in which case the EL film 103Rf can be inhibited from being irradiated with ultraviolet rays and deterioration of the EL film 103Rf can be suppressed.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M(M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the EL film 103Rf is higher than that of a nitride insulating film.

Subsequently, a resist mask 190R is formed as illustrated in FIG. 5C. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device.

Next, as illustrated in FIG. 5D, part of the mask film 159Rf is removed using the resist mask 190R, so that a mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

The use of a wet etching method can reduce damage to the EL film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the EL film 103Rf can be inhibited by not using a gas containing oxygen as the etching gas.

The resist mask 190R can be removed by a method similar to that for the resist mask 191.

Next, as illustrated in FIG. 5D, the EL film 103Rf is processed to form the EL layer 103R. For example, part of the EL film 103Rf is removed using the mask layer 159R and the sacrificial layer 158R as a hard mask, whereby the EL layer 103R is formed.

Accordingly, as illustrated in FIG. 5D, the stacked-layer structure of the EL layer 103R, the sacrificial layer 158R, and the mask layer 159R remains over the conductive layer 152R. The conductive layers 152G and 152B are exposed.

The EL film 103Rf is preferably processed by anisotropic etching. Anisotropic dry etching is particularly preferable. Alternatively, wet etching may be used.

In the case of using a dry etching method, deterioration of the EL film 103Rf can be suppressed by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the EL film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

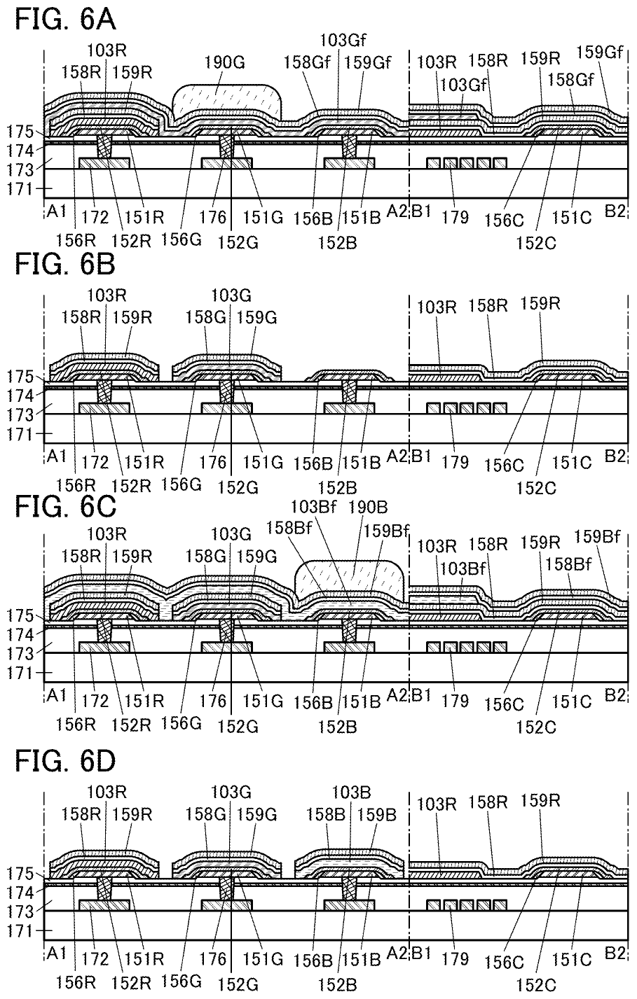

Then, as illustrated in FIG. 6A, an EL film 103Gf to be the EL layer 103G is formed.

The EL film 103Gf can be formed by a method similar to that for forming the EL film 103Rf. The EL film 103Gf can have a structure similar to that of the EL film 103Rf.

Subsequently, a sacrificial film 158Gf and a mask film 159Gf are formed in this order. A resist mask 190G is then formed at a position overlapping with the conductive layer 152G. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

Subsequently, as illustrated in FIG. 6B, part of the mask film 159Gf is removed using the resist mask 190G, so that a mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the EL film 103Gf is processed to form the EL layer 103G.

Then, an EL film 103Bf is formed as illustrated in FIG. 6C. The EL film 103Bf can be formed by a method similar to that for forming the EL film 103Rf. The EL film 103Bf can have a structure similar to that of the EL film 103Rf.

Subsequently, a sacrificial film 158Bf and a mask film 159Bf are formed in this order as illustrated in FIG. 6C. A resist mask 190B is then formed at a position overlapping with the conductive layer 152B. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

Subsequently, as illustrated in FIG. 6D, part of the mask film 159Bf is removed using the resist mask 190B, so that a mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the EL film 103Bf is processed to form the EL layer 103B. For example, part of the EL film 103Bf is removed using the mask layer 159B and the sacrificial layer 158B as a hard mask, whereby the EL layer 103B is formed.

Accordingly, the stacked-layer structure of the EL layer 103B, the sacrificial layer 158B, and the mask layer 159B remains over the conductive layer 152B. The mask layers 159R and 159G are exposed.

The side surfaces of the EL layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the EL layers 103R, 103G, and 103B, which are formed by a photolithography technique as described above, can be reduced to less than or equal to 8 μm, less than or equal to 5 μm, less than or equal to 3 μm, less than or equal to 2 μm, or less than or equal to 1 μm. Here, the distance can be specified, for example, by the distance between opposite end portions of two adjacent layers among the EL layers 103R, 103G, and 103B. Reducing the distance between the island-shaped EL layers makes it possible to provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

Next, the mask layers 159R, 159G, and 159B are preferably removed as illustrated in FIG. 7A.

The step of removing the mask layers can be performed by a method similar to that for the step of processing the mask layers. Specifically, by using a wet etching method, damage caused to the EL layer 103 at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 7B.

Then, as illustrated in FIG. 7C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness of 3 nm or more, 5 nm or more, or 10 nm or more and 200 nm or less, 150 nm or less, 100 nm or less, or 50 nm or less is preferably formed at a substrate temperature in the above-described range.

The inorganic insulating film 125f is preferably formed by an ALD method, for example. An ALD method is preferably used, in which case deposition damage is reduced and a film with good coverage can be formed. As the inorganic insulating film 125f, an aluminum oxide film is preferably formed by an ALD method, for example.

The insulating film 127f is preferably formed by the aforementioned wet process. For example, the insulating film 127f is preferably formed by spin coating using a photosensitive material, and specifically preferably formed using a photosensitive resin composition containing an acrylic resin.

Then, part of the insulating film 127f is exposed to visible light or ultraviolet rays. The insulating layer 127 is formed in regions that are sandwiched between any two of the conductive layers 152R, 152G, and 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

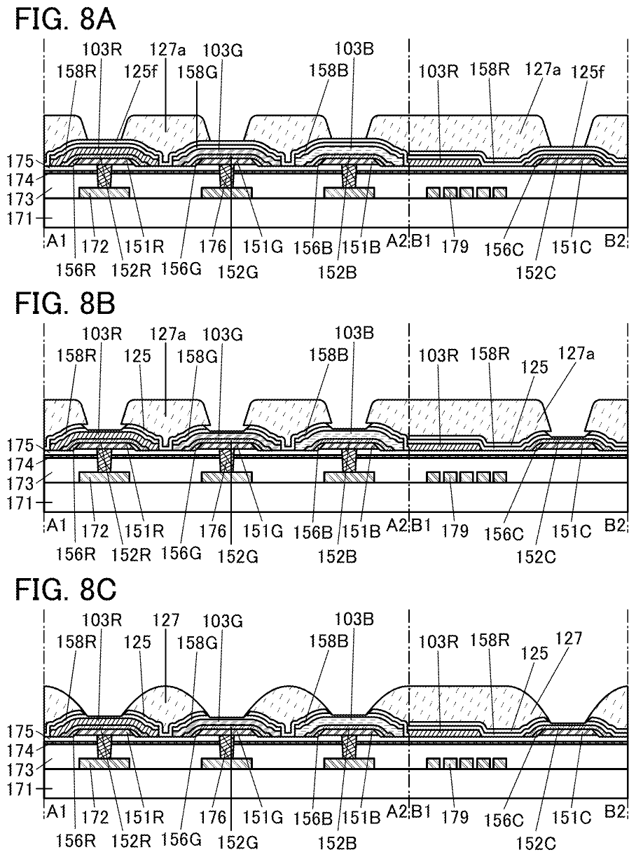

Next, the region of the insulating film 127f exposed to light is removed by development as illustrated in FIG. 8A, so that an insulating layer 127a is formed.

Next, as illustrated in FIG. 8B, etching treatment is performed with the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the EL layers 103R, 103G, and 103B, as compared to the case of using a dry etching method. Wet etching can be performed using an alkaline solution or an acid solution, for example.

It is preferable that the sacrificial layers 158R, 158G, and 158B not be removed completely by the first etching treatment, and the etching treatment be stopped when the thickness of the sacrificial layers 158R, 158G, and 158B is reduced. The corresponding sacrificial layers 158R, 158G, and 158B remain over the EL layers 103R, 103G, and 103B in this manner, whereby the EL layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen into the EL layers 103R, 103G, and 103B can be suppressed.

Then, heat treatment (also referred to as post-baking) is performed. The heat treatment can change the insulating layer 127a into the insulating layer 127 having a tapered side surface (FIG. 8C). The heat treatment is conducted at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., and further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the EL layers 103R, 103G, and 103B can be prevented from being damaged and deteriorating in the heat treatment. This increases the reliability of the light-emitting device.

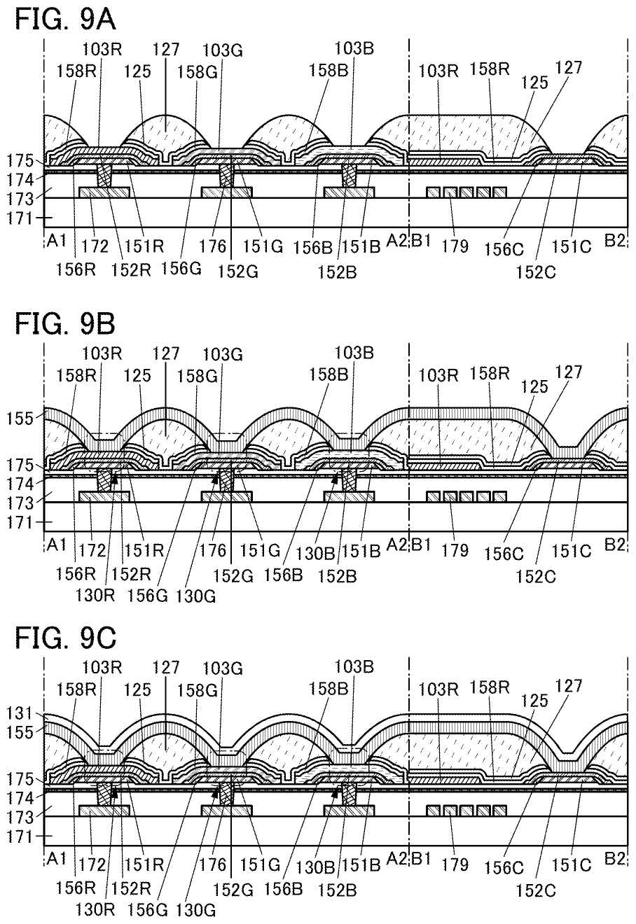

Next, as illustrated in FIG. 9A, etching treatment is performed with the insulating layer 127 as a mask to remove part of the sacrificial layers 158R, 158G, and 158B. Thus, openings are formed in the sacrificial layers 158R, 158G, and 158B, and the top surfaces of the EL layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 9A illustrates an example in which part of an end portion of the sacrificial layer 158G (specifically, a tapered portion formed by the first etching treatment) is covered with the insulating layer 127 and a tapered portion formed by the second etching treatment is exposed.

The second etching treatment is performed by wet etching. The use of a wet etching method can reduce damage to the EL layers 103R, 103G, and 103B, as compared to the case of using a dry etching method. Wet etching can be performed using an alkaline solution or an acid solution, for example.

Next, as illustrated in FIG. 9B, a common electrode 155 is formed over the EL layers 103R, 103G, and 103B, the conductive layer 152C, and the insulating layer 127. The common electrode 155 can be formed by a sputtering method, a vacuum evaporation method, or the like.

Next, as illustrated in FIG. 9C, the protective layer 131 is formed over the common electrode 155. The protective layer 131 can be formed by a vacuum evaporation method, a sputtering method, a CVD method, an ALD method, or the like.

Then, the substrate 120 is bonded over the protective layer 131 using the resin layer 122, so that the display device can be manufactured. In the method for manufacturing the display device of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for manufacturing the display device in one embodiment of the present invention, the island-shaped EL layers 103R, 103G, and 103B are formed not by using a fine metal mask but by processing a film formed on the entire surface; thus, the island-shaped layers can be formed to have a uniform thickness. In addition, a high-resolution display device or a display device with a high aperture ratio can be obtained. Furthermore, even when the resolution or the aperture ratio is high and the distance between the subpixels is extremely short, the EL layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices formed by a photolithography technique can have favorable characteristics.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, desktop and notebook personal computers, a monitor of a computer and the like, digital signage, and a large game machine such as a pachinko machine.

### [Display Module]

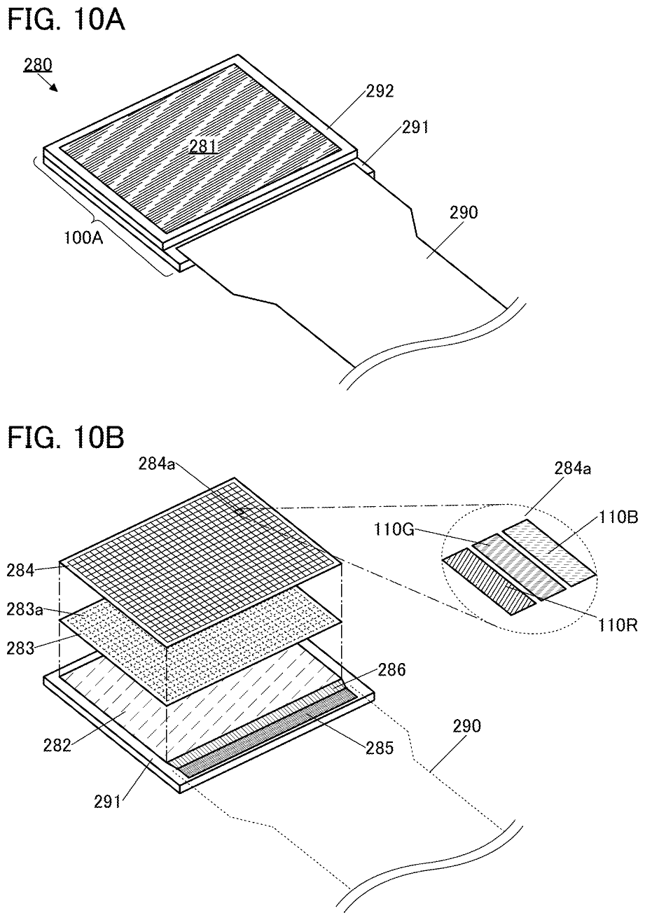

FIG. 10A is a perspective view of a display module 280. The display module 280 includes a display device 100A and an FPC 290. Note that the display device included in the display module 280 is not limited to the display device 100A and may be any of display devices 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 10B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 10B. The pixels 284a can employ any of the structures described in the above embodiments.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Device 100A]

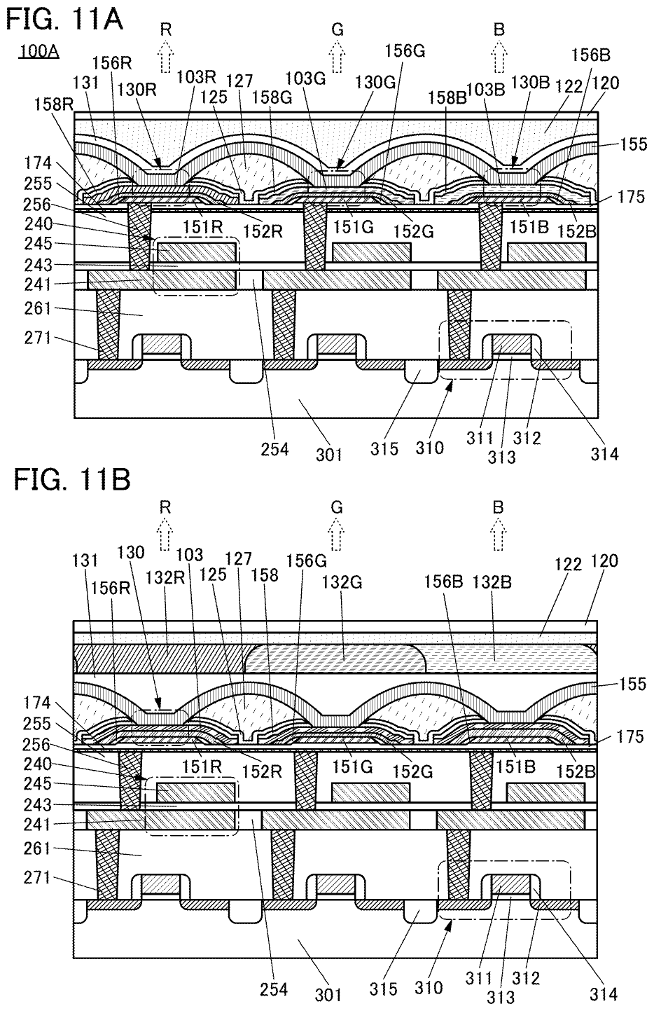

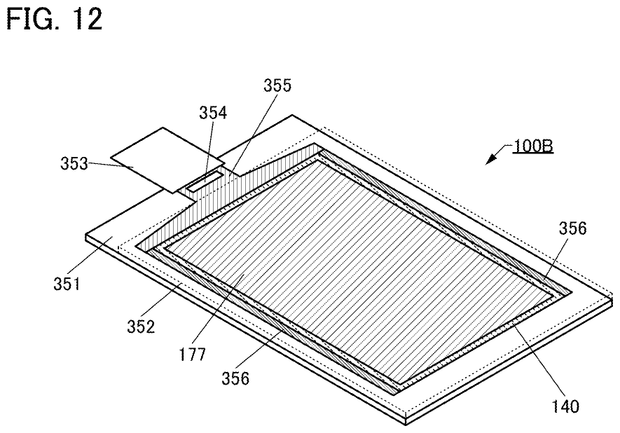

The display device 100A illustrated in FIG. 11A includes a substrate 301, the light-emitting devices 130R, 130G, and 130B, a capacitor 240, and a transistor 310.

The substrate 301 corresponds to the substrate 291 in FIGS. 10A and 10B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the EL layer 103R. The sacrificial layer 158G is positioned over the EL layer 103G. The sacrificial layer 158B is positioned over the EL layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 2 can be referred to for the details of the light-emitting device 130 and the components thereover up to the substrate 120. The substrate 120 corresponds to the substrate 292 in FIG. 10A.

FIG. 11B illustrates a variation example of the display device 100A illustrated in FIG. 11A. The display device illustrated in FIG. 11B includes the coloring layers 132R, 132G, and 132B, and each of the light-emitting devices 130 includes a region overlapping with one of the coloring layers 132R, 132G, and 132B. In the display device illustrated in FIG. 11B, the light-emitting device 130 can emit white light, for example. The coloring layer 132R, the coloring layer 132G, and the coloring layer 132B can transmit red light, green light, and blue light, respectively, for example.

### [Display Device 100B]

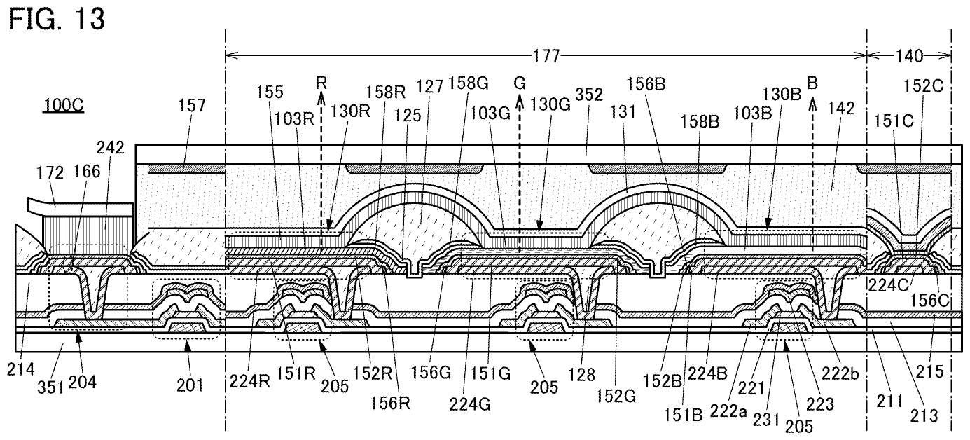

FIG. 12 is a perspective view of the display device 100B, and FIG. 13 is a cross-sectional view of the display device 100B.

In the display device 100B, a substrate 352 and a substrate 351 are bonded to each other. In FIG. 12, the substrate 352 is denoted by a dashed line.

The display device 100B includes the pixel portion 177, the connection portion 140, a circuit 356, a wiring 355, and the like. FIG. 12 illustrates an example in which an IC 354 and an FPC 353 are mounted on the display device 100B. Thus, the structure illustrated in FIG. 12 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 12 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 13 illustrates an example of cross sections of part of a region including the FPC 353, part of the circuit 356, part of the pixel portion 177, part of the connection portion 140, and part of a region including an end portion of the display device 100B.

### [Display Device 100C]

The display device 100C illustrated in FIG. 13 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depression portion covering the opening provided in the insulating layer 214. A layer 128 is embedded in the depression portion.

The layer 128 has a function of filling the depression portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depression portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 13, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-like adhesive layer 142.

FIG. 13 illustrates an example in which the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 13, the insulating layer 156C is provided to include a region overlapping with the side surface of the conductive layer 151C.

The display device 100B has a top-emission structure. Light from the light-emitting device is emitted toward the substrate 352. For the substrate 352, a material having a high visible-light-transmitting property is preferably used. The pixel electrode contains a material that reflects visible light, and the counter electrode (common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable for the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the wiring 355 is electrically connected to the FPC 353 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

A light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

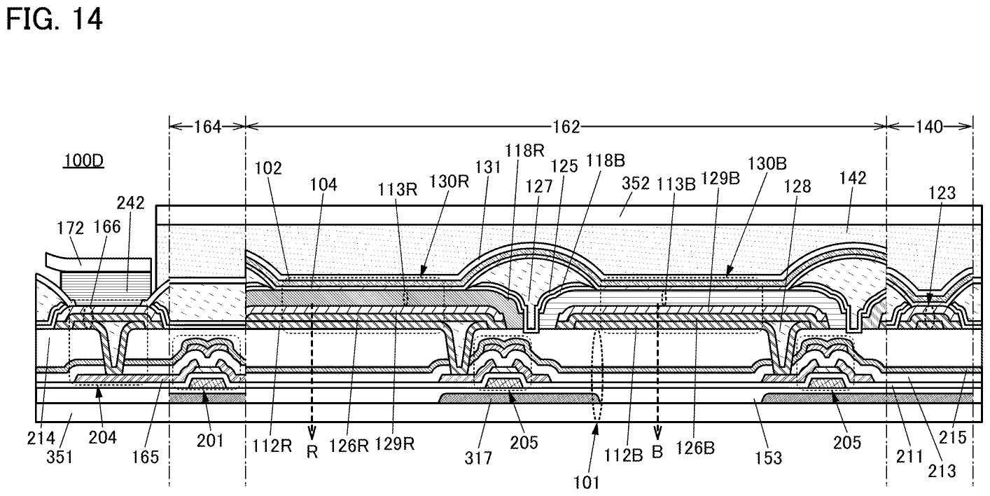

The display device 100D in FIG. 14 differs from the display device 100A in FIG. 13 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

The light-blocking layer 317 is preferably formed between the substrate 351 and the transistor 201 and between the substrate 351 and the transistor 205. FIG. 14 illustrates an example in which the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the second electrode 102.

Although not illustrated in FIG. 14, the light-emitting device 130G is also provided.

Although FIG. 14 and the like illustrate an example in which the top surface of the layer 128 includes a flat portion, the shape of the layer 128 is not particularly limited.

### [Display Device 100E]

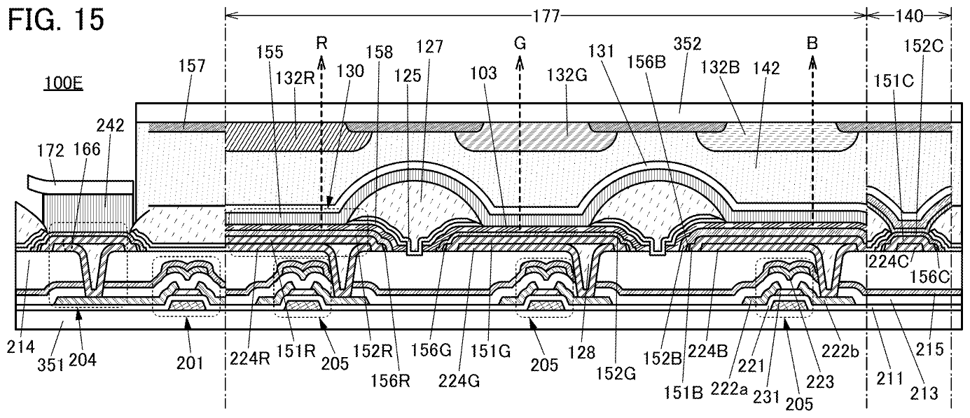

The display device 100E illustrated in FIG. 15 is a variation example of the display device 100B illustrated in FIG. 13 and differs from the display device 100B mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the light-emitting device 130 can emit white light, for example. The coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic devices of embodiments of the present invention will be described.

Electronic devices of this embodiment are each provided with the display device of one embodiment of the present invention in a display portion. The display device of one embodiment of the present invention has low power consumption and high reliability. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook personal computers, a monitor of a computer and the like, digital signage, and a large game machine such as a pachinko machine.

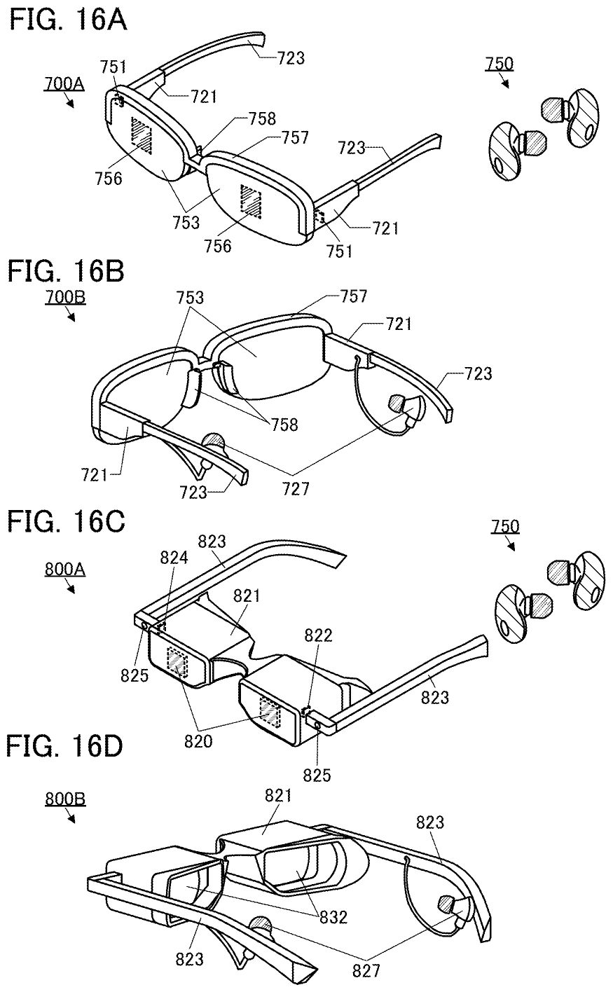

Examples of head-mounted wearable devices are described with reference to FIGS. 16A to 16D.

An electronic device 700A illustrated in FIG. 16A and an electronic device 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices can be highly reliable.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic device 800A illustrated in FIG. 16C and an electronic device 800B illustrated in FIG. 16D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic devices can be highly reliable.

The display portions 820 are positioned inside the housing 821 so as to be seen through the lenses 832. When the pair of display portions 820 display different images, three-dimensional display using parallax can be performed.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes.

The electronic device 800A or the electronic device 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic device 800A may include a vibration mechanism that functions as bone-conduction earphones.

The electronic devices 800A and 800B may each include an input terminal. To the input terminal, a cable for supplying a video signal from a video output device or the like, power for charging a battery provided in the electronic apparatus, and the like can be connected.

The electronic device of one embodiment of the present invention may have a function of performing wireless communication with earphones 750.

The electronic device may include an earphone portion. The electronic device 700B in FIG. 16B includes earphone portions 727. Part of a wiring that connects the earphone portion 727 and the control portion may be positioned inside the housing 721 or the mounting portion 723.

Similarly, the electronic device 800B in FIG. 16D includes earphone portions 827. For example, the earphone portion 827 can be connected to the control portion 824 by wire.

As described above, both the glasses-type device (e.g., the electronic devices 700A and 700B) and the goggles-type device (e.g., the electronic devices 800A and 800B) are preferable as the electronic device of one embodiment of the present invention.

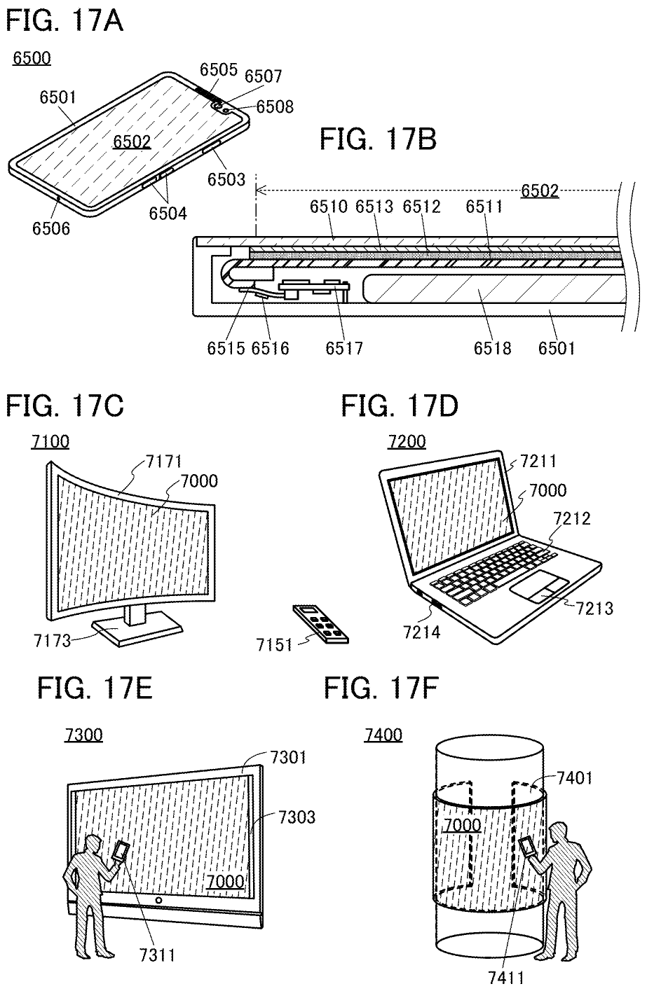

An electronic device 6500 illustrated in FIG. 17A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic device can be highly reliable.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used in the display panel 6511. Thus, the electronic device can be extremely lightweight. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby the electronic device can have a narrow bezel.

FIG. 17C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic device is obtained.

Operation of the television device 7100 illustrated in FIG. 17C can be performed with an operation switch provided in the housing 7171 and a separate remote controller 7151.

FIG. 17D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic device is obtained.

FIGS. 17E and 17F illustrate examples of digital signage.

Digital signage 7300 illustrated in FIG. 17E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 17F shows digital signage 7400 attached to a cylindrical pillar 7401. The digital signage 7400 includes the display portion 7000 provided along a curved surface of the pillar 7401.

In FIGS. 17E and 17F, the display device of one embodiment of the present invention can be used in the display portion 7000. Thus, the electronic apparatuses can be highly reliable.

A larger area of the display portion 7000 can increase the amount of information that can be provided at a time. The display portion 7000 having a larger area attracts more attention, so that the effectiveness of the advertisement can be increased, for example.

As illustrated in FIGS. 17E and 17F, it is preferable that the digital signage 7300 or the digital signage 7400 can work with an information terminal 7311 or an information terminal 7411, such as a smartphone that a user has, through wireless communication.

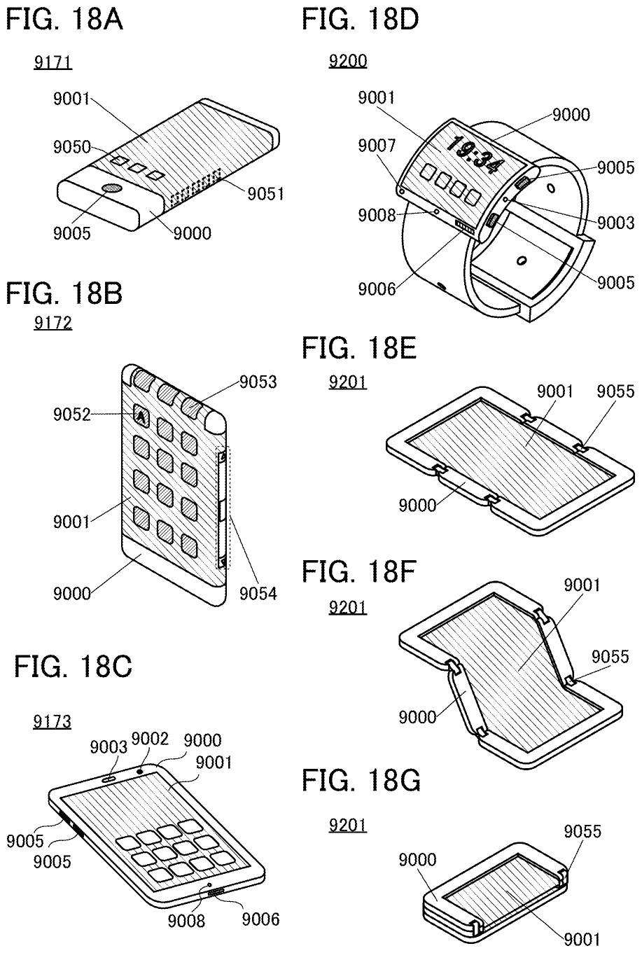

Electronic devices illustrated in FIGS. 18A to 18G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic devices illustrated in FIGS. 18A to 18G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic devices in FIGS. 18A to 18G are described in detail below.

FIG. 18A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 18A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 18B is a perspective view of a portable information terminal 9172. The portable information terminal 9172 has a function of displaying information on three or more surfaces of the display portion 9001. Here, information 9052, information 9053, and information 9054 are displayed on the respective surfaces. For example, the user of the portable information terminal 9172 can check the information 9053 displayed such that it can be seen from above the portable information terminal 9172, with the portable information terminal 9172 put in a breast pocket of his/her clothes.

FIG. 18C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 18D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 18E to 18G are perspective views of a foldable portable information terminal 9201. FIG. 18E is a perspective view showing the portable information terminal 9201 that is opened. FIG. 18G is a perspective view showing the portable information terminal 9201 that is folded. FIG. 18F is a perspective view showing the portable information terminal 9201 that is shifted from one of the states in FIGS. 18E and 18G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

In this example, specific fabrication methods of Light-emitting device 1 of one embodiment of the present invention and Comparative light-emitting device 1 and the measurement results of the initial characteristics and reliability of the light-emitting devices are described.

Structural formulae of main compounds used in this example are shown below.

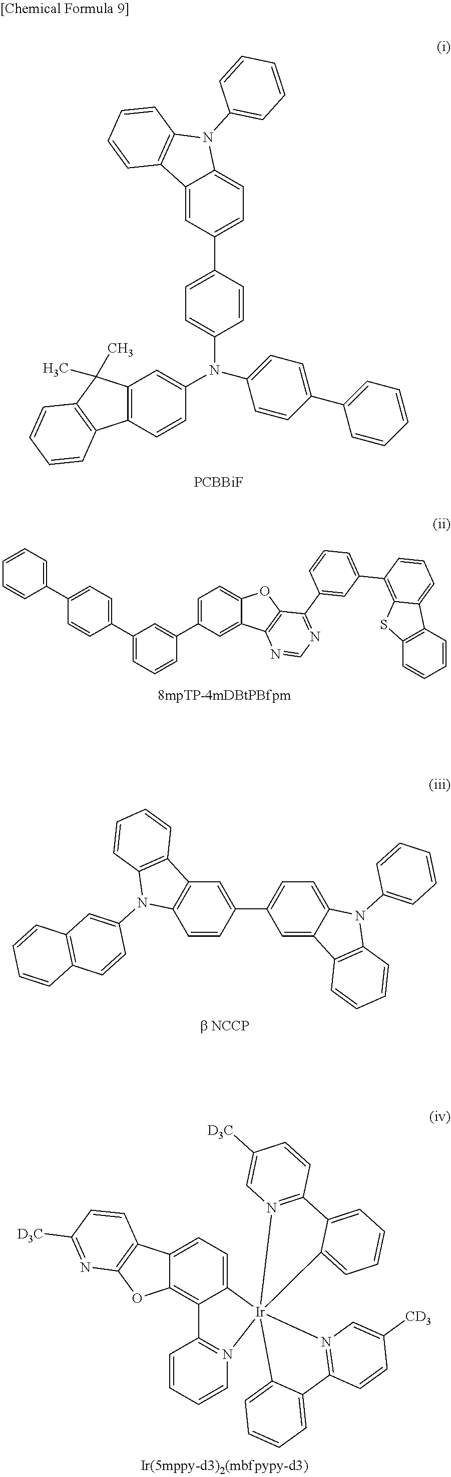

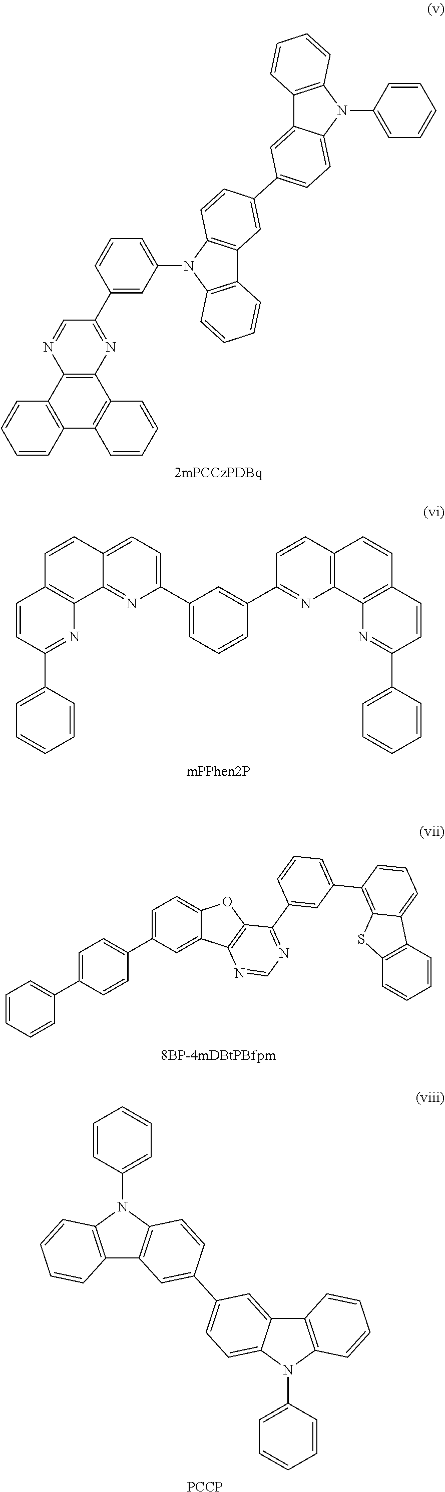 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-c2ccc3ccc4ccc(-c5cccc(-c6ccc7ccc8ccc(-c9ccccc9)nc8c7n6)c5)nc4c3n2)cc1 ; c1ccc(-c2ccc(-c3ccc4oc5c(-c6cccc(-c7cccc8c7sc7ccccc78)c6)ncnc5c4c3)cc2)cc1 ; c1ccc(-n2c3ccccc3c3cc(-c4ccc5c(c4)c4ccccc4n5-c4ccccc4)ccc32)cc1 ; "PCCP"]

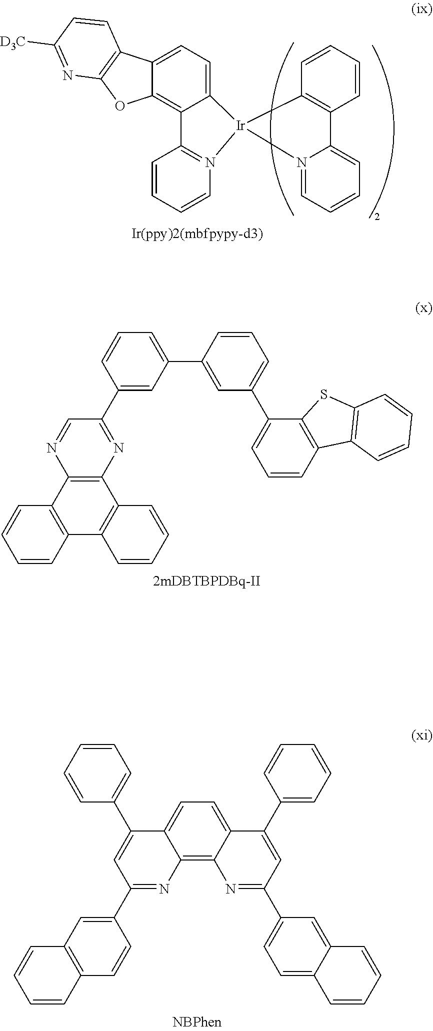

### (Fabrication Method of Light-Emitting Device 1)

First, over a glass substrate, titanium (Ti), aluminum (Al), and Ti were deposited to a thickness of 50 nm, 70 nm, and 6 nm, respectively, so that they are stacked, and then baking was performed at 300° C. in the atmosphere for 1 hour. After that, indium tin oxide containing silicon oxide (ITSO) was deposited to a thickness of 10 nm by a sputtering method, so that the first electrode 101 having a size of 2 mm×2 mm was formed. Note that ITSO functions as an anode, and is regarded as the first electrode 101 together with the above stacked-layer structure of Ti and Al.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 60 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 10 nm, whereby the hole-transport layer 112 was formed.

Then, over the hole-transport layer, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii), 9-(2-naphthyl)-9′-phenyl-9H,9′H-3,3′-bicarbazole (abbreviation: βNCCP) represented by Structural Formula (iii), and [2-d₃-methyl-8-(2-pyridinyl-κN)benzofuro[2,3-b]pyridine-κC]bis[2-(5-d₃-methyl-2-pyridinyl-κN2)phenyl-κC]iridium(III) (abbreviation: Ir(5mppy-d₃)₂(mbfpypy-d3)) represented by Structural Formula (iv) were deposited by co-evaporation to a thickness of 40 nm such that the weight ratio of 8mpTP-4mDBtPBfpm to βNCCP and Ir(5mppy-d3)₂(mbfpypy-d3) was 0.6:0.4:0.1, whereby the light-emitting layer 113 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) was deposited by evaporation to a thickness of 10 nm to form a first electron-transport layer, and then 2,2′-(1,3-phenylene)bis(9-phenyl-1,10-phenanthroline) (abbreviation: mPPhen2P) represented by Structure Formula (vi) was deposited by evaporation to a thickness of 15 nm to form a second electron-transport layer, whereby the electron-transport layer 114 was formed. Note that the first electron-transport layer also functions as a hole-blocking layer.

After that, lithium fluoride (LiF) and ytterbium (Yb) were deposited by co-evaporation to a thickness of 1.5 nm such that the volume ratio of LiF to Yb was 1:0.5 to form the electron-injection layer 115, and then silver (Ag) and magnesium (Mg) were deposited by co-evaporation to a thickness of 25 nm such that the volume ratio of Ag to Mg was 1:0.1, whereby the second electrode 102 was formed. In this manner, the light-emitting device of one embodiment of the present invention was fabricated. Over the second electrode 102, ITO was deposited to a thickness of 70 nm as a cap layer to improve light extraction efficiency.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, Light-emitting device 1 was fabricated.

### (Fabrication Method of Comparative Light-Emitting Device 1)

The first electrode to the hole-transport layer of Comparative light-emitting device 1 were formed in the same manner as those of Light-emitting device 1. Then, over the hole-transport layer, 8-(biphenyl-4-yl)-4-[3-(dibenzothiophen-4-yl)phenyl]-benzofuro[3,2-d]pyrimidine (abbreviation: 8BP-4mDBtPBfpm) represented by Structural Formula (vii), 9,9′-diphenyl-9H,9′H-3,3′-bicarbazole (PCCP) represented by Structural Formula (viii), and [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d3)) represented by Structural Formula (ix) were deposited by co-evaporation to a thickness of 40 nm such that the weight ratio of 8BP-4mDBtPBfpm to PCCP and Ir(ppy)₂(mbfpypy-d3) was 0.6:0.4:0.1, whereby the light-emitting layer 113 was formed.

Then, 2-[3-(3′-dibenzothiophen-4-yl)biphenyl-3-yl]dibenzo[f,h]quinoxaline (abbreviation: 2mDBTBPDBq-II) represented by Structural Formula (x) was deposited to a thickness of 20 nm by evaporation to form a first electron-transport layer, and 2,9-di(naphthalen-2-yl)-4,7-diphenyl-1,10-phenanthroline (abbreviation: NBPhen) represented by Structural Formula (xi) was deposited to a thickness of 15 nm by evaporation to form a second electron-transport layer, whereby the electron-transport layer 114 was formed. Note that the first electron-transport layer also functions as a hole-blocking layer.

After that, lithium fluoride (LiF) was deposited by evaporation to a thickness of 1 nm to form the electron-injection layer 115, and then silver (Ag) and magnesium (Mg) were deposited by co-evaporation to a thickness of 25 nm such that the volume ratio of Ag to Mg was 1:0.1, whereby the second electrode 102 was formed. In this manner, the light-emitting device of one embodiment of the present invention was fabricated. Over the second electrode 102, ITO was deposited to a thickness of 70 nm as a cap layer to improve light extraction efficiency.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, Comparative light-emitting device 1 was fabricated.

Device structures of Light-emitting device 1 and Comparative light-emitting device 1 are shown below.

TABLE 1

| | | | | Light-emitting | Comparative light- |
|---|---|---|---|---|---|
| | | Thickness | | device 1 | emitting device 1 |
| Cap layer | | 70 | nm | ITO | |
| Second electrode | | 25 | nm | Ag:Mg (1:0.1) | |
| Electron-injection layer | | *2 | | LiF:Yb (1:0.5) | LiF |
| Electron- | 2 | 15 | nm | mPPhen2P | NBPhen |

| | | | | |
|---|---|---|---|---|
| transport layer | 1 | *1 | 2mPCCzPDBq | 2mDBTBPDBq-II |

| | | | | |
|---|---|---|---|---|
| Light-emitting layer | 40 | nm | 8mpTP-4mDBtPBfpm: | 8BP-4mDBtPBfpm: |

| | |
|---|---|
| βNCCP: | PCCP: |
| Ir(5mppy-d3)₂(mbfpypy-d3) | Ir(ppy)₂(mbfpypy-d3) |
| (0.6:0.4:0.1) | (0.6:0.4:0.1) |

| Hole-transport layer | 10 | nm | PCBBiF |
|---|---|---|---|
| Hole-injection layer | 10 | nm | PCBBiF:OCHD-003 (1:0.03) |
| First electrode | 10 | nm | ITSO |
| | 6 | nm | Ti |
| | 70 | nm | Al |
| | 50 | nm | Ti |

*1 Light-emitting device 1: 10 nm, Comparative light-emitting device 1: 20 nm
*2 Light-emitting device 1: 1.5 nm, Comparative light-emitting device 1: 1 nm

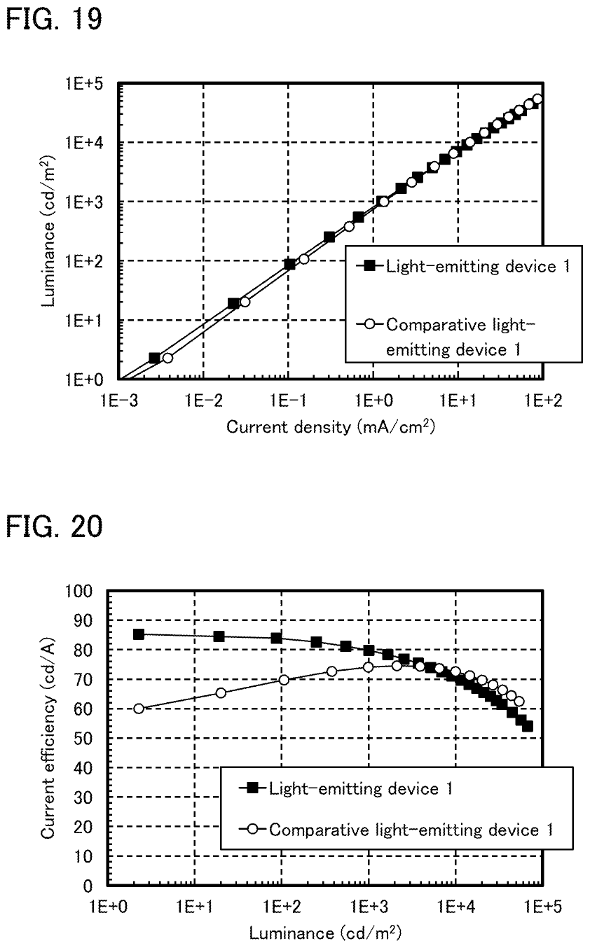

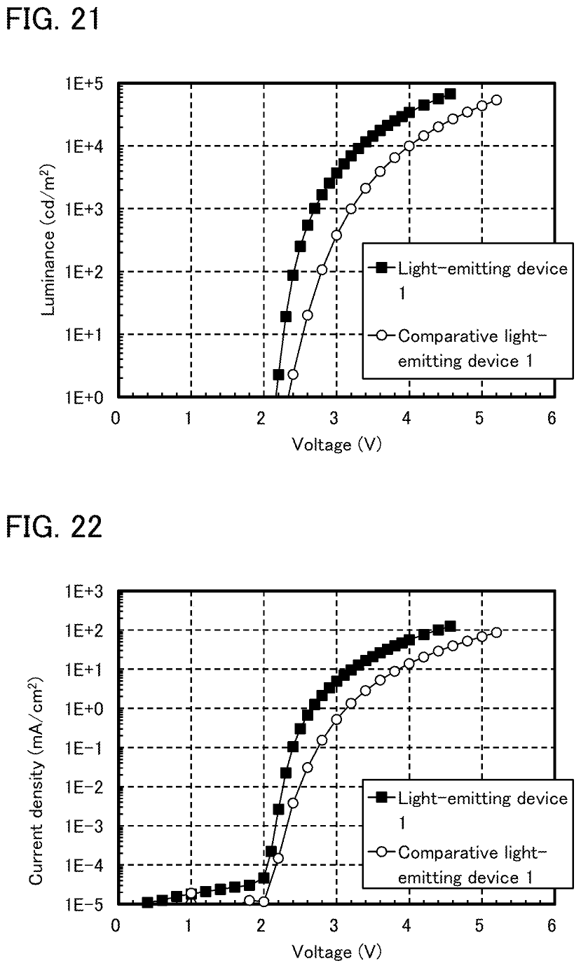

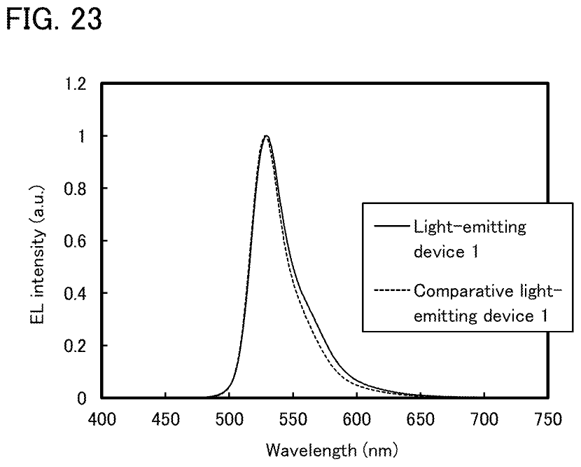

FIG. 19 shows the luminance-current density characteristics of Light-emitting device 1 and Comparative light-emitting device 1. FIG. 20 shows the current efficiency-luminance characteristics thereof. FIG. 21 shows the luminance-voltage characteristics thereof. FIG. 22 shows the current density-voltage characteristics thereof. FIG. 23 shows the emission spectra thereof. The values of the voltage, current, current density, CIE chromaticity, and current efficiency at 1000 cd/cm² are shown below. The luminance, CIE chromaticity, and emission spectra were measured at normal temperature with a spectroradiometer (SR-UL1R manufactured by TOPCON TECHNOHOUSE CORPORATION).

TABLE 2

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting device 1 | 2.7 | 0.050 | 1.26 | 0.28 | 0.68 | 80 |
| Comparative light- | 3.2 | 0.054 | 1.34 | 0.26 | 0.70 | 74 |
| emitting device 1 | | | | | | |

FIG. 19 to FIG. 23 show that Light-emitting device 1 has higher efficiency and lower driving voltage than Comparative light-emitting device 1.

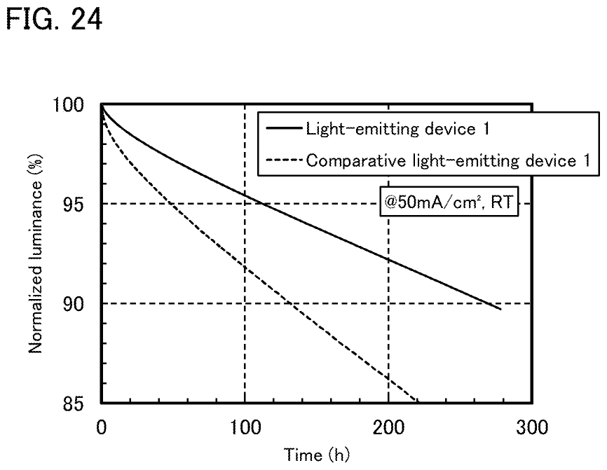

FIG. 24 shows changes in luminance over driving time in constant-current driving at a current density of 50 mA/cm². According to FIG. 24, the lifetime of Light-emitting device 1 is approximately twice as long as that of Comparative light-emitting device 1, indicating that Light-emitting device 1 has a long lifetime.

Light-emitting device 1 is the light-emitting device of one embodiment of the present invention including 8mpTP-4mDBtPBfpm as the first organic compound, βNCCP as the second organic compound, and Ir(5mppy-d3)₂(mbfpypy-d3) as the phosphorescent light-emitting substance in the light-emitting layer.

Thus, 8mpTP-4mDBtPBfpm as the first organic compound is the organic compound having a benzofuropyrimidine skeleton, which is a heteroaromatic ring skeleton, and a terphenyl group, which is an aromatic hydrocarbon group, and the lowest triplet excited level of 8mpTP-4mDBtPBfpm is derived from the terphenyl group. Moreover, βNCCP, which is the second organic compound, is the organic compound having a bicarbazole skeleton, and the lowest triplet excitation energy of βNCCP is 2.55 eV (within the range of 2.20 eV to 2.65 eV). In addition, Ir(5mppy-d3)₂(mbfpypy-d3) is a phosphorescent light-emitting substance that emits green phosphorescent light.

For calculation of the lowest triplet excitation energy level (T₁ level) of βNCCP, an emission spectrum (a phosphorescence spectrum) was measured at a measurement temperature of 10 K using a 50-nm-thick βNCCP film formed over a quartz substrate. The measurement was performed with a PL microscope, LabRAM HR-PL (produced by HORIBA, Ltd.) and a He—Cd laser (325 nm) as excitation light. As a result, the shortest-wavelength peak of the emission spectrum (phosphorescence spectrum) is 491 nm (2.53 eV) and the emission edge on the shortest wavelength side of the emission spectrum is 486 nm (2.55 eV). Note that the emission edge was determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum (phosphorescence spectrum).

In a manner similar to the above, the lowest triplet excitation energy level of PCCP was measured. The emission edge on the shortest wavelength side of the emission spectrum is 454 nm (2.73 eV).

The first organic compound and the second organic compound in Light-emitting device 1 form an exciplex capable of exciting the green phosphorescent light-emitting substance. Furthermore, the relatively low T₁ level of the second organic compound, which is 2.55 eV, prevents the generation of excitons in an excessively high energy state. The T₁ level of the first organic compound is as moderate as that of the second organic compound because its lowest triplet excited level is present at the terphenyl group (particularly preferably, the terphenyl group the meta-position of which is bonded to a heteroaromatic ring skeleton). Thus, Light-emitting device 1 can be highly reliable.

In Comparative light-emitting device 1, although 8BP-4mDBtPBfpm corresponding to the first substance is the organic compound having a benzofuropyrimidine skeleton, which is a heteroaromatic ring skeleton, and a biphenyl group, which is an aromatic hydrocarbon group, the lowest triplet excited level of 8BP-4mDBtPBfpm is derived from not the biphenyl group but a dibenzothiophenyl group. Accordingly, the T₁ level of 8BP-4mDBtPBfpm is higher than that of 8mpTP-4mDBtPBfpm, so that high energy excitons are generated. Furthermore, although PCCP corresponding to the second organic compound includes a bicarbazole skeleton, its lowest triplet excitation energy is 2.73 eV (higher than or equal to 2.65 eV). In addition, Ir(ppy)₂(mbfpypy-d3) is a phosphorescent light-emitting substance that emits green phosphorescent light.

In a manner similar to that of βNCCP, the lowest triplet excitation energy level (T₁ level) of each of 8mpTP-4mDBtPBfpm and 8BP-4mDBtPBfpm was measured. The shortest-wavelength peak of the emission spectrum of 8mpTP-4mDBtPBfpm is 500 nm (2.48 eV), and the emission edge on the shortest wavelength side of the emission spectrum is 486 nm (2.55 eV). The shortest-wavelength peak of the emission spectrum of 8BP-4mDBtPBfpm is 495 nm (2.51 eV), and the emission edge on the shortest wavelength side of the emission spectrum is 482 nm (2.57 eV). Thus, it can be said that 8mpTP-4mDBtPBfpm is an organic compound, the lowest triplet excitation energy level of which is lower than that of 8BP-4mDBtPBfpm.

### Example 2

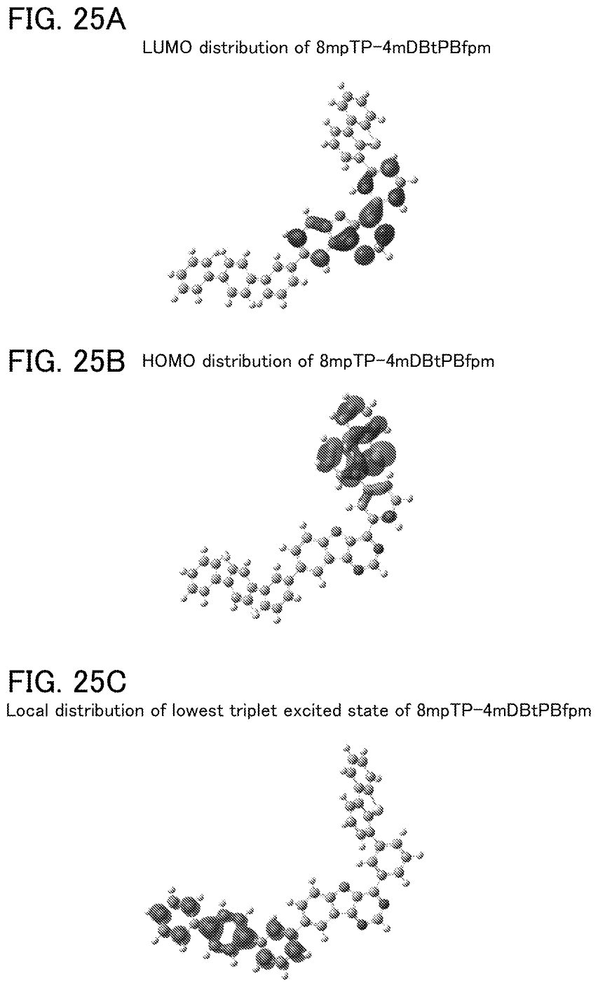

In this example, the first organic compound that can be used for the light-emitting device of one embodiment of the present invention was analyzed by calculation, and the results are described with reference to FIGS. 25A to 25C, FIGS. 26A to 26C, and FIGS. 27A to 27C.

Analysis of the HOMO distribution, the LUMO distribution, and the state of local distribution of the lowest triplet excited state was performed on 8mpTP-4mDBtPBfpm (Structural Formula (200)) that is a specific example of the first organic compound, an organic compound represented by Structural Formula (216), and 8BP-4mDBtPBfpm that is a comparative example.

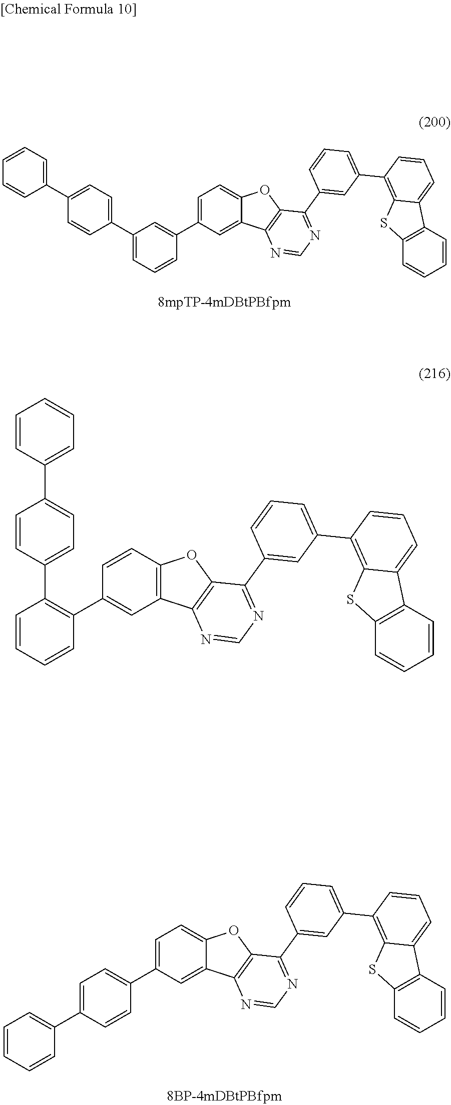 [SMILES: c1ccc(-c2ccc(-c3cccc(-c4ccc5oc6c(-c7cccc(-c8cccc9c8sc8ccccc89)c7)ncnc6c5c4)c3)cc2)cc1 ; c1ccc(-c2ccc(-c3ccccc3-c3ccc4oc5c(-c6cccc(-c7cccc8c7sc7ccccc78)c6)ncnc5c4c3)cc2)cc1 ; c1ccc(-c2ccc(-c3ccc4oc5c(-c6cccc(-c7cccc8c7sc7ccccc78)c6)ncnc5c4c3)cc2)cc1]

### <Calculation Method>

The HOMO and LUMO distributions were analyzed by analyzing vibration (spin density) in the most stable structure where the singlet ground state (S₀) level of the compound is the lowest. Local distribution of the lowest triplet excited state was analyzed by analyzing the spin density in the most stable structure where the lowest triplet excited state (T₁) level of the compound is the lowest. A density functional theory (DFT) method was used as the calculation method. The total energy calculated by the DF T is represented as the sum of potential energy, electrostatic energy between electrons, electronic kinetic energy, and exchange-correlation energy including all the complicated interactions between electrons. In the DFT, an exchange-correlation interaction is approximated by a functional (a function of another function) of one electron potential represented in terms of electron density to enable high-speed calculations. Here, B3LYP which is a hybrid functional was used to specify the weight of each parameter related to exchange-correlation energy. As a basis function, 6-311G (d,p) was used. Gaussian 09 was used as a computational program.

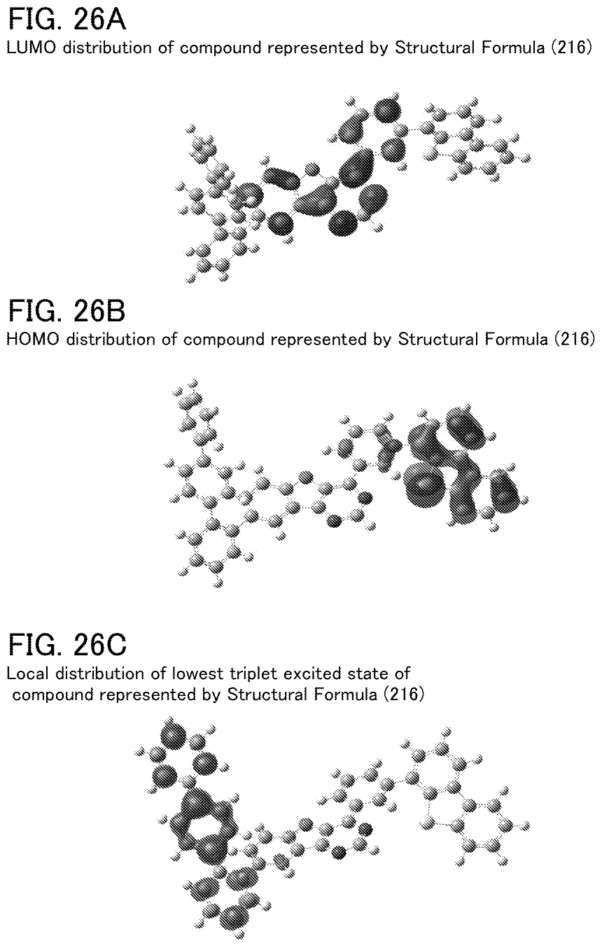

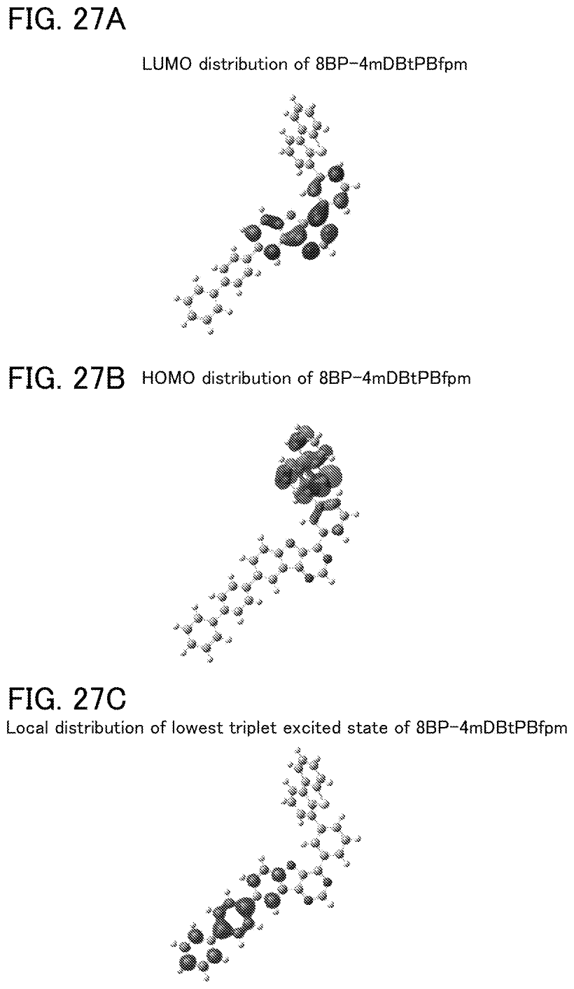

FIGS. 25A to 25C show the analysis results of 8mpTP-4mDBtPBfpm, FIGS. 26A to 26C show the analysis results of the organic compound represented by Structural Formula (216), and FIGS. 27A to 27C show the analysis results of 8BP-4mDBtPBfpm. In FIGS. 25A to 25C, FIGS. 26A to 26C, and FIGS. 27A to 27C, spheres represent atoms that form a compound, and cloud-like objects around the the spin density distribution at the density value of 0.003. In FIGS. 25A, 26A, and 27A, the cloud-like objects around the atoms show the LUMO distribution in the molecule. In FIGS. 25B, 26B, and 27B, the cloud-like objects around the atoms show the HOMO distribution in the molecule. In FIGS. 25C, 26C, and 27C, the cloud-like objects around the atoms show the state of local distribution of the lowest triplet excited state of the molecule.

FIGS. 25A to 25C and FIGS. 26A to 26C show that, in 8mpTP-4mDBtPBfpm and the organic compound represented by Structural Formula (216), the lowest triplet excited state is locally distributed in a terphenyl group corresponding to the first substituent of the first organic compound. Thus, in the organic compound 8mpTP-4mDBtPBfpm represented by Structural Formula (216), the lowest triplet excited state is locally distributed at the 1,1′:4′,1″-terphenyl skeleton of the first substituent. This indicates that the T₁ level of the organic compound 8mpTP-4mDBtPBfpm represented by Structural Formula (216) is derived from the 1,1′:4′,1″-terphenyl skeleton.

Meanwhile, FIGS. 27A to 27C show that the lowest triplet excited state of 8BP-4mDBtPBfpm is distributed not only in a 1,1′-biphenyl-4-yl group corresponding to the first substituent of the first organic compound, but also in the [1]benzofuro[3,2-d]pyrimidine ring corresponding to the electron-transport skeleton. Thus, it is found in 8BP-4mDBtPBfpm that there is no local distribution of the lowest triplet excited state at the first substituent.

### Example 3

In this example, specific fabrication methods of Light-emitting device 2 of one embodiment of the present invention and Comparative light-emitting device 2 and the measurement results of the initial characteristics and reliability of the light-emitting devices are described.

Structural formulae of main compounds used in this example are shown below.

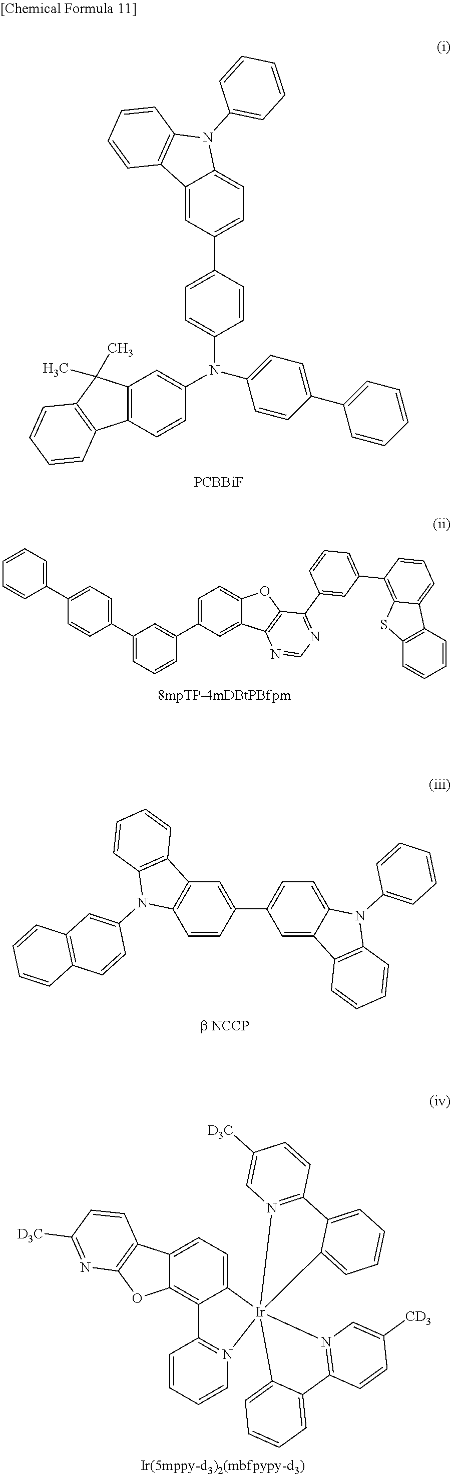

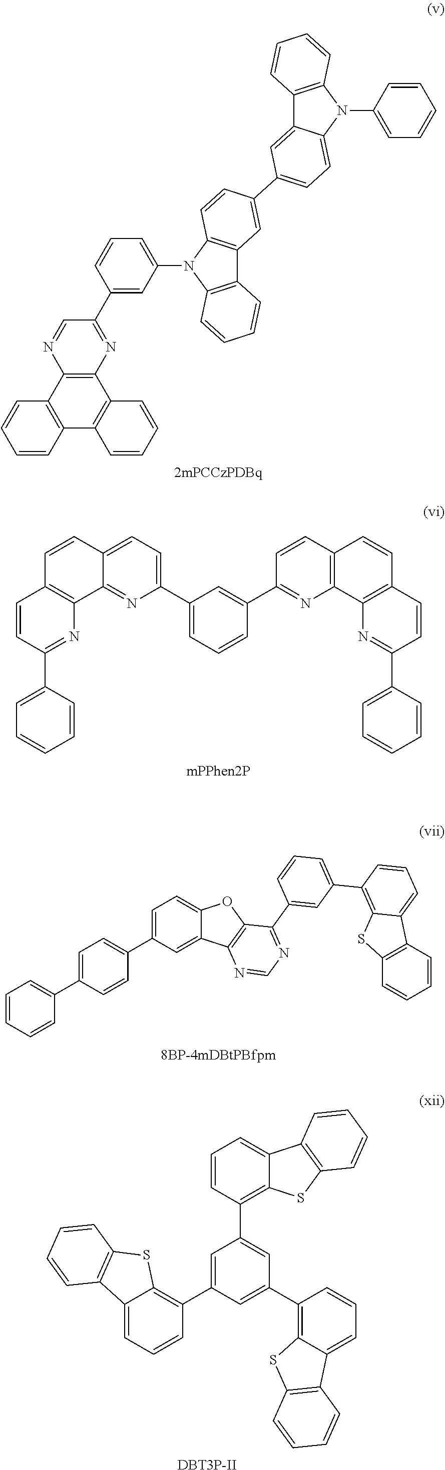 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-c2ccc3ccc4ccc(-c5cccc(-c6ccc7ccc8ccc(-c9ccccc9)nc8c7n6)c5)nc4c3n2)cc1 ; c1ccc(-c2ccc(-c3ccc4oc5c(-c6cccc(-c7cccc8c7sc7ccccc78)c6)ncnc5c4c3)cc2)cc1 ; c1ccc2c(c1)sc1c(-c3cc(-c4cccc5c4sc4ccccc45)cc(-c4cccc5c4sc4ccccc45)c3)cccc12 ; "DBT3P-II"]

### (Fabrication Method of Light-Emitting Device 2)

First, 100-nm-thick silver (Ag) and 10-nm-thick indium tin oxide containing silicon oxide (ITSO) were sequentially stacked over a glass substrate by a sputtering method, whereby the first electrode 101 with a size of 2 mm×2 mm was formed. Note that ITSO functions as an anode, and is regarded as the first electrode 101 together with the above Ag.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 60 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 15 nm, whereby the hole-transport layer 112 was formed.

Then, over the hole-transport layer, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii), 9-(2-naphthyl)-9′-phenyl-9H,9′H-3,3′-bicarbazole (abbreviation: βNCCP) represented by Structural Formula (iii), and [2-d₃-methyl-8-(2-pyridinyl-κN)benzofuro[2,3-b]pyridine-κC]bis[2-(5-d₃-methyl-2-pyridinyl-κN2)phenyl-κC]iridium(III) (abbreviation: Ir(5mppy-d₃)₂(mbfpypy-d₃)) represented by Structural Formula (iv) were deposited by co-evaporation to a thickness of 40 nm such that the weight ratio of 8mpTP-4mDBtPBfpm to βNCCP and Ir(5mppy-d3)₂(mbfpypy-d3) was 0.5:0.5:0.1, whereby the light-emitting layer 113 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) was deposited by evaporation to a thickness of 10 nm to form a first electron-transport layer, and then 2,2′-(1,3-phenylene)bis(9-phenyl-1,10-phenanthroline) (abbreviation: mPPhen2P) represented by Structure Formula (vi) was deposited by evaporation to a thickness of 20 nm to form a second electron-transport layer, whereby the electron-transport layer 114 was formed. Note that the first electron-transport layer also functions as a hole-blocking layer.

After that, lithium fluoride (LiF) and ytterbium (Yb) were deposited by co-evaporation to a thickness of 1.5 nm such that the volume ratio of LiF to Yb was 1:0.5 to form the electron-injection layer 115, and then silver (Ag) and magnesium (Mg) were deposited by co-evaporation to a thickness of 15 nm such that the volume ratio of Ag to Mg was 1:0.1, whereby the second electrode 102 was formed. In this manner, the light-emitting device of one embodiment of the present invention was fabricated. Over the second electrode 102, 4,4′,4″-(benzene-1,3,5-triyl)tri(dibenzothiophene) (abbreviation: DBT3P-II) represented by Structural Formula (xii) was deposited to a thickness of 70 nm as a cap layer to improve light extraction efficiency.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, Light-emitting device 2 was fabricated.

### (Fabrication Method of Comparative Light-Emitting Device 2)

Comparative light-emitting device 2 was fabricated in a manner similar to that of Light-emitting device 2 except that 8mpTP-4mDBtPBfpm was replaced with 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm) represented by Structural Formula (vii) above.

Device structures of Light-emitting device 2 and Comparative light-emitting device 2 are shown below.

TABLE 3

| | | |
|---|---|---|
| | Light-emitting | Comparative light- |
| Thickness | device 2 | emitting device 2 |

| Cap layer | | 70 | nm | DBT3P-II |
|---|---|---|---|---|
| Second electrode | | 15 | nm | Ag:Mg (1:0.1) |
| Electron-injection layer | | 1.5 | nm | LiF:Yb (1:0.5) |
| Electron- | 2 | 20 | nm | mPPhen2P |
| transport layer | 1 | 10 | nm | 2mPCCzPDBq |

| | | | | |
|---|---|---|---|---|
| Light-emitting layer | 40 | nm | 8mpTP-4mDBtPBfpm: | 8BP-4mDBtPBfpm: |

| | |
|---|---|
| βNCCP: | βNCCP: |
| Ir(5mppy-d₃)₂(mbfpypy-d₃) | Ir(5mppy-d₃)₂(mbfpypy-d₃) |
| (0.5:0.5:0.1) | (0.5:0.5:0.1) |

| Hole-transport layer | 15 | nm | PCBBiF |
|---|---|---|---|
| Hole-injection layer | 10 | nm | PCBBiF:OCHD-003 (1:0.03) |
| First electrode | 10 | nm | ITSO |
| | 100 | nm | Ag |

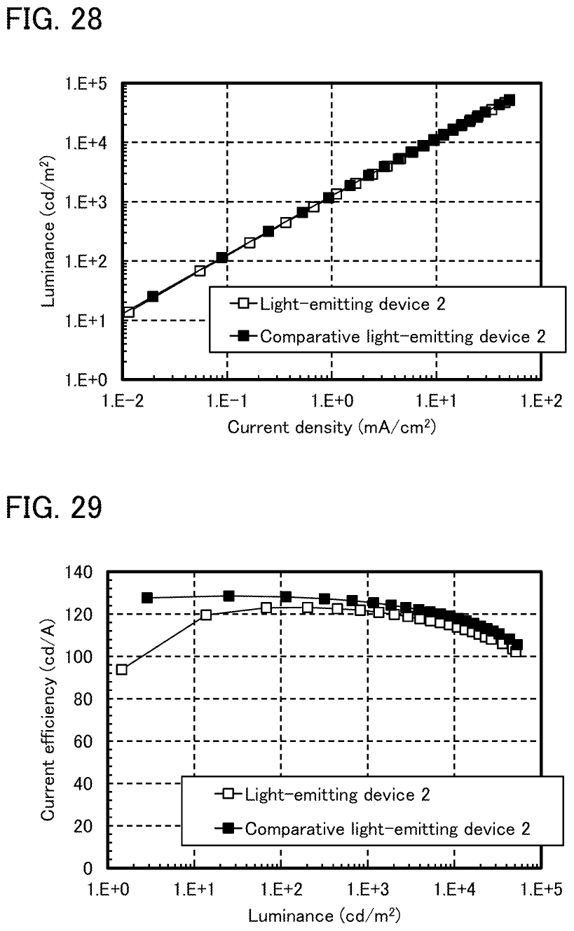

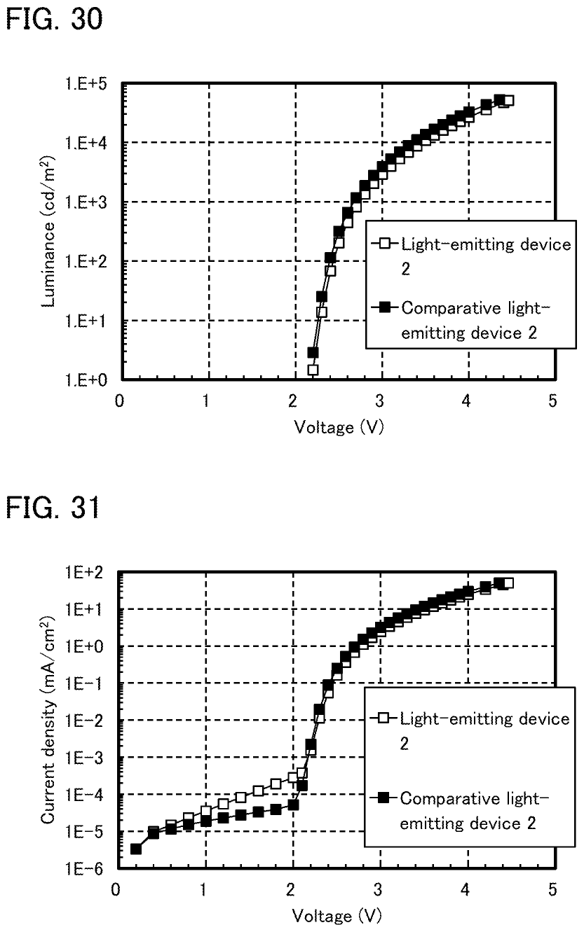

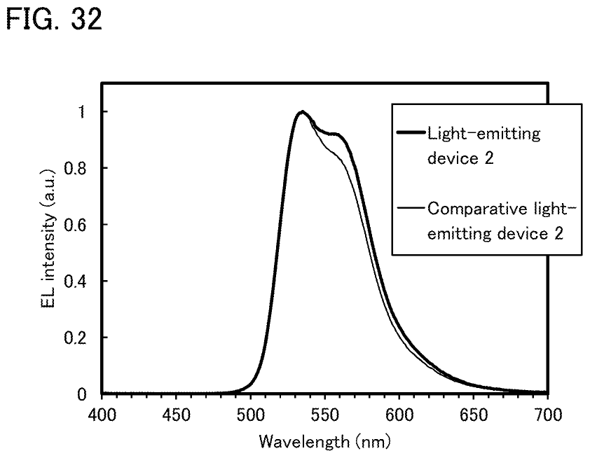

FIG. 28 shows the luminance-current density characteristics of Light-emitting device 2 and Comparative light-emitting device 2. FIG. 29 shows the current efficiency-luminance characteristics thereof. FIG. 30 shows the luminance-voltage characteristics thereof. FIG. 31 shows the current density-voltage characteristics thereof. FIG. 32 shows the emission spectra thereof. The values of the voltage, current, current density, CIE chromaticity, and current efficiency at 1000 cd/cm² are shown below. The luminance, CIE chromaticity, and emission spectra were measured at normal temperature with a spectroradiometer (SR-UL1R manufactured by TOPCON TECHNOHOUSE CORPORATION).

TABLE 4

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting device 2 | 2.7 | 0.027 | 0.67 | 0.37 | 0.62 | 122 |
| Comparative light- | 2.7 | 0.037 | 0.93 | 0.36 | 0.63 | 125 |
| emitting device 2 | | | | | | |

FIG. 28 to FIG. 32 show that Light-emitting device 2 and Comparative light-emitting device 2 both have favorable characteristics.

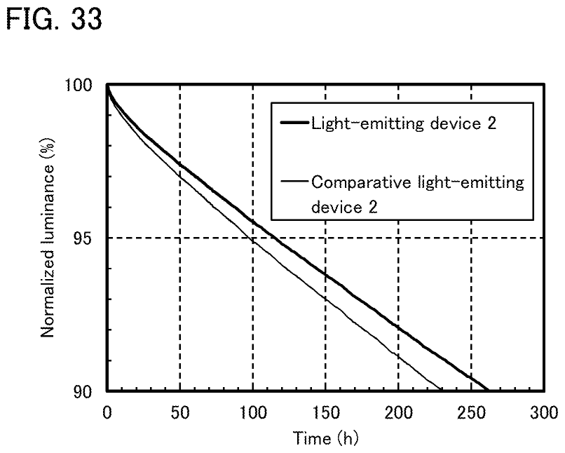

FIG. 33 shows the changes in luminance of Light-emitting device 2 and Comparative light-emitting device 2 over driving time in constant-current driving at a current density of 50 mA/cm². As shown in FIG. 33, the values of LT90, which is a time taken until the luminance decreases by 10%, of Light-emitting device 2 and Comparative light-emitting device 2 are 263 hours and 232 hours, respectively. Thus, Light-emitting device 2 is found to have a longer lifetime than Comparative light-emitting device 2.

Light-emitting device 2 is the light-emitting device of one embodiment of the present invention including 8mpTP-4mDBtPBfpm as the first organic compound, βNCCP as the second organic compound, and Ir(5mppy-d₃)₂(mbfpypy-d₃) as the phosphorescent light-emitting substance in the light-emitting layer.

Thus, 8mpTP-4mDBtPBfpm as the first organic compound is the organic compound having a benzofuropyrimidine skeleton, which is a heteroaromatic ring skeleton, and a terphenyl group, which is an aromatic hydrocarbon group, and the lowest triplet excited level of 8mpTP-4mDBtPBfpm is derived from the terphenyl group. Moreover, βNCCP, which is the second organic compound, is the organic compound having a bicarbazole skeleton, and the lowest triplet excitation energy of βNCCP is 2.55 eV (within the range of 2.20 eV to 2.65 eV). In addition, Ir(5mppy-d₃)₂(mbfpypy-d₃) is a phosphorescent light-emitting substance that emits green phosphorescent light.

For calculation of the lowest triplet excitation energy level (T₁ level) of βNCCP, an emission spectrum (a phosphorescence spectrum) was measured at a measurement temperature of 10 K using a 50-nm-thick βNCCP film formed over a quartz substrate. The measurement was performed with a PL microscope, LabRAM HR-PL (produced by HORIBA, Ltd.) and a He—Cd laser (325 nm) as excitation light. As a result, the shortest-wavelength peak of the emission spectrum (phosphorescence spectrum) is 491 nm (2.53 eV) and the emission edge on the shortest wavelength side of the emission spectrum is 486 nm (2.55 eV). Note that the emission edge was determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum (phosphorescence spectrum).

The first organic compound and the second organic compound in Light-emitting device 2 form an exciplex capable of exciting the green phosphorescent light-emitting substance. Furthermore, the relatively low T₁ level of the second organic compound, which is 2.55 eV, prevents the generation of excitons in an excessively high energy state. The T₁ level of the first organic compound is as moderate as that of the second organic compound because its lowest triplet excited level is present at the terphenyl group (particularly preferably, the terphenyl group the meta-position of which is bonded to a heteroaromatic ring skeleton). Thus, Light-emitting device 2 can be highly reliable.

In Comparative light-emitting device 2, although 8BP-4mDBtPBfpm corresponding to the first substance is the organic compound having a benzofuropyrimidine skeleton, which is a heteroaromatic ring skeleton, and a biphenyl group, which is an aromatic hydrocarbon group, the lowest triplet excited level of 8BP-4mDBtPBfpm is derived from not the biphenyl group but a dibenzothiophenyl group. Accordingly, the T₁ level of 8BP-4mDBtPBfpm is higher than that of 8mpTP-4mDBtPBfpm, so that high energy excitons are generated.

In a manner similar to that of βNCCP, the lowest triplet excitation energy level (T₁ level) of each of 8mpTP-4mDBtPBfpm and 8BP-4mDBtPBfpm was measured. The shortest-wavelength peak of the emission spectrum of 8mpTP-4mDBtPBfpm is 500 nm (2.48 eV), and the emission edge on the shortest wavelength side of the emission spectrum is 486 nm (2.55 eV). The shortest-wavelength peak of the emission spectrum of 8BP-4mDBtPBfpm is 495 nm (2.51 eV), and the emission edge on the shortest wavelength side of the emission spectrum is 482 nm (2.57 eV). Thus, it can be said that 8mpTP-4mDBtPBfpm is an organic compound, the lowest triplet excitation energy level of which is lower than that of 8BP-4mDBtPBfpm.

### Example 4

In this example, specific fabrication methods of Light-emitting device 3 and Light-emitting device 4 of one embodiment of the present invention and the measurement results of the initial characteristics and reliability of the light-emitting devices are described.

Structural formulae of main compounds used in this example are shown below.

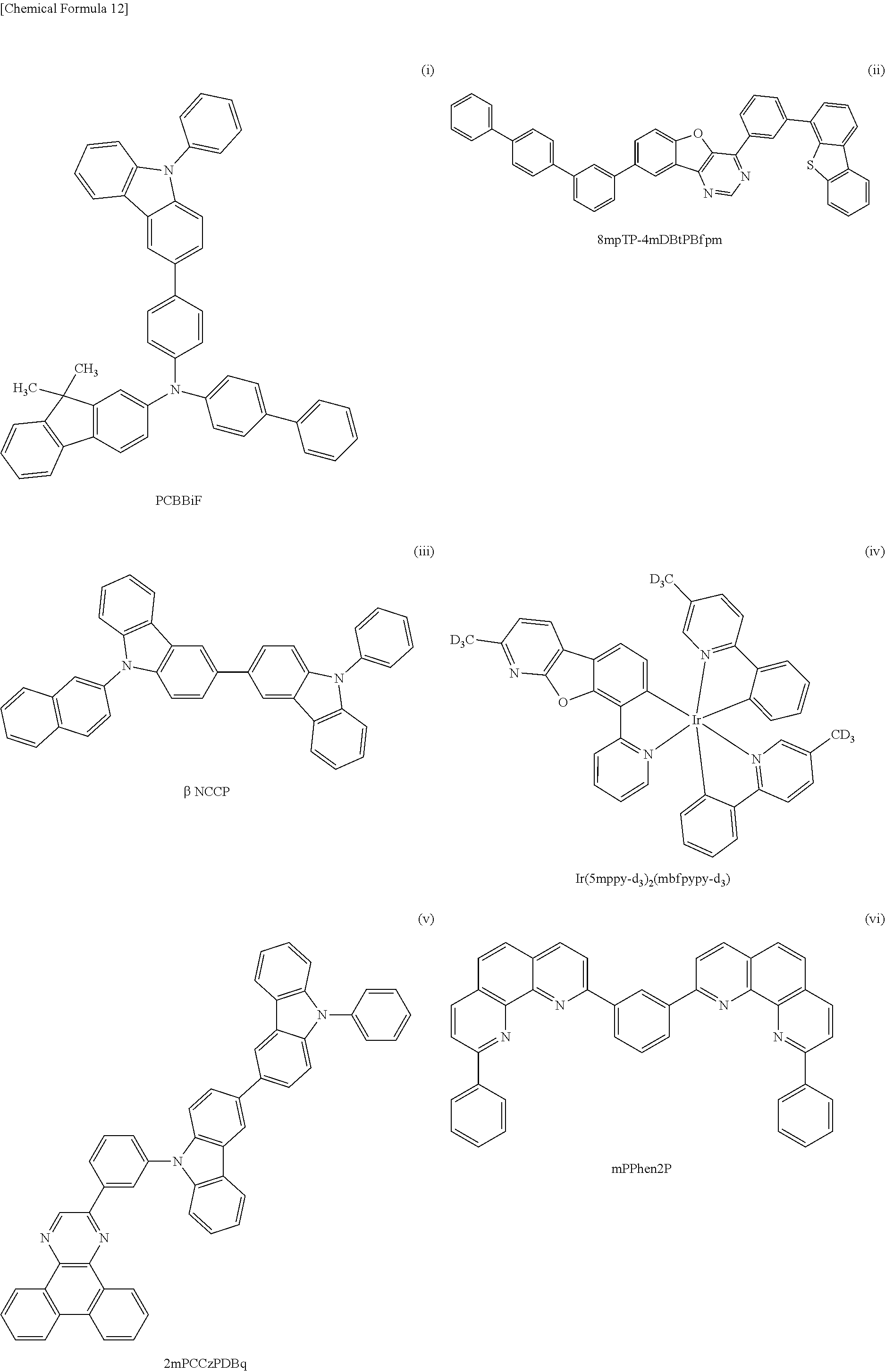

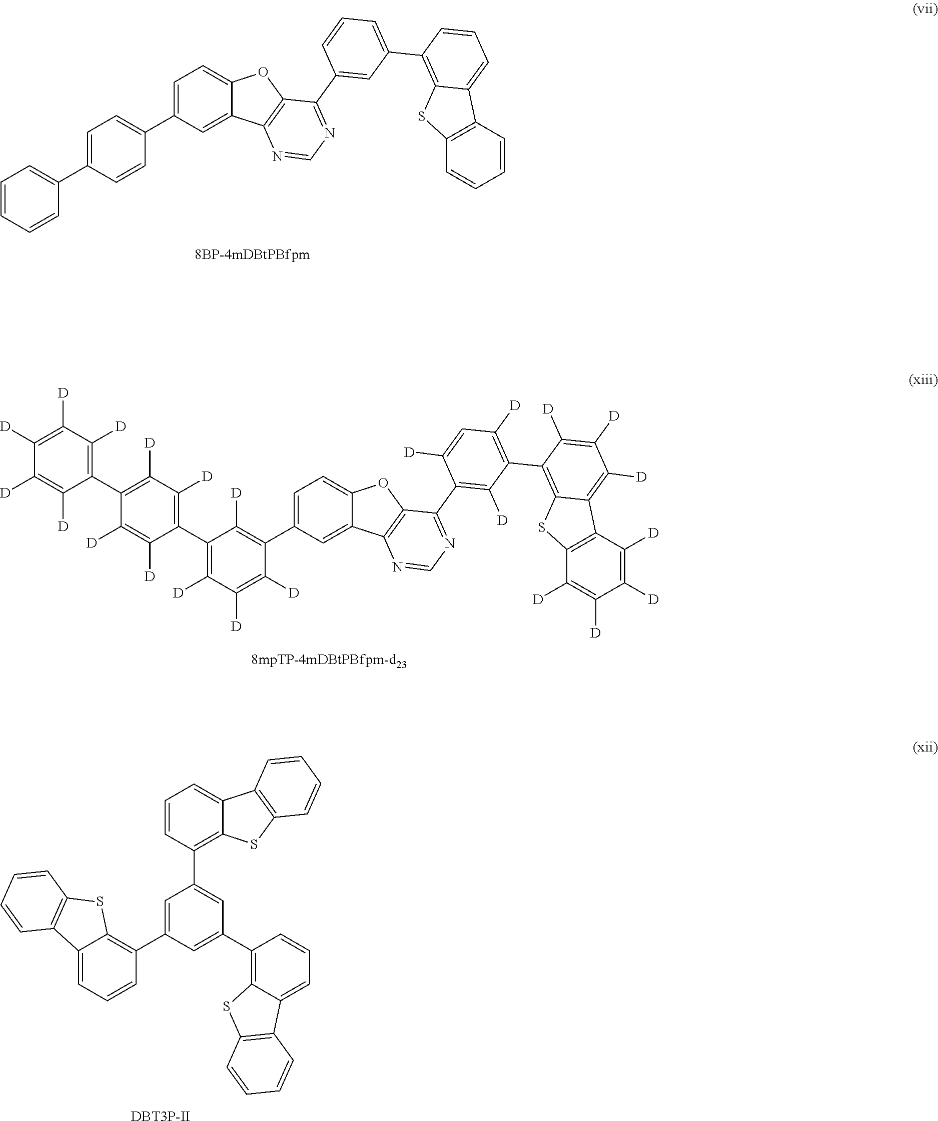

### (Fabrication Method of Light-Emitting Device 3)

First, 100-nm-thick silver (Ag) and 10-nm-thick indium tin oxide containing silicon oxide (ITSO) were sequentially stacked over a glass substrate by a sputtering method, whereby the first electrode 101 with a size of 2 mm×2 mm was formed. Note that ITSO functions as an anode, and is regarded as the first electrode 101 together with the above Ag.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 60 minutes in a heating chamber of the vacuum evaporation apparatus, and then the substrate was cooled down for approximately 30 minutes.

Then, the substrate was fixed to a holder provided in the vacuum evaporation apparatus such that the surface on which the first electrode 101 was formed faced downward. Over the inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 10 nm, whereby the hole-transport layer 112 was formed.

Then, over the hole-transport layer, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii), 9-(2-naphthyl)-9′-phenyl-9H,9′H-3,3′-bicarbazole (abbreviation: βNCCP) represented by Structural Formula (iii), and [2-d₃-methyl-8-(2-pyridinyl-κN)benzofuro[2,3-b]pyridine-κC]bis[2-(5-d₃-methyl-2-pyridinyl-κN2)phenyl-κC]iridium(III) (abbreviation: Ir(5mppy-d3)₂(mbfpypy-d3)) represented by Structural Formula (iv) were deposited by co-evaporation to a thickness of 50 nm such that the weight ratio of 8mpTP-4mDBtPBfpm to βNCCP and Ir(5mppy-d3)₂(mbfpypy-d3) was 0.5:0.5:0.1, whereby the light-emitting layer 113 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) was deposited by evaporation to a thickness of 10 nm to form a first electron-transport layer, and then 2,2′-(1,3-phenylene)bis(9-phenyl-1,10-phenanthroline) (abbreviation: mPPhen2P) represented by Structure Formula (vi) was deposited by evaporation to a thickness of 10 nm to form a second electron-transport layer, whereby the electron-transport layer 114 was formed. Note that the first electron-transport layer also functions as a hole-blocking layer.

After that, lithium fluoride (LiF) and ytterbium (Yb) were deposited by co-evaporation to a thickness of 1.5 nm such that the volume ratio of LiF to Yb was 1:0.5 to form the electron-injection layer 115, and then silver (Ag) and magnesium (Mg) were deposited by co-evaporation to a thickness of 25 nm such that the volume ratio of Ag to Mg was 1:0.1, whereby the second electrode 102 was formed. In this manner, the light-emitting device of one embodiment of the present invention was fabricated. Over the second electrode 102, 4,4′,4″-(benzene-1,3,5-triyl)tri(dibenzothiophene) (abbreviation: DBT3P-II) represented by Structural Formula (xii) was deposited to a thickness of 70 nm as a cap layer to improve light extraction efficiency.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 3 was fabricated.

### (Fabrication Method of Light-Emitting Device 4)

Light-emitting device 4 was fabricated in a manner similar to that of Light-emitting device 3 except that 8mpTP-4mDBtPBfpm was replaced with 8-(1,1′:4′,1″-terphenyl-3-yl-2,4,5,6,2′,3′,5′,6′,2″,3″,4″,5″,6″-d₁₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d23) represented by Structural Formula (xiii) above.

Device structures of Light-emitting devices 3 and 4 are shown below.

TABLE 5

| | | |
|---|---|---|
| Thickness | Light-emitting device 3 | Light-emitting device 4 |

| Cap layer | | 70 | nm | DBT3P-II |
|---|---|---|---|---|
| Second electrode | | 25 | nm | Ag:Mg (1:0.1) |
| Electron-injection layer | | 1.5 | nm | LiF:Yb (1:0.5) |
| Electron- | 2 | 10 | nm | mPPhen2P |
| transport layer | 1 | 10 | nm | 2mPCCzPDBq |

| | | | | |
|---|---|---|---|---|
| Light-emitting layer | 50 | nm | 8mpTP-4mDBtPBfpm: | 8mpTP-4mDBtPBfpm-d23: |

| | |
|---|---|
| βNCCP: | βNCCP: |
| Ir(5mppy-d₃)₂(mbfpypy-d₃) | Ir(5mppy-d₃)₂(mbfpypy-d₃) |
| (0.5:0.5:0.1) | (0.5:0.5:0.1) |

| Hole-transport layer | 10 | nm | PCBBiF |
|---|---|---|---|
| Hole-injection layer | 10 | nm | PCBBiF:OCHD-003 (1:0.03) |
| First electrode | 10 | nm | ITSO |
| | 100 | nm | Ag |

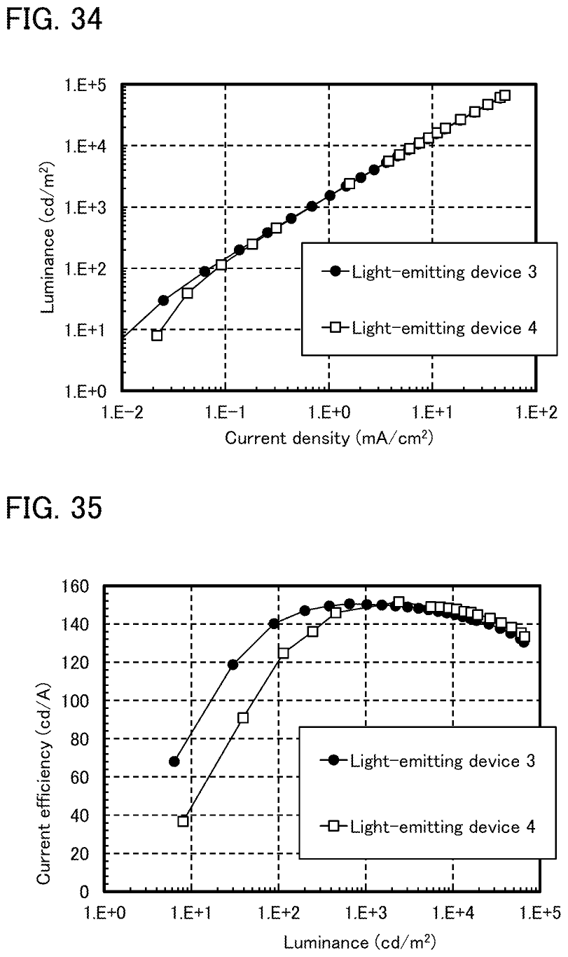

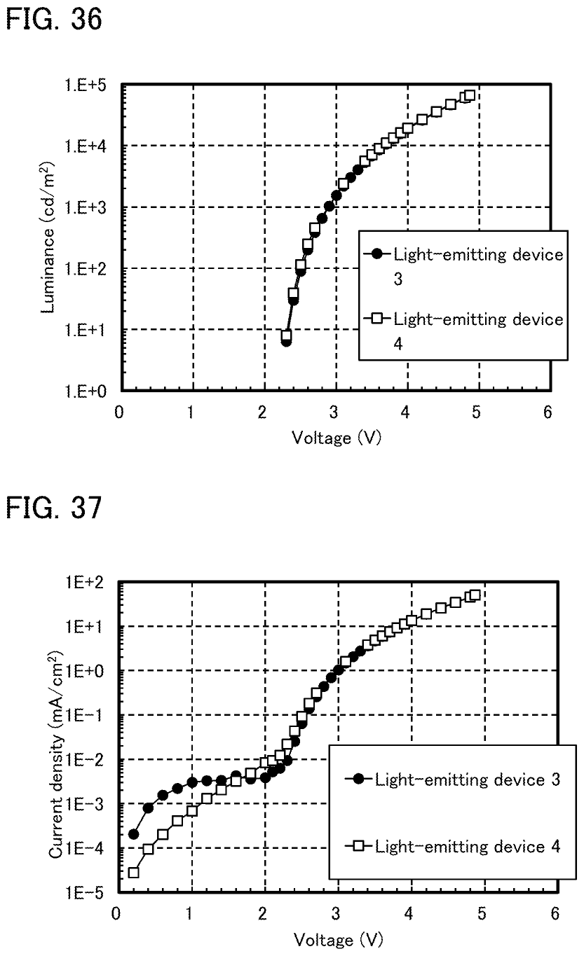

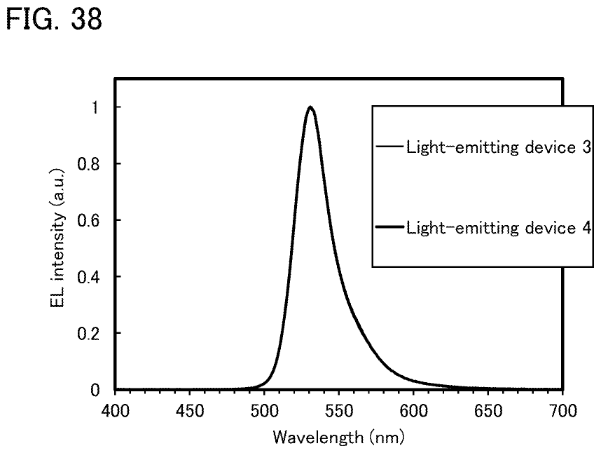

FIG. 34 shows the luminance-current density characteristics of Light-emitting devices 3 and 4. FIG. 35 shows the current efficiency-luminance characteristics thereof. FIG. 36 shows the luminance-voltage characteristics thereof. FIG. 37 shows the current density-voltage characteristics thereof. FIG. 38 shows the emission spectra thereof. The values of the voltage, current, current density, CIE chromaticity, and current efficiency at 2000 cd/m² are shown below. The luminance, CIE chromaticity, and emission spectra were measured at normal temperature with a spectroradiometer (SR-UL1R manufactured by TOPCON TECHNOHOUSE CORPORATION).

TABLE 6

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting device 3 | 3.1 | 0.059 | 1.47 | 0.26 | 0.71 | 149 |
| Light-emitting device 4 | 3.1 | 0.063 | 1.58 | 0.25 | 0.71 | 152 |

FIG. 34 to FIG. 38 show that Light-emitting devices 3 and 4 both have favorable characteristics.

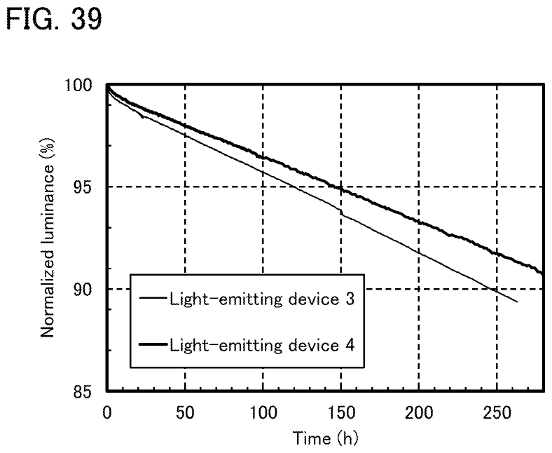

FIG. 39 shows the changes in luminance of Light-emitting devices 3 and 4 over driving time in constant-current driving at a current density of 50 mA/cm². As shown in FIG. 39, the luminances of Light-emitting devices 3 and 4 after the 250-hour driving were 90% and 92%, respectively, of the initial luminance. It is found that Light-emitting devices 3 and 4 are both highly reliable and Light-emitting device 4 particularly has a long lifetime.

Light-emitting device 3 is the light-emitting device of one embodiment of the present invention including 8mpTP-4mDBtPBfpm as the first organic compound, βNCCP as the second organic compound, and Ir(5mppy-d₃)₂(mbfpypy-d₃) as the phosphorescent light-emitting substance in the light-emitting layer. Light-emitting device 4 is the light-emitting device of one embodiment of the present invention including 8mpTP-4mDBtPBfpm-d₂₃ as the first organic compound, βNCCP as the second organic compound, and Ir(5mppy-d₃)₂(mbfpypy-d₃) as the phosphorescent light-emitting substance in the light-emitting layer.

Thus, 8mpTP-4mDBtPBfpm or 8mpTP-4mDBtPBfpm-d₂₃ as the first organic compound is the organic compound having a benzofuropyrimidine skeleton, which is a heteroaromatic ring skeleton, and a terphenyl group, which is an aromatic hydrocarbon group, and the lowest triplet excited level of 8mpTP-4mDBtPBfpm is derived from the terphenyl group. Moreover, βNCCP, which is the second organic compound, is the organic compound having a bicarbazole skeleton, and the lowest triplet excitation energy of βNCCP is 2.55 eV (within the range of 2.20 eV to 2.65 eV). In addition, Ir(5mppy-d3)₂(mbfpypy-d3) is a phosphorescent light-emitting substance that emits green phosphorescent light.

For calculation of the lowest triplet excitation energy level (T₁ level) of βNCCP, an emission spectrum (a phosphorescence spectrum) was measured at a measurement temperature of 10 K using a 50-nm-thick βNCCP film formed over a quartz substrate. The measurement was performed with a PL microscope, LabRAM HR-PL (produced by HORIBA, Ltd.) and a He—Cd laser (325 nm) as excitation light. As a result, the shortest-wavelength peak of the emission spectrum (phosphorescence spectrum) of βNCCP is 491 nm (2.53 eV) and the emission edge on the shortest wavelength side is 486 nm (2.55 eV). Note that the emission edge was determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum (phosphorescence spectrum).

The first organic compound and the second organic compound in Light-emitting devices 3 and 4 form an exciplex capable of exciting the green phosphorescent light-emitting substance. Furthermore, the relatively low T₁ level of the second organic compound, which is 2.55 eV, prevents the generation of excitons in an excessively high energy state. The T₁ level of the first organic compound is as moderate as that of the second organic compound because its lowest triplet excited level is present at the terphenyl group (particularly preferably, the terphenyl group the meta-position of which is bonded to a heteroaromatic ring skeleton). Thus, Light-emitting devices 3 and 4 can be highly reliable.

In a manner similar to that of βNCCP, the lowest triplet excitation energy level (T₁ level) of each of 8mpTP-4mDBtPBfpm and 8mpTP-4mDBtPBfpm-d₂₃ was measured. The shortest-wavelength peak of the emission spectrum of 8mpTP-4mDBtPBfpm is 500 nm (2.48 eV), and the emission edge on the shortest wavelength side of the emission spectrum is 486 nm (2.55 eV). The shortest-wavelength peak of the emission spectrum of 8mpTP-4mDBtPBfpm-d₂₃ is 501 nm (2.48 eV), and the emission edge on the shortest wavelength side of the emission spectrum is 484 nm (2.56 eV).

Then, a 2Me-THF solution of 8mpTP-4mDBtPBfpm and a 2Me-THF solution of 8mpTP-4mDBtPBfpm-d₂₃ were cooled using liquid nitrogen, and the emission spectra and emission quantum yields thereof were measured. The results are described below.

The emission spectrum and the emission quantum yield were measured in the following manner: an absolute PL quantum yield measurement system (C11347-01 manufactured by Hamamatsu Photonics K. K.) was used, a deoxidized 2Me-THF solution (0.120 mmol/L) of each of 8mpTP-4mDBtPBfpm and 8mpTP-4mDBtPBfpm-d₂₃ was sealed in a quartz cell under a nitrogen atmosphere in a glove box (LABstar M13 (1250/780) manufactured by Bright Co., Ltd.) and cooled using liquid nitrogen. FIG. shows the measurement results of the emission spectra of 8mpTP-4mDBtPBfpm and 8mpTP-4mDBtPBfpm-d₂₃. The horizontal axis represents the wavelength and the vertical axis represents the emission intensity.

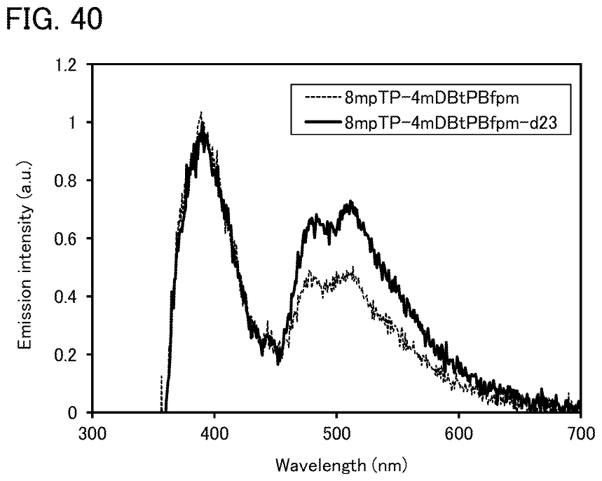

As shown in FIG. 40, each sample has an emission spectrum derived from both fluorescence and phosphorescence. From the results of room temperature measurement and emission lifetime measurement, the spectra around 351 nm to 455 nm were confirmed to be derived from fluorescence. In addition, the spectra around 455 nm to 660 nm, which were observed only in low-temperature measurement, were confirmed to be derived from phosphorescence.

Furthermore, the measurement results of the emission quantum yield show that the quantum yield (Φ_{f}(H)) of fluorescent components (in a wavelength range of 351 nm to 455 nm) of 8mpTP-4mDBtPBfpm at low temperature (temperature cooled using liquid nitrogen) is 8.5%. It is also shown that the quantum yield (Φₚ(H)) of phosphorescent components (in a wavelength range of 455 nm to 660 nm) is 10%.

The measurement results of the emission quantum yield show that the quantum yield (Φ_{f}(D)) of fluorescent components (in a wavelength range of 351 nm to 455 nm) of 8mpTP-4mDBtPBfpm-d₂₃ at low temperature (temperature cooled using liquid nitrogen) is 8.5%. It is also shown that the quantum yield (Φₚ(D)) of phosphorescent components (in a wavelength range of 455 nm to 660 nm) is 15%.

That is, at low temperature (temperature cooled using liquid nitrogen), the quantum yield of the phosphorescent components of 8mpTP-4mDBtPBfpm-d₂₃ is 1.5 times as high as that of the phosphorescent components of 8mpTP-4mDBtPBfpm, and the quantum yields of the fluorescent components are substantially equal to each other.

Furthermore, the 2-methyltetrahydrofuran (2Me-THF) solution of 8mpTP-4mDBtPBfpm and that of 8mpTP-4mDBtPBfpm-d₂₃ were cooled using liquid nitrogen and the emission lifetimes were measured. The results are described below.

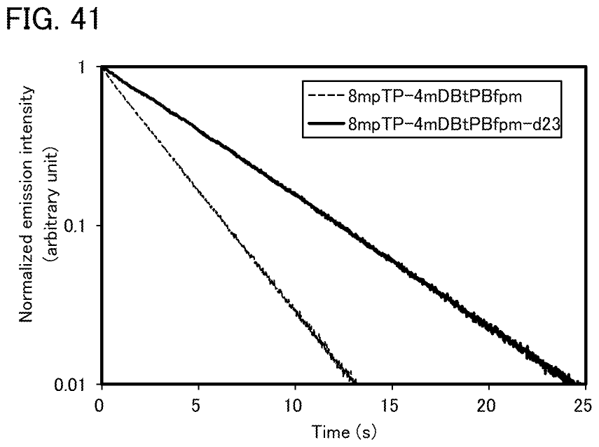

The emission lifetime was measured with a fluorescence spectrophotometer (FP-8600, manufactured by JASCO Corporation). The 2Me-THF solution (0.120 mmol/L) of 8mpTP-4mDBtPBfpm and the 2Me-THF solution (0.120 mmol/L) of 8mpTP-4mDBtPBfpm-d₂₃ were each put in a quartz cell under air, and cooled using liquid nitrogen to be measured. As the measurement, time-resolved measurement was performed in such a manner that the quartz cell containing the solution was irradiated with excitation light for approximately 30 seconds and the emission intensity attenuating after the excitation light was blocked by a shutter was measured at 10 ms intervals. Note that the wavelength of the excitation light was 320 nm, the wavelength of the measured light was 515 nm, and the band widths of the excitation light and the measured light were nm. FIG. 41 shows the time-dependent attenuation curves obtained by the measurement. The horizontal axis represents time and the vertical axis represents the emission intensity.

As shown in FIG. 41, the emission intensity attenuates single-exponentially. The emission lifetime was calculated from the obtained attenuation curve. The emission lifetime of 8mpTP-4mDBtPBfpm was 2.8 s. The emission lifetime of 8mpTP-4mDBtPBfpm-d₂₃ was 5.3 s. Since the wavelength of the light whose emission lifetime was measured is 515 nm, the emission lifetimes can be regarded as the lifetimes of phosphorescent components. This reveals that, at low temperature (temperature cooled using liquid nitrogen), the deuterated substance has a phosphorescence lifetime 1.9 times as long as that of the non-deuterated substance.

Here, a phosphorescent emission quantum yield (Φₚ) and a phosphorescence lifetime (τₚ) can be respectively expressed as Formula (1) and Formula (2), from a rate constant kᵣₚ of radiative transfer and a rate constant kₘₚ of non-radiative transfer from the lowest triplet excited state (T₁) of the organic compound, and a quantum yield (Φ_{isc}) of intercrossing system from the lowest singlet excited state (S₁) to the lowest triplet excited state (T₁).

$$\begin{matrix}[ Formula 1 ] & \\ {∅}_{p} = {∅}_{isc} \times \frac{{k}_{rp}}{{k}_{rp} + {k}_{nrp}} & ( 1 )\end{matrix}$$

$${τ}_{p} = \frac{1}{{k}_{r p} + {k}_{nrp}} \qquad ( 2 )$$

According to the formulae, kᵣₚ and kₙᵣₚ can be respectively expressed as Formulae (3) and (4) with the use of Φ and τ.

$$\begin{matrix}[ Formula 2 ] & \\ {k}_{rp} = \frac{1}{{∅}_{isc}} \times \frac{{∅}_{p}}{{τ}_{p}} & ( 3 )\end{matrix}$$

$${k}_{nrp} = \frac{1}{{∅}_{isc}} \times \frac{1 - {∅}_{p}}{{τ}_{p}} \qquad ( 4 )$$

The above measurement results show that the phosphorescence quantum yield Φₚ(D) of 8mpTP-4mDBtPBfpm-d23 that is deuterated is 1.5 times as high as the phosphorescence quantum yield Φₚ(H) of 8mpTP-4mDBtPBfpm that is not deuterated, and the phosphorescence lifetime τₚ(D) of 8mpTP-4mDBtPBfpm-d₂₃ is 1.9 times as long as the phosphorescence lifetime τₚ(H) of 8mpTP-4mDBtPBfpm. The fluorescence quantum yield Φ_{f}(D) of 8mpTP-4mDBtPBfpm-d₂₃ and the fluorescence quantum yield Φ_{f}(H) of 8mpTP-4mDBtPBfpm are substantially equal to each other.

Note that at the temperature cooled using liquid nitrogen, the rate constant of non-radiative transfer of fluorescent light is much smaller than the rate constants of radiative transfer and intercrossing; thus, the quantum yield Φ_{isc}(H) of intersystem crossing of 8mpTP-4mDBtPBfpm and the quantum yield Φ_{isc}(D) of intercrossing system of 8mpTP-4mDBtPBfpm-d₂₃ can be expressed with the use of the fluorescence quantum yields Φ_{f}(H) and Φ_{f}(D) of the corresponding substances as follows:

Φ_{isc}(H)=1−Φ_{f}(H)

Φ_{isc}(D)=1−Φ_{f}(D),

where since Φ_{f}(H) and Φ_{f}(D) have substantially the same value, Φ_{isc}(H) and Φ_{isc}(D) can be regarded as being substantially equal to each other.

That is, with the use of the phosphorescence quantum yield Φₚ(H), the rate constant τₚ(H), the intercrossing system quantum yield Φ_{isc}(H), the radiative transfer rate constant kᵣₚ(H), and the non-radiative transfer rate constant kₙᵣₚ(H) of 8mpTP-4mDBtPBfpm, and the phosphorescence quantum yield Φₚ(D), the rate constant τₚ(D), the intercrossing system quantum yield Φ_{isc}(D), the radiative transfer rate constant kᵣₚ(D), and the non-radiative transfer rate constant kₙᵣₚ(D) of 8mpTP-4mDBtPBfpm-d₂₃, kᵣₚ(H), kᵣₚ(D), kₙᵣₚ(H), and kₙᵣₚ(D) can be expressed as Formulae (3-1), (3-2), (4-1), and (4-2), respectively.

$$\begin{matrix}[ Formula 3 ] & \\ {k}_{rp} ( H ) = \frac{1}{{∅}_{isc} ( H )} \times \frac{{∅}_{p} ( H )}{{τ}_{p} ( H )} & ( 3 - 1 )\end{matrix}$$

$${k}_{r p} ( D ) = \frac{1}{{∅}_{i s c} ( D )} \times \frac{{∅}_{p} ( D )}{{τ}_{p} ( D )} = \frac{1}{{∅}_{i s c} ( H )} \times \frac{1.5 {∅}_{p} ( H )}{1.9 {τ}_{p} ( H )} \qquad ( 3 - 2 )$$

$${k}_{nrp} ( H ) = \frac{1}{{∅}_{i s c} ( H )} \times \frac{1 - {∅}_{p} ( H )}{{τ}_{p} ( H )} \qquad ( 4 - 1 )$$

$${k}_{nrp} ( D ) = \frac{1}{{∅}_{i s c} ( D )} \times \frac{1 - {∅}_{p} ( D )}{{τ}_{p} ( D )} = \frac{1}{{∅}_{i s c} ( H )} \times \frac{1 - 1.5 {∅}_{p} ( H )}{1.9 {τ}_{p} ( H )} \qquad ( 4 - 2 )$$

As shown above, kₙᵣₚ(D) is 0.50 times as large as kₙᵣₚ(H), i.e., kₙᵣₚ(D)<kₙᵣₚ(H), and kᵣₚ(D) is 0.79 times as large as kᵣₚ(H), i.e., kᵣₚ(D)<kᵣₚ(H). This shows that both the non-radiative transfer rate constant and the radiative transfer rate constant of 8mpTP-4mDBtPBfpm-d₂₃, which is deuterated, are smaller than those of 8mpTP-4mDBtPBfpm; meanwhile, the non-radiative transfer rate constant has a larger decrease than the radiative transfer rate constant, and thus the radiative transfer is inhibited more than the non-radiative transfer.

Although a deuterated organic compound has a small radiative transfer rate constant and a small non-radiative transfer rate constant as described above, the non-radiative transfer is more inhibited, which results in radiative transfer of more triplet excitons. Since the radiative transition relates to energy transfer, a deuterated organic compound has higher efficiency of excitation energy transfer to another compound (here, a phosphorescent light-emitting substance that is a guest material) than a non-deuterated organic compound. An improvement in energy efficiency can inhibit deterioration of the deuterated organic compound; thus, a light-emitting device using the organic compound as the host material can inhibit deterioration of the host material and can have favorable reliability.

At low temperature (temperature cooled using liquid nitrogen), the radiative transfer rate constant kᵣₚ(D) of 8mpTP-4mDBtPBfpm-d₂₃ is 0.79 times as large as the radiative transfer rate constant kᵣₚ(H) of 8mpTP-4mDBtPBfpm, and the non-radiative transfer rate constant kₙᵣₚ(D) of 8mpTP-4mDBtPBfpm-d₂₃ is 0.50 times as large as the non-radiative transfer rate constant kₙᵣₚ(H) of 8mpTP-4mDBtPBfpm; thus, a decrease in the non-radiative transfer rate constant kₙᵣₚ(D) is relatively large. Since the proportion of triplet excitons of radiative transition in 8mpTP-4mDBtPBfpm-d₂₃ is high even when the decrease in the radiative transfer rate constant kᵣₚ(D) is taken into consideration, it can be said that deuteration improves the energy transfer efficiency.

As for the fluorescence quantum yield, there was no significant difference between 8mpTP-4mDBtPBfpm-d₂₃ and 8mpTP-4mDBtPBfpm. In addition, the rate constant of non-radiative transition at a low temperature of 77K is much smaller than the rate constants of radiative transition and intercrossing system. From this, it can be said that deuteration does not cause significant difference in the rate constants of radiative transition and non-radiative transition in fluorescent emission process of 8mpTP-4mDBtPBfpm-d₂₃ and 8mpTP-4mDBtPBfpm, and deuteration mainly affects the behavior of triplet excitons.

Here, 8mpTP-4mDBtPBfpm-d₁₃ (Structural Formula (223)) obtained by replacing only the first substituent of 8mpTP-4mDBtPBfpm with deuterium and 8mpTP-4mDBtPBfpm-d₁₀ (Structural Formula (225)) obtained by replacing only the second substituent of 8mpTP-4mDBtPBfpm with deuterium were subjected to measurement in a similar manner. Consequently, 8mpTP-4mDBtPBfpm-d₁₀ (Structural Formula (225)) and 8mpTP-4mDBtPBfpm exhibited substantially the same results, and 8mpTP-4mDBtPBfpm-d₁₃ (Structural Formula (223)) and 8mpTP-4mDBtPBfpm-d₂₃ exhibited substantially the same results.

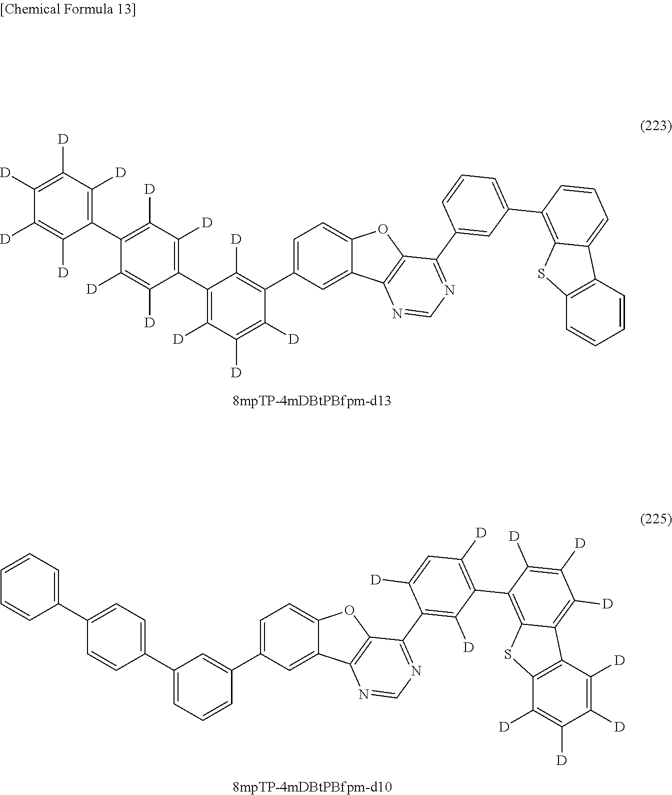

Note that 8mpTP-4mDBtPBfpm-d₁₃ that exhibited substantially the same result as 8mpTP-4mDBtPBfpm-d₂₃ is an organic compound obtained by substituting only the first substituent of the first organic compound with deuterium. This reveals that substituting only the first substituent of the first organic compound with deuterium can inhibit non-radiative transition in a phosphorescent emission process. This is probably because, in the first organic compound where T₁ is locally distributed in the first substituent, deuteration of the first substituent inhibits vibration in the molecule in the lowest triplet excited state and accordingly can inhibit non-radiative transition from T₁ in the first organic compound. This agrees with the above result (the result that fluorescence quantum yield and fluorescence lifetime do not change and only phosphorescence quantum yield and phosphorescence lifetime change).

In view of the efficiency ϕ_{ET} of energy transfer from the host material to the guest material, the energy transfer efficiency ϕ_{ET} is expressed as Formula (5), and what is needed to increase the energy transfer efficiency ϕ_{ET} is increasing the energy transfer rate constant k_{h*→g} to make another rate constant kᵣ+kₙᵣ (=1/τ) relatively small.

In Formula (5), kᵣ represents the rate constant of a light emission process (a fluorescent emission process in the case where energy transfer from a singlet excited state is discussed, and a phosphorescent emission process in the case where energy transfer from a triplet excited state is discussed) of the host material, kₙᵣ represents the rate constant of a non-light-emission process (thermal deactivation and intersystem crossing) of the host material, and r represents a measured lifetime of an excited state of the host material. In addition, k_{h*→g} represents the rate constant of energy transfer (Förster mechanism or Dexter mechanism).

$$\begin{matrix}[ Formula 4 ] & \\ {∅}_{E T} = \frac{{k}_{{h}^{*} \to g}}{{k}_{r} + {k}_{n r} + {k}_{{h}^{*} \to g}} = \frac{{k}_{{h}^{⋁} \to g}}{( \frac{1}{τ} ) + {k}_{{h}^{*} \to g}} & ( 5 )\end{matrix}$$

The atomic arrangement in a molecule, the spectrum shape, and the like do not differ between the deuterated organic compound (8mpTP-4mDBtPBfpm-d₂₃) and the non-deuterated organic compound (8mpTP-4mDBtPBfpm), which indicates that these two organic compounds have substantially the same energy transfer rate constants k_{h*→g}(see Formula (6) or (7)). It is thus found that a significant difference between the deuterated organic compound and the non-deuterated organic compound is the emission lifetime (phosphorescence lifetime) τ.

As described above, the phosphorescence lifetime measured at low temperature (temperature cooled using liquid nitrogen) of the deuterated organic compound (8mpTP-4mDBtPBfpm-d₂₃) was 1.9 times as long as that of the non-deuterated organic compound (8mpTP-4mDBtPBfpm). On the assumption that the phosphoresce lifetime differs between the deuterated organic compound and the non-deuterated organic compound also at room temperature, it can be said that a light-emitting device using the deuterated organic compound (8mpTP-4mDBtPBfpm-d₂₃) as a host material has higher energy transfer efficiency than a light-emitting device using the non-deuterated organic compound (8mpTP-4mDBtPBfpm) as a host material, as found from Formula (5) of the energy transfer efficiency ϕ_{ET}.

An improvement in energy transfer efficiency can inhibit deterioration of the deuterated organic compound. Accordingly, the light-emitting device using the deuterated organic compound as the host material can inhibit deterioration of the host material more than the light-emitting device using the non-deuterated organic compound as the host material, and thus can have favorable reliability.

$$\begin{matrix}[ Formula 5 ] & \\ {k}_{{h}^{*} \to g} = \frac{9000 {K}^{2} ∅ ln 10}{128 {π}^{5} {n}^{4} N τ {R}^{6}} \int \frac{{f}_{h}^{′} ( v ) {ε}_{g} ( v )}{{v}^{4}} dv & ( 6 )\end{matrix}$$

$$\begin{matrix}[ Formula 6 ] & \\ {k}_{{h}^{⋆} \to g} = ( \frac{2 π}{h} ) {K}^{2} exp ( - \frac{2 R}{L} ) \int {f}_{h}^{′} ( v ) {ε}_{g}^{′} ( v ) dv & ( 7 )\end{matrix}$$

Formula (6) is a formula of the rate constant k_{h*→g} of the Forster mechanism and Formula (7) is a formula of the rate constant k_{h*→g} of the Dexter mechanism.

In Formula (6), ν represents a frequency, f′ₕ(v) denotes a normalized emission spectrum of the host material (a fluorescent spectrum in the case where energy transfer from a singlet excited state is discussed, and a phosphorescent spectrum in the case where energy transfer from a triplet excited state is discussed), ε_{g}(v) represents a molar absorption coefficient of the guest material, N represents Avogadro's number, n denotes a refractive index of a medium, R represents an intermolecular distance between the host material and the guest material, τ represents a measured lifetime of an excited state (fluorescence lifetime or phosphorescence lifetime), ϕ represents an emission quantum yield (a fluorescence quantum yield in energy transfer from a singlet excited state, and a phosphorescence quantum yield in energy transfer from a triplet excited state), and K² represents a coefficient (0 to 4) of orientation of a transition dipole moment between the host material and the guest material. Note that K²=2/3 in random orientation.

In Formula (7), h represents a Planck constant, K represents a constant having an energy dimension, v represents a frequency, f′ₕ(v) represents a normalized emission spectrum of the host material (a fluorescent spectrum in the case where energy transfer from a singlet excited state is discussed, and a phosphorescent spectrum in the case where energy transfer from a triplet excited state is discussed), ε′_{g}(v) represents a normalized absorption spectrum of the guest material, L represents an effective molecular radius, and R represents an intermolecular distance between the host material and the guest material.

In the case where the triplet exciton has high energy and a long lifetime, deterioration might be promoted. However, the T₁ level of the first organic compound of one embodiment of the present invention is relatively low, and thus the triplet exciton having a long lifetime does not much affect the reliability. A substance obtained by deuterating the first and second substituents of the first organic compound (host material) inhibits non-radiative transition, which increases the efficiency of energy transfer from the substance to the light-emitting material and improves the reliability of the light-emitting device.

### Example 5

In this example, fabrication methods of Light-emitting device 5, Light-emitting device 6, and Light-emitting device 7 of one embodiment of the present invention, and the measurement results of the initial characteristics and reliability of the light-emitting devices are described.

Structural formulae of main compounds used in this example are shown below.

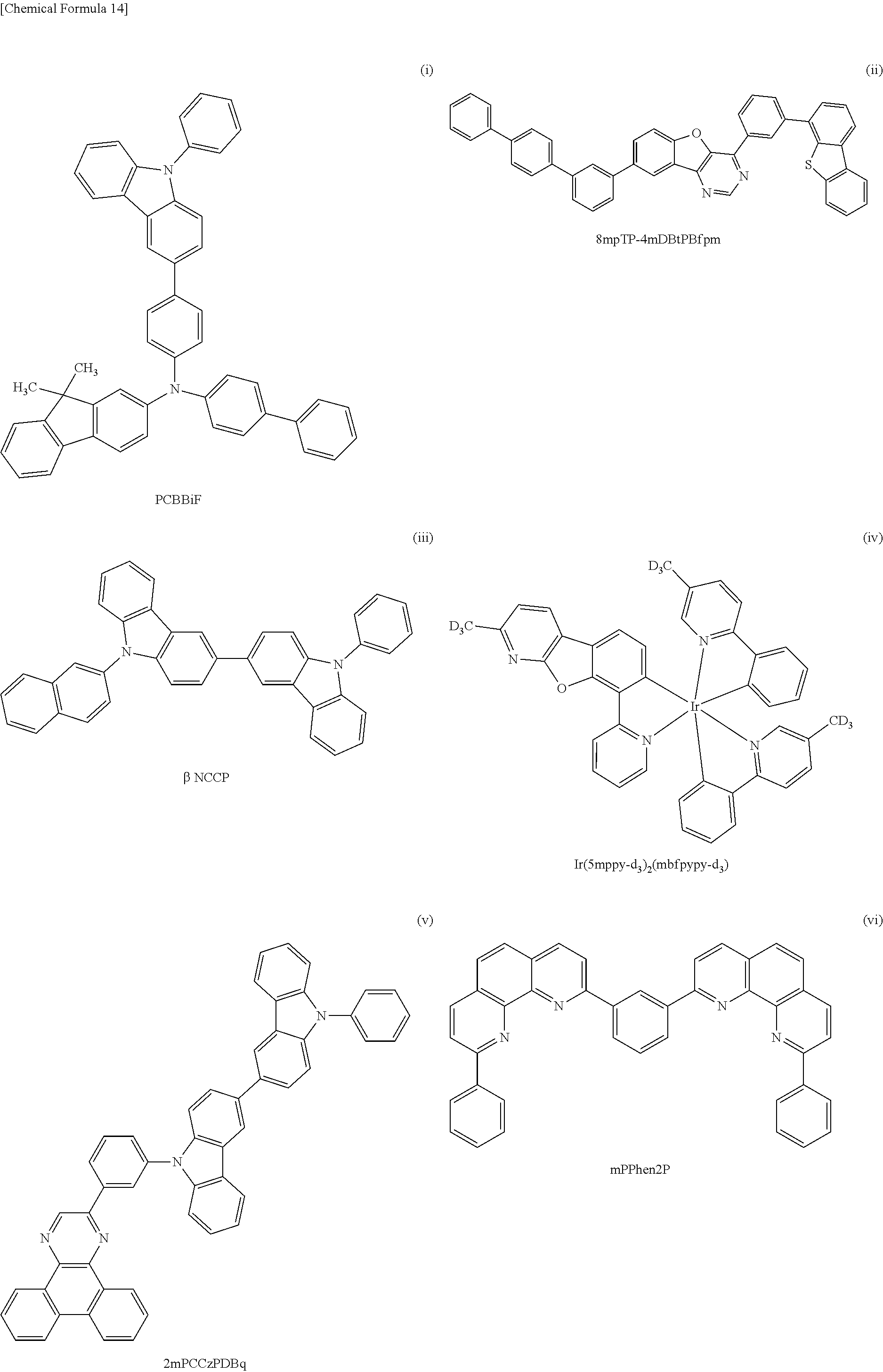

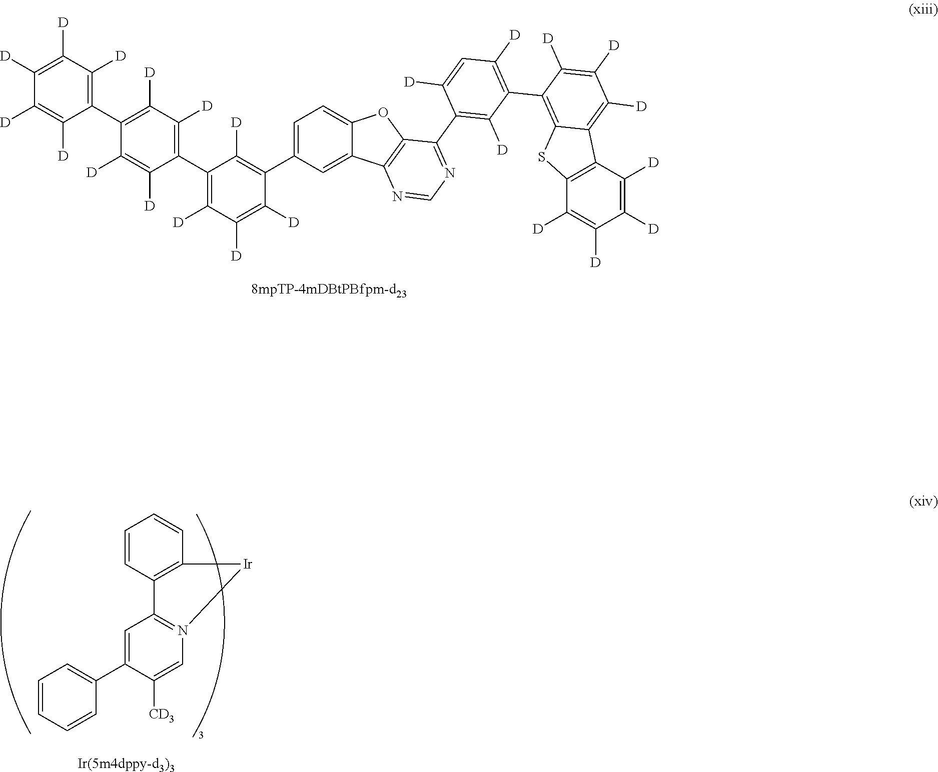

### (Fabrication Method of Light-Emitting Device 5)

First, over a silicon substrate provided with a wiring, 50-nm-thick titanium (Ti), 70-nm-thick aluminum (Al), and 6-nm-thick T₁ were sequentially stacked by a sputtering method. This was heated at 300° C. in an air atmosphere for 1 hour. After the heat treatment, washing was performed and then indium tin oxide containing silicon oxide (ITSO) was deposited by a sputtering method to a thickness of 10 nm. This stacked-layer film was patterned by a photolithography method, whereby a first electrode was formed. Note that the transparent electrode functions as an anode, and the transparent electrode and the reflective electrode are collectively regarded as the first electrode.

The first electrode area was set to 4 mm² (2 mm×2 mm).

Next, in pretreatment for forming the light-emitting device over the substrate, the substrate was subjected to heat treatment at 120° C. for 120 seconds, 1,1,1,3,3,3-hexamethyldisilazane (abbreviation: HMDS) was then vaporized, and a spray thereof was given, for 120 seconds, to the substrate heated to 60° C. Consequently, the stacked-layer film formed over the first electrode are hardly separated from the first electrode in the fabrication process.

After that, the substrate was transferred into a vacuum evaporation apparatus where the pressure was reduced to approximately 1×10⁻⁴ Pa, and was subjected to vacuum baking at 170° C. for 60 minutes in a heating chamber of the vacuum evaporation apparatus and then, the substrate was cooled down for approximately 60 minutes.

Then, the substrate was fixed to a holder provided in the vacuum evaporation apparatus such that the surface on which the first electrode 101 was formed faced downward. Over the inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 111 was formed.

Over the hole-injection layer 111, PCBBiF was deposited by evaporation to a thickness of 10 nm, whereby the hole-transport layer 112 was formed.

Then, over the hole-transport layer, 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (ii), 9-(2-naphthyl)-9′-phenyl-9H,9′H-3,3′-bicarbazole (abbreviation: βNCCP) represented by Structural Formula (iii), and [2-d₃-methyl-8-(2-pyridinyl-κN)benzofuro[2,3-b]pyridine-κC]bis[2-(5-d₃-methyl-2-pyridinyl-κN2)phenyl-κC]iridium(III) (abbreviation: Ir(5mppy-d3)₂(mbfpypy-d3)) represented by Structural Formula (iv) were deposited by co-evaporation to a thickness of 40 nm such that the weight ratio of 8mpTP-4mDBtPBfpm to βNCCP and Ir(5mppy-d3)₂(mbfpypy-d3) was 0.6:0.4:0.1, whereby the light-emitting layer 113 was formed.

Next, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) was deposited by evaporation to a thickness of 10 nm to form a first electron-transport layer, and then 2,2′-(1,3-phenylene)bis(9-phenyl-1,10-phenanthroline) (abbreviation: mPPhen2P) represented by Structure Formula (vi) was deposited by evaporation to a thickness of 15 nm to form a second electron-transport layer, whereby the electron-transport layer 114 was formed.

Then, processing by a photolithography method was performed. The substrate provided with components up to the electron-transport layer 114 was taken out from the vacuum evaporation apparatus and exposed to the air, and then aluminum oxide was deposited to a thickness of 30 nm by an ALD method, whereby a first sacrificial layer was formed. For the deposition of aluminum oxide by an ALD method, trimethylaluminum (abbreviation: TMA) and water vapor were used as a precursor and an oxidizer, respectively.

Over the first sacrificial layer, tungsten (W) was deposited to a thickness of 54 nm by a sputtering method, whereby a second sacrificial layer was formed.

A photoresist was applied onto the second sacrificial layer, exposure to light and development were performed, and processing was performed such that the photoresist after the processing covered the first electrode and an edge portion of the photoresist had a shape with a 3.0-μm-width slit in a position on the outside of an edge portion of the first electrode at a distance of 3.5 μm.

The second sacrificial layer was processed using an etching gas containing SF₆ with the use of the processed photoresist as a mask, and then the first sacrificial layer was processed using the second sacrificial layer as a hard mask with the use of an etching gas containing fluoroform (CHF₃), helium (He), and methane (CH₄) at a flow rate ratio of CHF₃:He:CH₄=16.5:118.5:15. After that, an EL layer including the hole-injection layer, the hole-transport layer, the light-emitting layer, and the electron-transport layer was processed using an etching gas containing oxygen (O₂).

After the EL layer was processed, the second sacrificial layer was removed using an etching gas containing SF₆, while the first sacrificial layer remained. Then, the first sacrificial layer was removed using an aqueous solution containing hydrofluoric acid (HF), whereby the electron-transport layer was exposed.

The substrate with the exposed second electron-transport layer was transferred into a vacuum evaporation apparatus where the pressure was reduced to approximately 1×10-4 Pa, and vacuum baking was performed at 70° C. for 90 minutes in a heating chamber of the vacuum evaporation apparatus.

After that, lithium fluoride (LiF) and ytterbium (Yb) were deposited by co-evaporation to a thickness of 1.5 nm such that the volume ratio of LiF to Yb was 1:0.5 to form the electron-injection layer 115, and then silver (Ag) and magnesium (Mg) were deposited by co-evaporation to a thickness of 25 nm such that the volume ratio of Ag to Mg was 1:0.1, whereby the second electrode 102 was formed. In this manner, the light-emitting device of one embodiment of the present invention was fabricated. Over the second electrode, indium tin oxide (ITO) was deposited to a thickness of 70 nm as a cap layer.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, Light-emitting device 5 was fabricated.

### (Fabrication Method of Light-Emitting Device 6)

Light-emitting device 6 was fabricated in a manner similar to that of Light-emitting device 5 except that 8mpTP-4mDBtPBfpm, βNCCP, and tris{2-[5-(methyl-d₃)-4-phenyl-2-pyridinyl-κN]phenyl-κC}iridium(III) (abbreviation: Ir(5m4dppy-d₃)₃) represented by Structural Formula (xiv) were deposited by co-evaporation to a thickness of 40 nm such that the weight ratio of 8mpTP-4mDBtPBfpm to βNCCP and Ir(5m4dppy-d3)₃ was 0.6:0.4:0.1 to form the light-emitting layer.

### (Fabrication Method of Light-Emitting Device 7)

Light-emitting device 7 was fabricated in a manner similar to that of Light-emitting device 6 except that 8mpTP-4mDBtPBfpm was replaced with 8-(1,1′:4′,1″-terphenyl-3-yl-2,4,5,6,2′,3′,5′,6′,2″,3″,4″,5″,6″-d₁₃)-4-[3-(dibenzothiophen-4-yl-1,2,3,6,7,8,9-d₇)phenyl-2,4,6-d₃]-[1]benzofuro[3,2-d]pyrimidine (abbreviation: 8mpTP-4mDBtPBfpm-d₂₃) represented by Structural Formula (xiii) above.

Device structures of Light-emitting devices 5 to 7 are shown below.

TABLE 7

| | | | |
|---|---|---|---|
| Thickness | Light-emitting device 5 | Light-emitting device 6 | Light-emitting device 7 |

| Cap layer | | 70 | nm | ITO |
|---|---|---|---|---|
| Second electrode | | 25 | nm | Ag:Mg (1:0.1) |
| Electron-injection layer | | 1.5 | nm | LiF:Yb (1:0.5) |
| Electron- | 2 | 15 | nm | mPPhen2P |
| transport layer | 1 | 10 | nm | 2mPCCzPDBq |

| Light-emitting layer | 40 | nm | * 1 |
|---|---|---|---|
| Hole-transport layer | 10 | nm | PCBBiF |
| Hole-injection layer | 10 | nm | PCBBiF:OCHD-003 (1:0.03) |
| First electrode | 10 | nm | ITSO |
| | 6 | nm | Ti |
| | 70 | nm | Al |
| | 50 | nm | Ti |

TABLE 8

| Light-emitting device | * 1 |
|---|---|
| Light-emitting device 5 | 8mpTP-4mDBtPBfpm: |
| | βNCCP: |
| | Ir(5mppy-d₃)₂(mbfpypy-d₃) |
| | (0.6:0.4:0.1) |
| Light-emitting device 6 | 8mpTP-4mDBtPBfpm: |
| | βNCCP: |
| | Ir(5m4dppy-d₃)₃ |
| | (0.5:0.5:0.1) |
| Light-emitting device 7 | 8mpTP-4mDBtPBfpm-d₂₃: |
| | βNCCP: |
| | Ir(5m4dppy-d₃)₃ |
| | (0.5:0.5:0.1) |

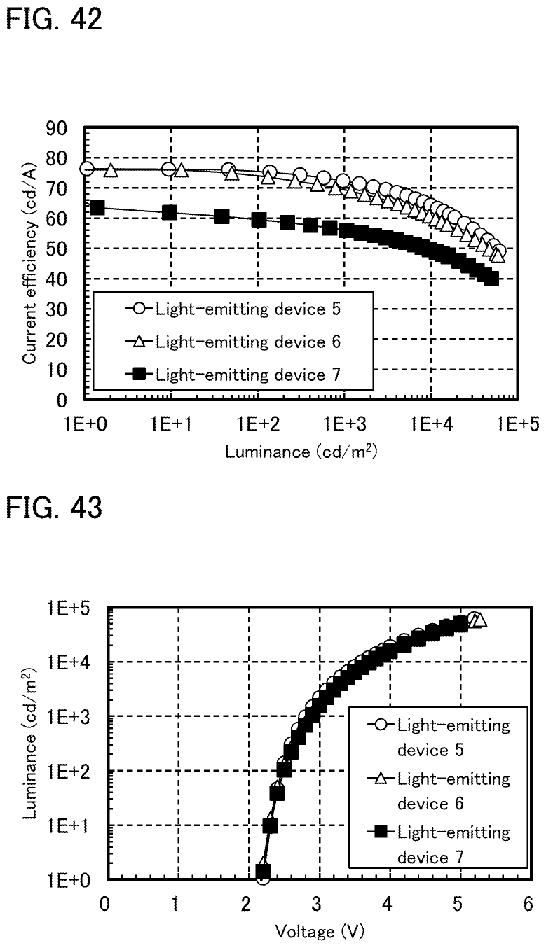

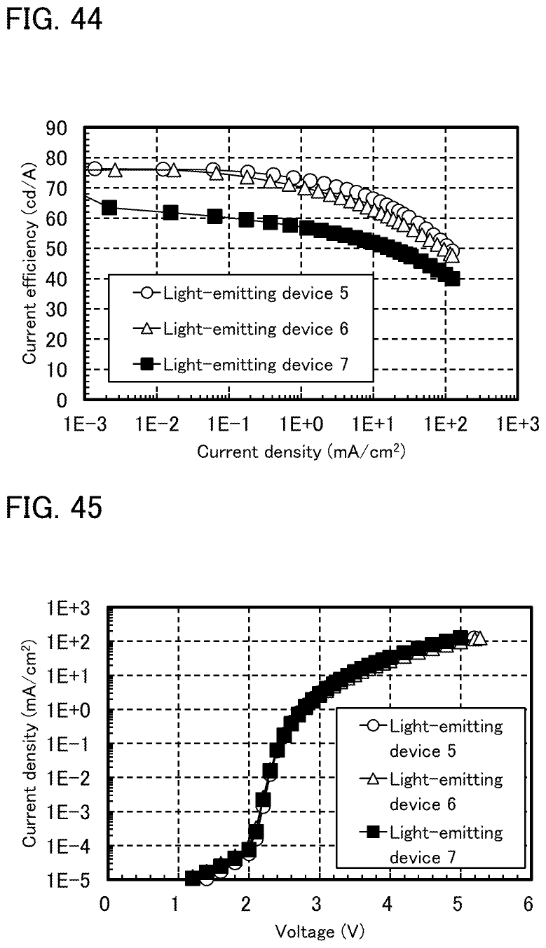

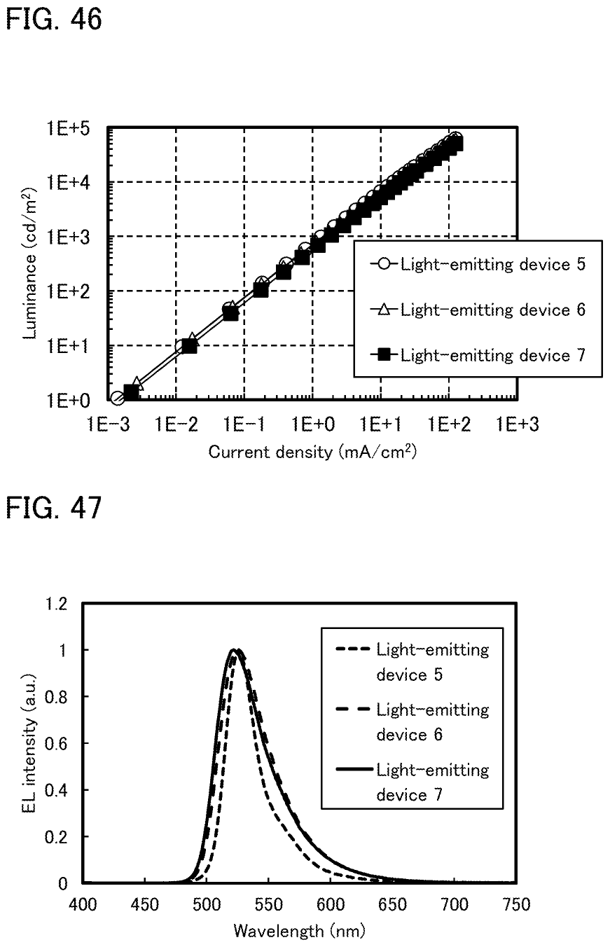

FIG. 42 shows the current efficiency-luminance characteristics of Light-emitting devices 5 to 7. FIG. 43 shows the luminance-voltage characteristics thereof. FIG. 44 shows the current efficiency-current density characteristics thereof. FIG. 45 shows the current density-voltage characteristics thereof. FIG. 46 shows the luminance-current density characteristics thereof. FIG. 47 shows electroluminescence spectra thereof. Table 9 shows main initial characteristics thereof. The luminance, CIE chromaticity, and emission spectra were measured at normal temperature with a spectroradiometer (SR-UL1R manufactured by TOPCON TECHNOHOUSE CORPORATION).

TABLE 9

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting device 5 | 2.8 | 0.054 | 1.34 | 0.25 | 0.70 | 72 |
| Light-emitting device 6 | 2.9 | 0.069 | 1.73 | 0.28 | 0.67 | 69 |
| Light-emitting device 7 | 2.9 | 0.076 | 1.90 | 0.27 | 0.67 | 56 |

FIG. 42 to FIG. 47 and Table 9 show that Light-emitting devices 5 to 7 each have favorable characteristics.

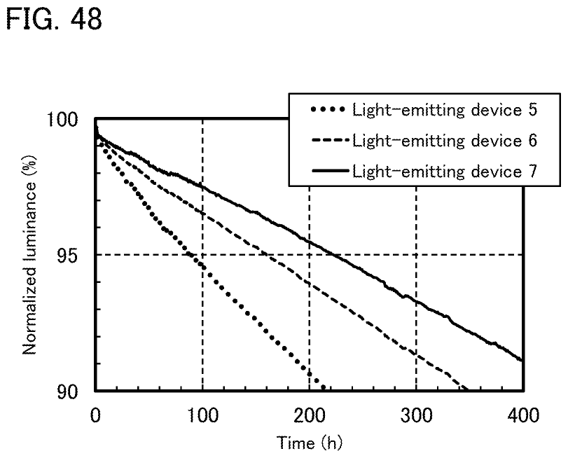

FIG. 48 shows the changes in luminance of Light-emitting devices 5 to 7 over driving time in constant-current driving at a current density of 50 mA/cm². It is found from FIG. 48 that Light-emitting devices 5 to 7 each have high reliability and Light-emitting device 7 particularly has a long lifetime.

Light-emitting device 5 is the light-emitting device of one embodiment of the present invention including 8mpTP-4mDBtPBfpm as the first organic compound, βNCCP as the second organic compound, and Ir(5mppy-d₃)₂(mbfpypy-d₃) as the phosphorescent light-emitting substance in the light-emitting layer. Light-emitting device 6 is the light-emitting device of one embodiment of the present invention including 8mpTP-4mDBtPBfpm as the first organic compound, βNCCP as the second organic compound, and Ir(5m4dppy-d₃)₃ as the phosphorescent light-emitting substance in the light-emitting layer. Light-emitting device 7 is the light-emitting device of one embodiment of the present invention including 8mpTP-4mDBtPBfpm-d₂₃ as the first organic compound, βNCCP as the second organic compound, and Ir(5m4dppy-d₃)₃ as the phosphorescent light-emitting substance in the light-emitting layer.

Thus, 8mpTP-4mDBtPBfpm or 8mpTP-4mDBtPBfpm-d₂₃ as the first organic compound is the organic compound having a benzofuropyrimidine skeleton, which is a heteroaromatic ring skeleton, and a terphenyl group, which is an aromatic hydrocarbon group, and the lowest triplet excited level of 8mpTP-4mDBtPBfpm is derived from the terphenyl group. Moreover, βNCCP, which is the second organic compound, is the organic compound having a bicarbazole skeleton, and the lowest triplet excitation energy of βNCCP is 2.55 eV (within the range of 2.20 eV to 2.65 eV). In addition, Ir(5mppy-d₃)₂(mbfpypy-d3) and Ir(5m4dppy-d₃)₃ are each a phosphorescent light-emitting substance that emits green phosphorescent light.

For calculation of the lowest triplet excitation energy level (T₁ level) of βNCCP, an emission spectrum (a phosphorescence spectrum) was measured at a measurement temperature of 10 K using a 50-nm-thick βNCCP film formed over a quartz substrate. The measurement was performed with a PL microscope, LabRAM HR-PL (produced by HORIBA, Ltd.) and a He—Cd laser (325 nm) as excitation light. As a result, the shortest-wavelength peak of the emission spectrum (phosphorescence spectrum) is 491 nm (2.53 eV) and the emission edge on the shortest wavelength side of the emission spectrum is 486 nm (2.55 eV). Note that the emission edge was determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum (phosphorescence spectrum).

The first organic compound and the second organic compound in Light-emitting devices 5 to 7 form an exciplex capable of exciting the green phosphorescent light-emitting substance. Furthermore, the relatively low T₁ level of the second organic compound, which is 2.55 eV, prevents the generation of excitons in an excessively high energy state. The T₁ level of the first organic compound is as moderate as that of the second organic compound because its lowest triplet excited level is present at the terphenyl group (particularly preferably, the terphenyl group the meta-position of which is bonded to a heteroaromatic ring skeleton). Thus, Light-emitting devices 5 to 7 can be highly reliable.

In a manner similar to that of βNCCP, the lowest triplet excitation energy level (T₁ level) of each of 8mpTP-4mDBtPBfpm and 8mpTP-4mDBtPBfpm-d₂₃ was measured. The shortest-wavelength peak of the emission spectrum of 8mpTP-4mDBtPBfpm is 500 nm (2.48 eV), and the emission edge on the shortest wavelength side of the emission spectrum is 486 nm (2.55 eV). The shortest-wavelength peak of the emission spectrum of 8mpTP-4mDBtPBfpm-d₂₃ is 501 nm (2.48 eV), and the emission edge on the shortest wavelength side of the emission spectrum is 484 nm (2.56 eV).

This application is based on Japanese Patent Application Serial No. 2022-105076 filed with Japan Patent Office on Jun. 29, 2022 and Japanese Patent Application Serial No. 2023-096193 filed with Japan Patent Office on Jun. 12, 2023, the entire contents of which are hereby incorporated by reference.

What is claimed is:

1. A light-emitting device comprising:
a first electrode;
a second electrode; and
a light-emitting layer,
wherein the light-emitting layer is between the first electrode and the second electrode,
wherein the light-emitting layer comprises a first organic compound, a second organic compound, and a phosphorescent light-emitting substance,
wherein the first organic compound comprises a heteroaromatic ring skeleton and an aromatic hydrocarbon group,
wherein the second organic compound comprises a bicarbazole skeleton,
wherein a lowest triplet excited state of the first organic compound is locally distributed at the aromatic hydrocarbon group, and
wherein energy of a lowest triplet excited level of the second organic compound is higher than or equal to 2.20 eV and lower than or equal to 2.65 eV.

2. A light-emitting device comprising:
a first electrode;
a second electrode; and
a light-emitting layer,
wherein the light-emitting layer is between the first electrode and the second electrode,
wherein the light-emitting layer comprises a first organic compound, a second organic compound, and a phosphorescent light-emitting substance,
wherein the first organic compound comprises a heteroaromatic ring skeleton and a substituent,
wherein the substituent comprises a 1,1′:4′,1″-terphenyl skeleton,
wherein the second organic compound comprises a bicarbazole skeleton, and
wherein energy of a lowest triplet excited level of the second organic compound is higher than or equal to 2.20 eV and lower than or equal to 2.65 eV.

3. The light-emitting device according to claim 2,
wherein the substituent comprises one or both of a dibenzofuran skeleton and a dibenzothiophene skeleton.

4. The light-emitting device according to claim 2,
wherein a 3-position of the 1,1′:4′,1″-terphenyl skeleton is bonded to the heteroaromatic ring skeleton.

5. The light-emitting device according to claim 2,
wherein the substituent is bonded to the heteroaromatic ring skeleton through a 1,3-phenylene group.

6. A light-emitting device comprising:
a first electrode;
a second electrode; and
a light-emitting layer,
wherein the light-emitting layer is between the first electrode and the second electrode,
wherein the light-emitting layer comprises a first organic compound, a second organic compound, and a phosphorescent light-emitting substance,
wherein the first organic compound comprises a heteroaromatic ring skeleton and a 1,1′:4′,1″-terphenyl group,
wherein the second organic compound comprises a bicarbazole skeleton, and
wherein energy of a lowest triplet excited level of the second organic compound is higher than or equal to 2.20 eV and lower than or equal to 2.65 eV.

7. The light-emitting device according to claim 6,
wherein a 3-position of the 1,1′:4′,1″-terphenyl group is bonded to the heteroaromatic ring skeleton.

8. The light-emitting device according to claim 6,
wherein the 1,1′:4′,1″-terphenyl group is bonded to the heteroaromatic ring skeleton through a 1,3-phenylene group.

9. The light-emitting device according to claim 1,
wherein the heteroaromatic ring skeleton comprises a fused ring.

10. The light-emitting device according to claim 1,
wherein the heteroaromatic ring skeleton comprises a diazine skeleton.

11. The light-emitting device according to claim 1,
wherein the heteroaromatic ring skeleton comprises a fused ring and a diazine skeleton.

12. The light-emitting device according to claim 1,
wherein the heteroaromatic ring skeleton comprises a benzofuropyrimidine skeleton or a triazine skeleton.

13. The light-emitting device according to claim 1,
wherein the second organic compound comprises a naphthyl group.

14. The light-emitting device according to claim 2,
wherein a lowest triplet excited level of the first organic compound is derived from only the substituent.

15. The light-emitting device according to claim 2,
wherein the heteroaromatic ring skeleton comprises a diazine skeleton.

16. The light-emitting device according to claim 2,
wherein the heteroaromatic ring skeleton comprises a benzofuropyrimidine skeleton or a triazine skeleton.

17. The light-emitting device according to claim 2,
wherein the second organic compound comprises a naphthyl group.

18. The light-emitting device according to claim 6,
wherein the heteroaromatic ring skeleton comprises a diazine skeleton.

19. The light-emitting device according to claim 6,
wherein the heteroaromatic ring skeleton comprises a benzofuropyrimidine skeleton or a triazine skeleton.

20. The light-emitting device according to claim 6,
wherein the second organic compound comprises a naphthyl group.
